(19) United States
(12) Patent Application Publication
(10) Pub. No.: US 2025/0350091 A1
(43) Pub. Date: Nov. 13, 2025

(54) ULTRA-NARROW PULSE EMISSION LASER DIODE DRIVER

(71) Applicant: Silanna Asia Pte Ltd, Singapore (SG)

(72) Inventors: Joseph H. Colles, Bonsall, CA (US); Steven E. Rosenbaum, San Diego, CA (US); William E. Rader, III, Carrboro, NC (US); Stuart B. Molin, Carlsbad, CA (US); Aleksandar Radic, British Columbia (CA)

(73) Assignee: Silanna Asia Pte Ltd, Singapore (SG)

(21) Appl. No.: 19/273,679

(22) Filed: Jul. 18, 2025

Related U.S. Application Data
(63) Continuation-in-part of application No. 19/041,592, filed on Jan. 30, 2025.
Application No. 19/041,592 is a continuation-in-part of application No. 18/440,422, filed on Feb. 13, 2024, now Pat. No. 12,244,118.
Application No. 18/440,422 is a continuation of application No. 18/185,962, filed on Mar. 17, 2023, now Pat. No. 11,929,588.
Application No. 18/185,962 is a continuation of application No. 17/648,907, filed on Jan. 25, 2022, now Pat. No. 11,631,961.
Application No. 17/648,907 is a continuation of application No. 17/301,009, filed on Mar. 22, 2021, now Pat. No. 11,245,247.
(60) Provisional application No. 62/994,470, filed on Mar. 25, 2020.
(60) Provisional application No. 63/127,794, filed on Dec. 18, 2020.
(60) Provisional application No. 63/675,379, filed on Jul. 25, 2024.

(51) Int. Cl. H01S 5/026; H01S 5/042; H01S 5/068; H01S 5/40

(52) U.S. Cl. CPC H01S 5/0261; H01S 5/0428; H01S 5/06808; H01S 5/4025

(57) ABSTRACT

A pulsed laser diode driver includes an inductor having a first terminal configured to receive a first source voltage provided by a source capacitor. A bypass switch has a drain node connected to a second terminal of the inductor. A laser diode has an anode connected to the second terminal of the inductor and a cathode connected to a drain node of a pulse emission switch. The pulse emission switch and the bypass switch are configured to control a current flow through the inductor to emit a high-current pulse through the laser diode to thereby emit a light pulse corresponding to a peak current of a resonant waveform developed at the anode of the laser diode. The bypass switch is enabled during emission of the high-current pulse to modify a falling edge of the high-current pulse.

### RELATED APPLICATIONS

This application claims priority to U.S. Provisional Patent Application No. 63/675,379, filed Jul. 25, 2024, and is a continuation in part of U.S. patent application Ser. No. 19/041,592, filed Jan. 30, 2025, which is a continuation in part of U.S. patent application Ser. No. 18/440,422, filed Feb. 13, 2024, which is a continuation of U.S. patent application Ser. No. 18/185,962, filed Mar. 17, 2023, which is a continuation of U.S. patent application Ser. No. 17/648,907, filed Jan. 25, 2022, which is a continuation of U.S. patent application Ser. No. 17/301,009, filed Mar. 22, 2021, which issued as U.S. Pat. No. 11,245,247 on Feb. 8, 2022, and which claims priority to U.S. Provisional Application No. 62/994,470, filed Mar. 25, 2020, and to U.S. Provisional Application No. 63/127,794, filed Dec. 18, 2020, all of which are incorporated by reference for all purposes.

### BACKGROUND

Laser-based ranging systems, such as LiDAR, often use a pulsed laser diode driver circuit to generate a short, high-current pulse, which is passed through a laser diode to emit a corresponding pulse of laser light. Reflected pulses of laser light are received by the LiDAR system and used to determine a distance between the LiDAR system and the point of reflection. Spatial resolution of LiDAR systems is determined in part by the width of the pulse of laser light. Thus, it is usually desirable to generate a pulse of light having a width of about 5 ns or less. However, parasitic inductances of the pulsed laser diode driver circuit and the laser diode typically must be overcome to achieve the desired short pulse width. For example, many laser diodes have at least one bond wire which can contribute 1 nH of inductance, thereby limiting a slew rate of the current pulse unless there is very high voltage. Thus, some conventional pulsed laser diode driver circuits use a high source voltage, often greater than 40V-100V, to achieve the desired pulse width. Switching devices, such as GaN field-effect transistors (FET) are often used in conventional pulsed laser diode driver circuits as they can withstand such high voltages. However, pulsed laser diode driver circuits that use GaN technology may be more expensive, and/or may be more difficult to integrate with Silicon-based architectures.

### SUMMARY

In some aspects, the techniques described herein relate to a pulsed laser diode driver including: an inductor having a first terminal and a second terminal, the first terminal of the inductor being configured to receive a first source voltage, the first source voltage being based on a DC input voltage; a source capacitor having a first terminal directly electrically connected to the first terminal of the inductor to provide the first source voltage and a second terminal electrically coupled to ground; a bypass switch having a drain node that is directly electrically connected to the second terminal of the inductor and a source node that is directly electrically connected to ground; a first laser diode having an anode and a cathode, the anode of the first laser diode being directly electrically connected to the second terminal of the inductor and to the drain node of the bypass switch; and a first pulse emission switch having a drain node that is directly electrically connected to the cathode of the first laser diode and a source node that is directly electrically connected to ground; wherein: the first pulse emission switch and the bypass switch are configured to control a current flow through the inductor to emit a high-current pulse through the first laser diode to thereby emit a light pulse, the high-current pulse corresponding to a peak current of a resonant waveform developed at the anode of the first laser diode; and the bypass switch is enabled during emission of the high-current pulse to modify a falling edge of the high-current pulse.

In some aspects, the techniques described herein relate to a pulsed laser diode driver including: an inductor having a first terminal and a second terminal, the first terminal of the inductor being configured to receive a first source voltage, the first source voltage being based on a DC input voltage; a source capacitor having a first terminal directly electrically connected to the first terminal of the inductor to provide the first source voltage and a second terminal electrically coupled to ground; a bypass switch having a drain node that is directly electrically connected to the second terminal of the inductor and a source node that is directly electrically connected to ground; a first laser diode having an anode and a cathode, the anode of the first laser diode being directly electrically connected to the second terminal of the inductor and to the drain node of the bypass switch; wherein: the bypass switch is configured to control a current flow through the inductor to emit a high-current pulse through the first laser diode to thereby emit a light pulse, the high-current pulse corresponding to a peak current of a resonant waveform developed at the anode of the first laser diode; and the bypass switch is enabled during emission of the high-current pulse to truncate emission of the light pulse after a gain-switching spike portion of the light pulse occurs and before a resonant portion of the light pulse concludes.

In some aspects, the techniques described herein relate to a pulsed laser diode driver including: an inductor having a first terminal and a second terminal, the first terminal of the inductor being configured to receive a first source voltage, the first source voltage being based on a DC input voltage; a source capacitor having a first terminal directly electrically connected to the first terminal of the inductor to provide the first source voltage and a second terminal electrically coupled to ground; a bypass switch having a drain node that is directly electrically connected to the second terminal of the inductor and a source node that is directly electrically connected to ground; a first laser diode having an anode and a cathode, the anode of the first laser diode being directly electrically connected to the second terminal of the inductor and to the drain node of the bypass switch; and a first pulse emission switch having a drain node that is directly electrically connected to the cathode of the first laser diode and a source node that is directly electrically connected to ground; wherein: the first pulse emission switch and the bypass switch are configured to control a current flow through the inductor to emit a high-current pulse through the first laser diode to thereby emit a light pulse, the high-current pulse corresponding to a peak current of a resonant waveform developed at the anode of the first laser diode; and the bypass switch is enabled during emission of the high-current pulse substantially concurrently with a peak amplitude of the high-current pulse.

### BRIEF DESCRIPTION OF THE DRAWINGS

FIGS. 1A-1C are simplified circuit schematics of pulsed laser diode drivers of a first general topology, in accordance with some embodiments.

FIGS. 2A-2G show simplified plots of signals related to operation of the pulsed laser diode driver shown in FIG. 1A, in accordance with some embodiments.

FIG. 3 is a portion of an example switching sequence for operation of the pulsed laser diode drivers shown in FIGS. 1A-1C, in accordance with some embodiments.

FIGS. 4A-4D are simplified circuit schematics of pulsed laser diode drivers of a second general topology, in accordance with some embodiments.

FIGS. 5A-5D are simplified circuit schematics of pulsed laser diode drivers of a third general topology, in accordance with some embodiments.

FIGS. 6A-6D are simplified circuit schematics of pulsed laser diode drivers of a fourth general topology, in accordance with some embodiments.

FIGS. 7A-7E are simplified circuit schematics of pulsed laser diode drivers of a fifth general topology, in accordance with some embodiments.

FIGS. 8A-8B are simplified circuit schematics of pulsed laser diode drivers of a sixth general topology, in accordance with some embodiments.

FIGS. 9A-9B are simplified circuit schematics of pulsed laser diode drivers of a seventh general topology, in accordance with some embodiments.

FIGS. 10A-10B are simplified circuit schematics of pulsed laser diode drivers of an eighth general topology, in accordance with some embodiments.

FIGS. 11-12 show simplified plots of signals related to operation of the pulsed laser diode driver shown in FIG. 10B, in accordance with some embodiments.

FIGS. 13A-13I are simplified circuit schematics of high-repetition-rate pulsed laser diode drivers, in accordance with some embodiments.

FIG. 14 shows simplified plots of signals related to operation of the pulsed laser diode driver shown in FIG. 13I, in accordance with some embodiments.

FIG. 15 shows a simplified circuit schematic of a pulsed laser diode driver of a ninth general topology, in accordance with some embodiments.

FIGS. 16A-16B show simplified plots of signals related to operation of the pulsed laser diode driver shown in FIG. 15, in accordance with some embodiments.

FIGS. 17, 18, 19, and 20 are simplified circuit schematics of pulsed laser diode drivers having an adjustable DC input voltage, in accordance with some embodiments.

FIGS. 21A-21B are simplified plots of signals related to operation of the pulsed laser diode drivers shown in FIGS. 17, 18, 19, and 20.

FIGS. 22-23D are simplified circuit schematics of multi-channel common-cathode pulsed laser diode driver circuits, in accordance with some examples.

FIG. 24A-24B are portions of example switching sequences for operation of the pulsed laser diode drivers shown in FIGS. 23A-23D, in accordance with some examples.

FIG. 25 is a simplified layout topology for the pulsed laser diode drivers shown in FIGS. 23A-23D, in accordance with some examples.

FIGS. 26A-26E are simplified plots of signals related to operation of the pulsed laser diode drivers shown in FIGS. 23A-23D, in accordance with some examples.

FIGS. 27A-27B are simplified circuit schematics for pulsed laser diode driver circuits for mitigating the effects of parasitic loop inductances, in accordance with some examples.

FIGS. 28A-28C are simplified plots of signals related to operation of the pulsed laser diode drivers shown in FIGS. 27A-27B, in accordance with some examples.

FIG. 29 is a portion of an example switching sequence for operation of the pulsed laser diode drivers shown in FIGS. 27A-27B, in accordance with some examples.

FIGS. 30A-30B are simplified plots of signals related to operation of the pulsed laser diode drivers shown in FIGS. 27A-27B, in accordance with some examples.

### DETAILED DESCRIPTION

The spatial resolution of LiDAR systems is partially determined by the pulse width of the emitted and reflected laser light. Consequently, many close-range industrial applications, such as assembly line quality control systems, require laser diode drivers that can produce low-power, sub-nanosecond (e.g., 100 psec) light pulses. In accordance with some embodiments, the laser diode driver circuits disclosed herein are operable to produce sub-nanosecond pulses by emitting only an initial portion of a light pulse from a laser diode and then truncating the laser pulse before a steady-state of the laser diode is reached.

To elaborate, upon application of current through a laser diode, carrier density within the diode increases until it reaches a threshold necessary for lasing. At this juncture, a rapid onset of stimulated emission occurs, leading to a sharp initial spike in output power known as a gain-switching spike. Following this spike, the laser diode experiences relaxation oscillations due to the interplay between carrier density and photon density. These oscillations gradually dampen as current through the laser diode stabilizes, ultimately reaching a steady-state operation, characterized by a constant output power where the rate of carrier injection balances the rate of stimulated emission and losses. However, many close-range industrial applications only require the initial gain-switching spike emission, and light emission of the pulse thereafter is either unnecessary or sometimes undesirable. Unfortunately, truncating the emission of the remaining portion of the light pulse is often difficult to achieve in conventional laser diode driver solutions. This is because many conventional laser diode driver solutions are based on merely discharging the energy in a capacitor, and therefore have a pulse width that is determined by the value of the capacitor and inductance of the driver circuit and is not configurable by an end-user.

In accordance with some embodiments, “gain-switching spike” pulsed laser diode driver circuits disclosed herein generate high-current pulses to produce ultra-short (<1 ns) laser pulses from a laser diode using a tunable resonant circuit and configurable switch timing to advantageously truncate light pulse emission once the gain-switching spike has occurred. The resonant circuits disclosed herein provide easily tunable parameters which control a pulse width, a peak current, a charge time, a recovery time, a decay time, and other tunable parameters of the pulsed laser diode drivers.

Additionally, in many LiDAR systems, the rate of change of current through the laser diode is governed by a total loop inductance of the current path—i.e., the combined self- and mutual inductance of the forward current path and return current path. Parasitic contributions to this loop inductance arise from bond-wire geometry inside the laser-diode package and from the trace layout of the supporting circuit board. A resulting inductive voltage drop due to the total loop inductance limits the achievable rate of change of current through the laser diode (di/dt), and therefore limits a minimum achieved optical pulse width. Disclosed herein are additional pulsed laser diode driver circuits and control methods that advantageously produce symmetric high-current pulses through one or more laser diodes despite the presence of considerable parasitic loop inductance in the current path.

Embodiments of a switching sequence to drive the pulsed laser diode drivers disclosed herein are operable to generate a resonant waveform at an anode of the laser diode to produce the high-current pulse through the laser diode, a voltage level of the resonant waveform being advantageously sufficient to support the high-current pulse and not of a voltage level that exceeds the voltage required to generate the high-current pulse.

Thus, embodiments of such pulsed laser diode drivers can advantageously generate the high-current pulses using a low input voltage (e.g., 6V, 9V, 15V, etc.) and can thereby use Silicon-based switches, rather than GaN-based switches which are used by many conventional solutions. Any of the pulsed laser diode drivers disclosed herein can therefore be integrated into a single semiconductor die. Embodiments of pulsed laser diode drivers disclosed herein advantageously use a discrete inductor (e.g., a through-hole or surface-mounted component) intentionally added to the pulsed laser diode driver to generate a resonant waveform rather than relying on parasitic inductances (e.g., of the laser diode, of bond wires, or inter-circuit connections) of the pulsed laser diode driver. As a result, embodiments of the laser drivers disclosed herein are easily tunable and have a reproducible architecture. By contrast, conventional pulsed laser diode drivers often use a variety of techniques to overcome the effects of parasitic inductances of the pulsed laser diode driver and of the laser diode itself and therefore teach away from intentionally adding yet additional inductance to the pulsed laser diode driver. In addition to such intentionally added inductors, the pulsed laser diode drivers disclosed herein advantageously include a bypass capacitor that may be used by a designer to easily tune a desired pulse width emitted by the laser diode, as compared to conventional solutions which only have a source capacitor, or that only consider non-tunable parasitic capacitances of the pulsed laser diode driver. Once again, such conventional solutions teach away from adding yet additional capacitance to the pulsed laser diode driver. Because conventional solutions rely on parasitic capacitances and inductances of the conventional laser driver, modifying parameters such as a pulse width might require a redesign or re-layout of the conventional solution. By comparison, parameters, such as a pulse width, of the pulsed laser diode drivers disclosed herein can be tuned by simply changing a component value.

Multi-channel laser diodes are conventionally produced on a single monolithic substrate housed in a laser diode package. Conventionally, a single pin of the laser diode package is connected to all of the laser diode cathodes as a group (i.e., “common cathode”), whereas each laser diode anode is individually connected to a respective pin of the laser diode package. Pulsing each laser diode independently conventionally requires a switch in the laser diode anode current path to select which laser diode fires. However, an N-type switch conventionally requires a bootstrap circuit to level-shift a gate drive of that switch when the laser diode current path is enabled. Such bootstrap circuitry adds complexity and cost to a pulsed laser diode driver design. Thus, disclosed herein are embodiments of a multi-channel pulsed laser diode driver circuit for independently driving laser diodes of a common cathode multi-channel laser diode package advantageously using N-type switches without any bootstrap circuitry.

The repetition rate of a multi-channel laser diode driver, as well as of each of the pulsed laser diode drivers described herein, is limited by a charging time of each channel's source capacitor which is described below. The pulsed laser diode drivers described herein create ultra-narrow (e.g., 1 psec-5 nsec) high-current pulses (e.g., 40 amp) through a driven laser diode. The instantaneous power in the driven laser diode is therefore high (e.g., in the order of hundreds of watts). For many applications (e.g., LiDAR), the duty cycle of the pulse is generally 0.01% or less to limit a total power dissipated in the laser diode, which results in an upper limit to a repetition rate. In conventional pulsed laser diode driver applications, a resistor is used to charge source capacitors during each cycle. In such conventional solutions, an RC time constant of charging circuits is typically not an issue because the duty cycle is so low. However, for applications that require a higher repetition rate for laser pulses, the RC time constant of conventional charging circuits creates an undesirable limitation. Thus, in any of the embodiments disclosed herein, each source resistor of a given laser diode driver may be advantageously replaced by an actively controlled source switch that quickly charges an associated source capacitor.

Typical resonant driver designs require a damping resistor to minimize ringing duration. However, the added damping resistor dissipates power which lowers the overall power efficiency of the design. Thus, in some embodiments, a pulsed laser diode driver is disclosed that advantageously switches a damping resistor into the resonant circuit during portions of a switching sequence during which the damping resistor critically damps ringing, and switches the damping resistor out of the resonant circuit during portions of the switching sequence when the damping resistor is not providing a positive benefit to the resonant circuit, thereby increasing an overall power efficiency of the pulsed laser diode driver as compared to one that includes a damping resistor for the entirety of a switching sequence.

For some applications, the amplitude of a high-current pulse delivered by a pulsed laser diode driver, such as any of those disclosed herein, may need to be adjusted in amplitude from pulse to pulse. Thus, in some embodiments, any of the pulsed laser diode drivers disclosed herein may be advantageously configured to adjust an amplitude of the high-current pulse delivered to one or more laser diodes on a pulse-to-pulse basis.

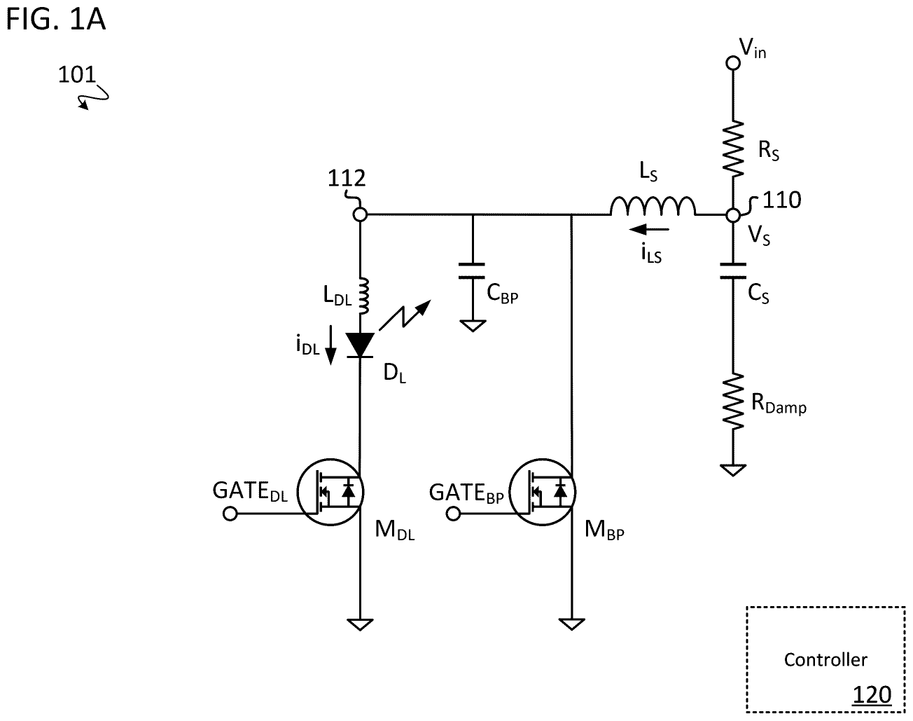

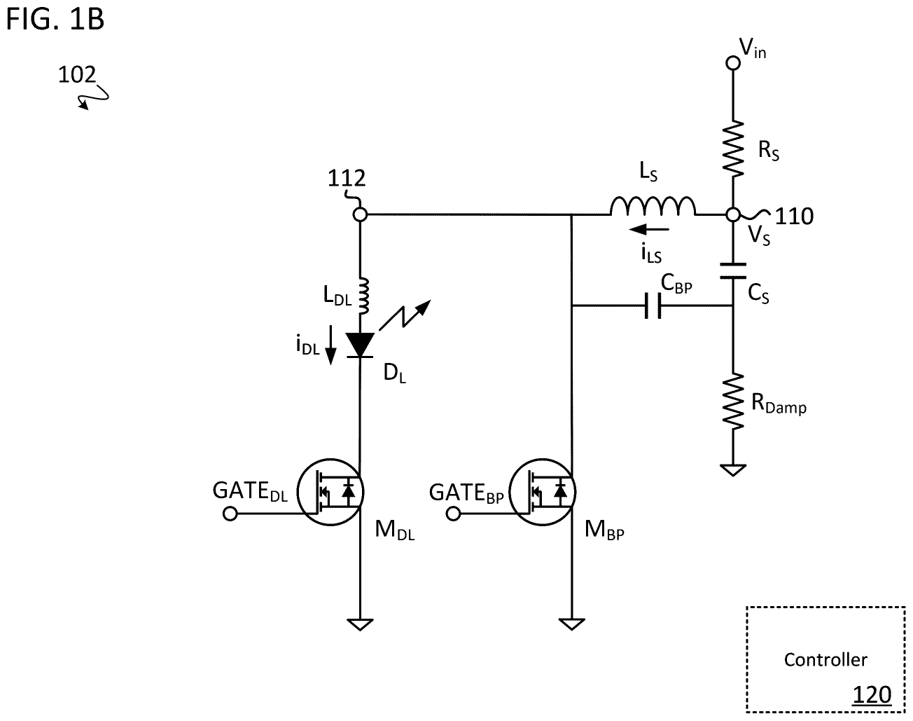

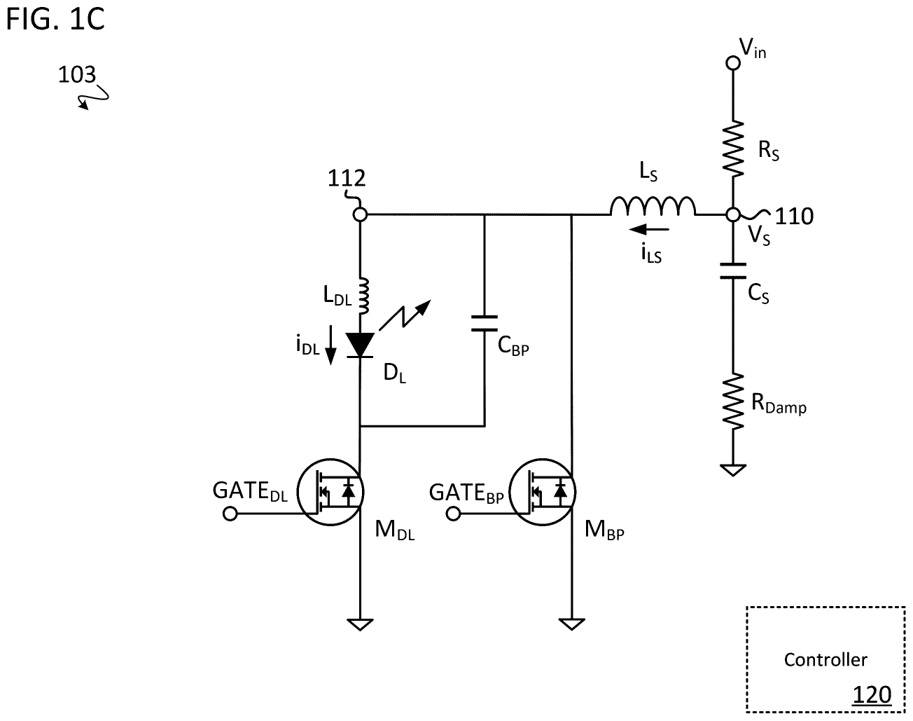

FIGS. 1A-C are simplified circuit schematics of pulsed laser diode drivers 101-103 of a first general topology to drive a laser diode using a low-side switch, in accordance with some embodiments. The pulsed laser diode drivers 101-103 each generally include a source resistor R_{S}, a source capacitor C_{S} (i.e., a physical component that is not representative of a parasitic capacitance of another component), a damping resistor R_{Damp}, an inductor L_{S} (i.e., a physical component that is not representative of a parasitic inductance of another component), a bypass capacitor C_{BP} (i.e., a physical component that is not representative of a parasitic capacitance of another component), a laser diode D_{L}, a bypass switch M_{BP}, and a laser diode switch M_{DL}. The laser diode switch M_{DL} is configured as a low-side switch. Also shown is a controller module “controller” 120, nodes 110, 112, a parasitic inductance L_{DL} of the laser diode D_{L}, a DC input voltage Vᵢₙ, a source voltage V_{S} at the source capacitor C_{S}, a current i_{LS} through the inductor L_{S}, a current i_{DL} through the laser diode D_{L}, a bypass switch gate driver signal GATE_{BP}, and a laser diode switch gate driver signal GATE_{DL}.

The controller 120 includes one or more timing circuits, look-up tables, processors, memory, or other modules to control the pulsed laser diode drivers disclosed herein. In some examples, the controller 120 is implemented by one or more circuits, Application-specific Integrated Circuit(s) (ASICs), Field-Programmable Gate Array(s) (FPGAs), or other suitable elements.

Topologies of the pulsed laser diode drivers 101-103 vary with respect to the placement of the bypass capacitor C_{BP}. In each of the topologies of the pulsed laser diode drivers 101-103, a first terminal of the source resistor R_{S} is configured to be directly electrically connected to the DC input voltage Vᵢₙ. A first terminal of the source capacitor C_{S} is directly electrically connected to a second terminal of the source resistor R_{S}, and a second terminal of the source capacitor C_{S} is directly electrically connected to a first terminal of the damping resistor R_{Damp}. A second terminal of the damping resistor R_{Damp} is directly electrically connected to a bias voltage node such as ground. Thus, the second terminal of the source capacitor C_{S} is electrically coupled to the bias voltage node. A first terminal of the inductor L_{S} is directly electrically connected to the second terminal of the source resistor R_{S} and to the first terminal of the source capacitor C_{S}. A drain node of the bypass switch M_{BP} is directly electrically connected to a second terminal of the inductor L_{S}, and a source node of the bypass switch M_{BP} is directly electrically connected to the bias voltage node. An anode of the laser diode D_{L} is directly electrically connected to the second terminal of the inductor L_{S}, and a cathode of the laser diode D_{L} is directly electrically connected to a drain node of the laser diode switch M_{DL}. A source node of the laser diode switch M_{DL} is directly electrically connected to the bias voltage node.

The bypass switch M_{BP} is configured to receive the bypass switch gate driver signal GATE_{BP} at a gate node, the bypass switch gate driver signal GATE_{BP} being operable to turn the bypass switch M_{BP} on or off based on a voltage level of the bypass switch gate driver signal GATE_{BP}. Similarly, the laser diode switch M_{DL} is configured to receive the laser diode switch gate driver signal GATE_{DL} at a gate node, the laser diode switch gate driver signal GATE_{DL} being operable to turn the laser diode switch M_{DL} on or off based on a voltage level of the laser diode switch gate driver signal GATE_{DL}. In some embodiments, the pulsed laser diode driver circuits disclosed herein include one or more bootstrap circuits or other level-shifting circuits to drive one or more high-side switches. Either or both of the bypass switch M_{BP} and the laser diode switch M_{DL} can be implemented as N-type switches or P-type switches. In some embodiments, the bypass switch M_{BP} and the laser diode switch M_{DL} are implemented as Silicon-based or Silicon-Carbide-based field-effect transistors (FETs). Two or more components described herein as having terminals that are directly electrically connected have a DC current path between the respective terminals of the two or more components. For example, a first and second component are not directly electrically connected via a capacitor or inductor connected in series between the first component and the second component.

As shown in the simplified circuit schematic of the pulsed laser diode driver 101 of FIG. 1A, in some embodiments a first terminal of the bypass capacitor C_{BP} is directly electrically connected to the second terminal of the inductor L_{S} and to the anode of the laser diode D_{L}. In such embodiments, a second terminal of the bypass capacitor C_{BP} is directly electrically connected to the bias voltage node. As shown in the simplified circuit schematic of the pulsed laser diode driver 102 of FIG. 1B, in some embodiments, the first terminal of the bypass capacitor C_{BP} is directly electrically connected to the second terminal of the inductor L_{S} and to the anode of the laser diode D_{L}. The second terminal of the bypass capacitor C_{BP} is directly electrically connected to the second terminal of the source capacitor C_{S} and to the first terminal of the damping resistor R_{Damp}. As shown in the simplified circuit schematic of the pulsed laser diode driver 103 of FIG. 1C, in some embodiments, the first terminal of the bypass capacitor C_{BP} is directly electrically connected to the second terminal of the inductor L_{S} and to the anode of the laser diode D_{L}. In such embodiments, the second terminal of the bypass capacitor C_{BP} is directly electrically connected to the drain terminal of the laser diode switch M_{DL} and to the cathode of the laser diode D_{L}.

In some embodiments, the pulsed laser diode drivers 101-103 are configured to receive the DC input voltage Vᵢₙ having a voltage range from about 10V to 20V, which is advantageously lower than an input voltage used by many conventional pulsed laser diode drivers. The inductor L_{S} is a physical component added to the pulsed laser diode drivers 101-103 (i.e., as opposed to a representation of a parasitic inductance caused by components or interconnections such as bond wires). Similarly, the bypass capacitor C_{BP} is a physical component added to the pulsed laser diode drivers 101-103 (i.e., as opposed to a representation of a parasitic capacitance). One advantage of using physical inductor and capacitor components rather than using parasitic inductances is that values of the inductor L_{S} and the bypass capacitor C_{BP} can be easily modified by a designer or even an end-user. By comparison, conventional designs that rely on parasitic reactances may require re-design and/or re-layout to change an operating parameter.

As disclosed herein, values of the DC input voltage Vᵢₙ, the inductance of the inductor L_{S}, the capacitance of the source capacitor C_{S}, the resistance of the damping resistor R_{Damp}, and the capacitance of the bypass capacitor C_{BP} can advantageously be selected (“tuned”) to achieve a desired operation of the pulsed laser diode drivers 101-103 (e.g., a charge time, a pulse width, a pulse voltage, a pulse current). For example, a pulse width of the current i_{DL} flowing through the laser diode D_{L} can be tuned by adjusting the capacitance value of the bypass capacitor C_{BP}, and the portion of the light pulse that is emitted can be controlled via the bypass switch gate driver signal GATE_{Bp}(e.g., to advantageously truncate light pulse emission after the gain-switching spike).

A peak current level of the pulse of current i_{DL} flowing through the laser diode D_{L} can be tuned by adjusting the source voltage V_{S} on the supply capacitor C_{S}. A capacitance value of the source capacitor C_{S} can be tuned to adjust a timing delay of the current pulse and an upper range of the current i_{DL} through the laser diode D_{L}. Resistance values of the damping resistor R_{D} amp are dependent on the capacitance value of the supply capacitor C_{S} and can be tuned within a range of values such that at a lower resistance, a lower frequency resonance of the pulsed laser diode drivers disclosed herein is underdamped (e.g., at about R_{Damp}=0.1 Ohm), or is critically damped (e.g., at about R_{Damp}=0.4 Ohm). The damping resistor R_{D} amp is operable to prevent current of the generated resonant waveform from becoming negative which could thereby enable a body diode of the bypass switch M_{BP} or the laser diode switch M_{DL}. Although a resulting maximum current level of the current i_{DL} through the laser diode D_{L} is lower for the critically damped case, the current level can be easily adjusted by raising the voltage level of the DC input voltage Vᵢₙ. In other embodiments, the damping resistor R_{Damp} is removed entirely from the design (i.e., the second terminal of the source capacitor C_{S} is directly electrically connected to the bias voltage node). In yet other embodiments, the resistance value of the damping resistor R_{D} amp is set to zero Ohms.

In some embodiments, the DC input voltage Vᵢₙ is about 15V, the inductance of the inductor L_{S} is about 6 nH, the capacitance of the source capacitor C_{S} is about 100 nF, the resistance of the damping resistor R_{Damp} is about 0.1 Ohms, and the capacitance of the bypass capacitor C_{BP} is about 1 nF. In some embodiments, a voltage at the first terminal of the damping resistor R_{Damp} is received by the controller 120 to provide an indication of a current flow through the damping resistor R_{Damp}.

In some or all of the embodiments disclosed herein, to produce around a 40A high-current pulse through the laser diode (or laser diodes) D_{L}, the DC input voltage Vᵢₙ may range from 10-15 volts. In some such embodiments, the inductance of inductor L_{S} may range from 5-10 nH, the value of which determines the amount of flux delay to produce the required current. In some such embodiments, the inductance of the inductor L_{S} is selected to be an order of magnitude greater than a parasitic inductance of a printed circuit board (PCB) in which the pulsed laser diode driver is implemented. In some embodiments, the resistance of the damping resistor R_{S} ranges from 100-200 mOhm. A capacitance of the bypass capacitor C_{BP} determines the pulse width of the high-current pulse through the laser diode(s) D_{L}, and in some embodiments ranges in capacitance from 1-5 nF. In some such embodiments, a capacitance of the supply capacitor C_{S} ranges from 25-100 nF depending on a peak current of the high-current pulse through the laser diode(s) D_{L} that is required or desired. The smaller the supply capacitor C_{S}, the higher the DC input voltage Vᵢₙ is needed to get the required or desired peak current of the high-current pulse through the laser diode(s) D_{L}. In some such embodiments, a smallest capacitance value of the supply capacitor C_{S} that can still deliver the needed or desired peak current of the high-current pulse through the laser diode(s) D_{L} is selected because all the remaining energy after the high-current pulse is shunted to ground and is wasted, thereby lowering a power efficiency of the pulsed laser diode driver.

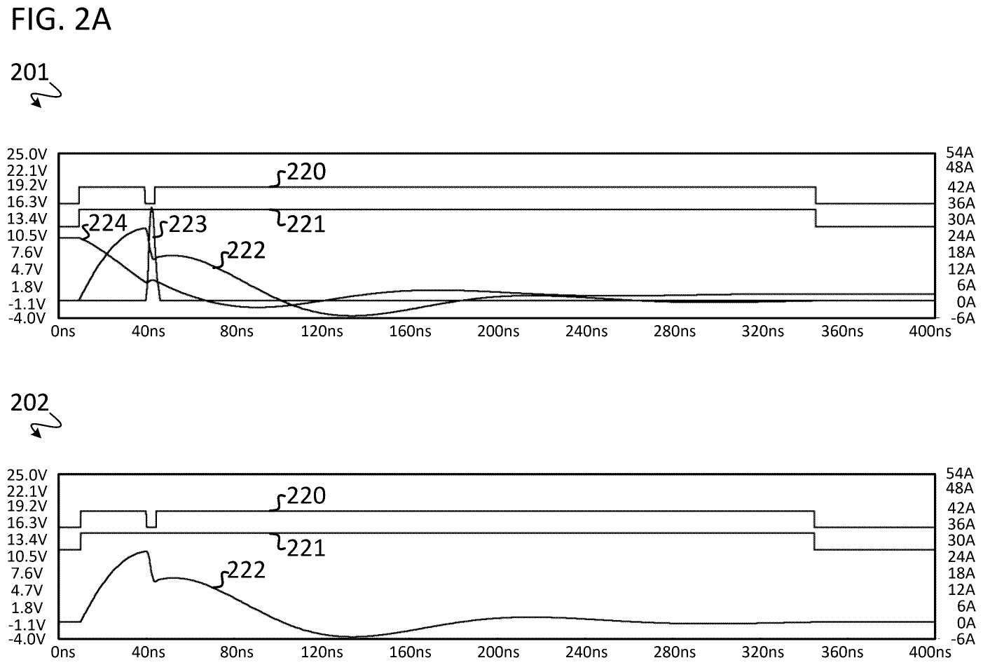

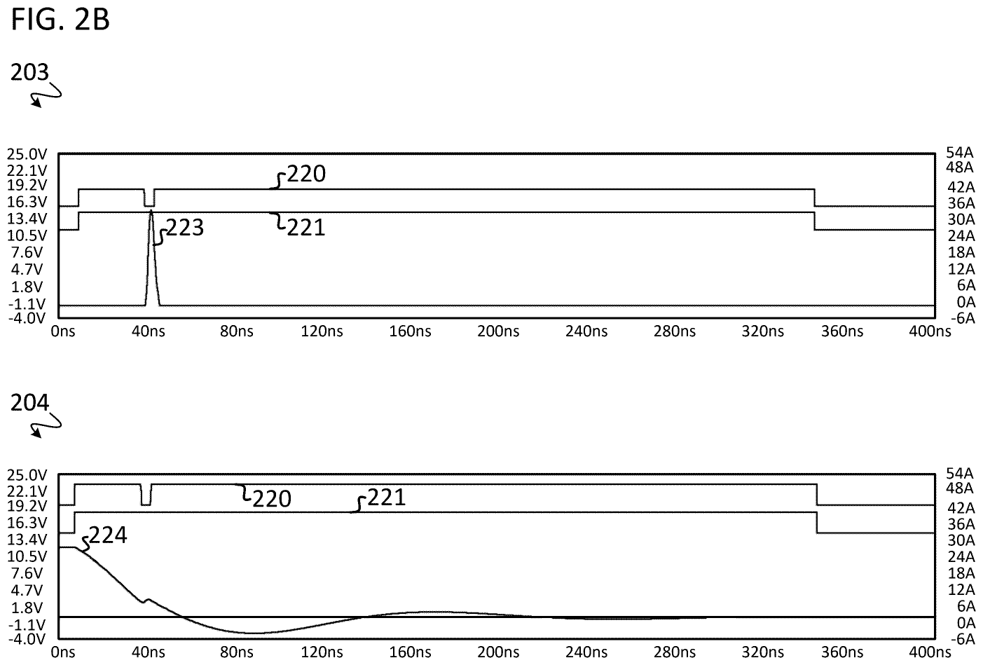

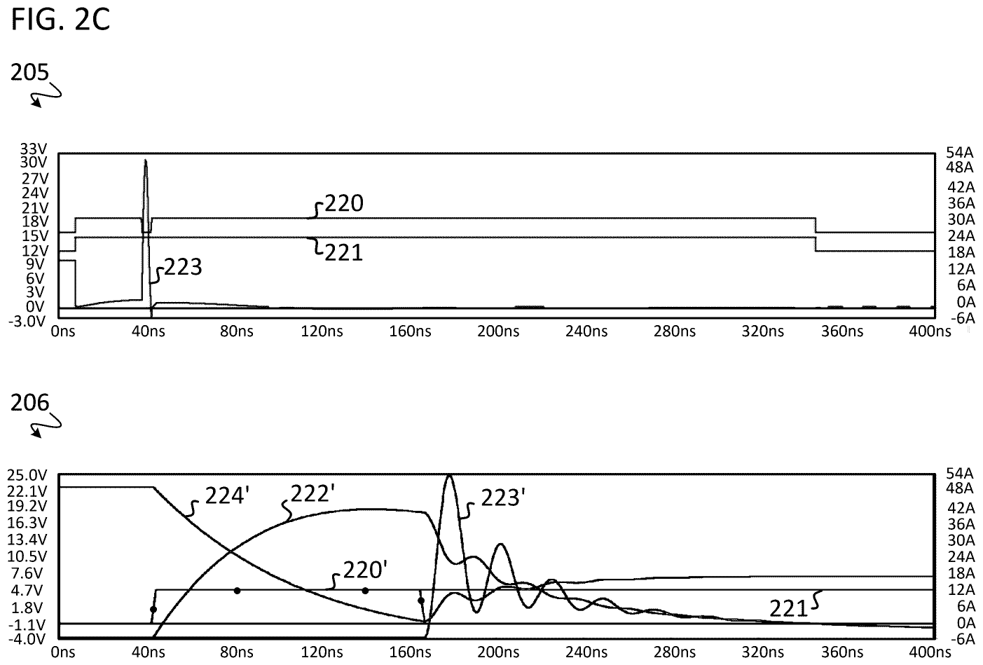

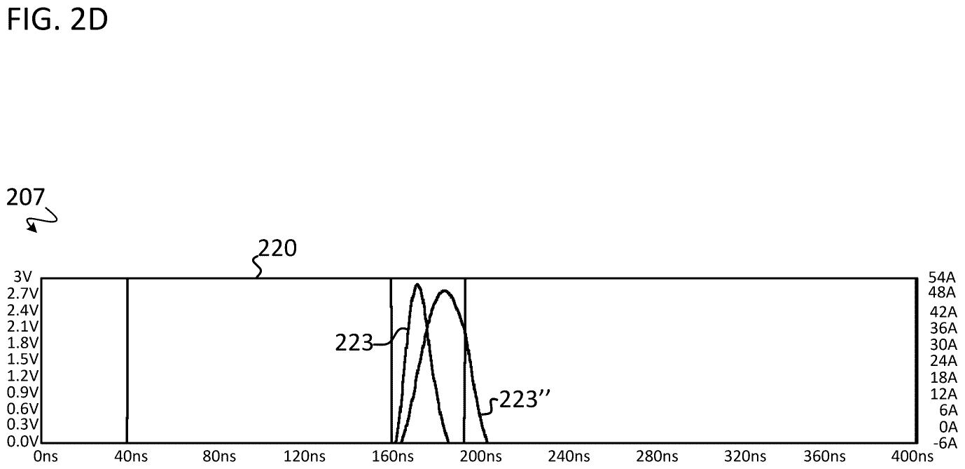

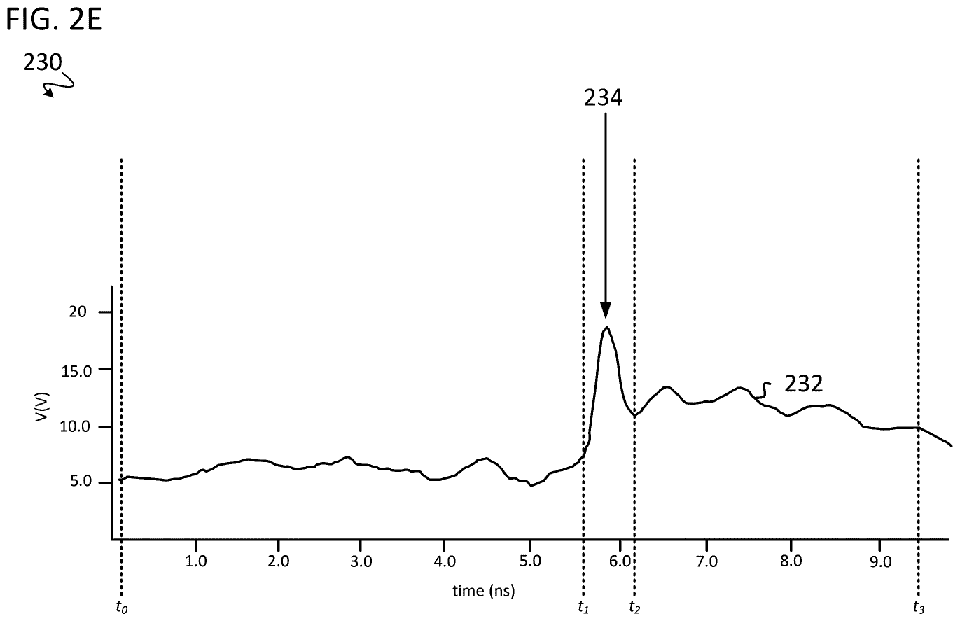

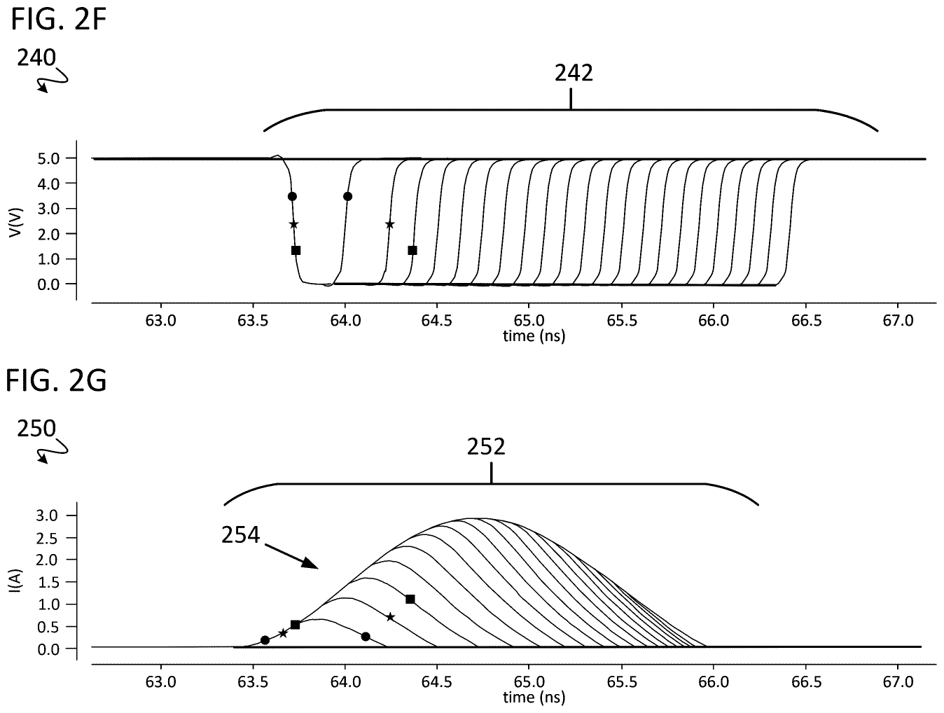

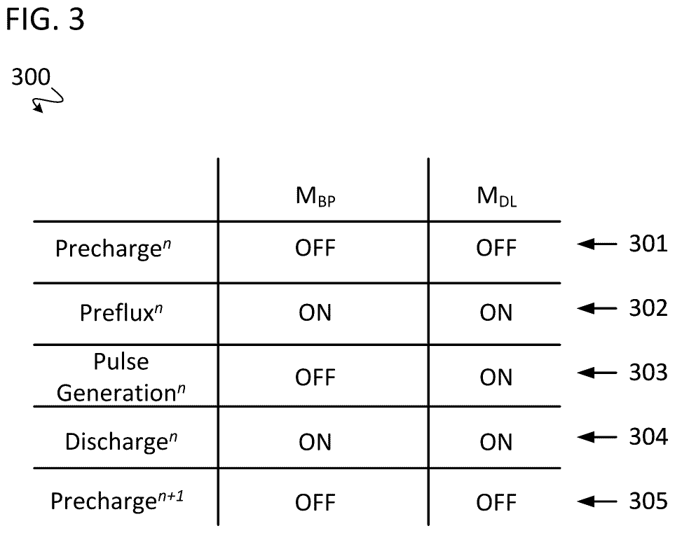

The controller 120 may be integrated with any embodiment of the pulsed laser diode drivers disclosed herein, or it may be a circuit or module that is external to any embodiment of the pulsed laser diode drivers disclosed herein. The controller 120 is operable to generate one or more gate drive signals having a voltage level that is sufficient to control one or more laser diode switches M_{DL} and one or more bypass switches M_{BP}. Additionally, the controller 120 is operable to sense a voltage and/or current at any of the nodes 110 and 112 and at nodes that are similar to, or the same as, the nodes 110 and 112 as described herein, or at still other nodes of the pulsed laser diode drivers disclosed herein. The controller 120 may include one or more timing circuits, look-up tables, processors, memory, or other modules to control the pulsed laser diode drivers disclosed herein. Operation of the pulsed laser diode drivers 101-103 is explained in detail with respect to simplified plots 201-207 of FIGS. 2A-2D, the simplified plots 230, 240, and 250 of FIGS. 2E-2G, and an example switching sequence 300 in FIG. 3.

FIGS. 2A-2D show simplified plots 201-207 of signals related to operation of the pulsed laser diode driver 101 shown in FIG. 1A for complete light-pulse emission, in accordance with some embodiments. However, signals related to the operation of the pulsed laser diode drivers 101-103, 401-404, 501-504, 601-604, 701-705, 801-802, and 901-902 are similar to, or are the same as, those shown in the simplified plots 201-207.

The simplified plot 201 illustrates a voltage plot of the bypass switch gate driver signal GATE_{BP} 220, a voltage plot of the laser diode switch gate driver signal GATE_{DL} 221, a current plot of the current i_{LS} through the inductor L_{S} 222, a current plot of the current i_{DL} through the laser diode D_{L} 223, and a voltage plot of the source voltage V_{S} 224 at the source capacitor C_{S}, all over the same duration of time. Details of these signals are described below. The voltage plots of the bypass switch gate driver signal GATE_{BP} 220 and the laser diode switch gate driver signal GATE_{DL} 221 have been level-shifted for readability, but are, in actuality, low voltage inputs. Additionally, the voltage plots of the bypass switch gate driver signal GATE_{BP} 220 and the laser diode switch gate driver signal GATE_{DL} 221 assume that the laser diode switch M_{DL} and the bypass switch M_{BP} are NFET devices. However, if PFET devices are used instead, the polarity of the bypass switch gate driver signal GATE_{BP} 220 and the laser diode switch gate driver signal GATE_{DL} 221 are inverted.

Upon receiving (e.g., from the controller 120) an asserted level of the bypass switch gate driver signal GATE_{Bp} 220 at the gate node of the bypass switch M_{BP}, the bypass switch M_{BP} is enabled (i.e., transitioned to an ON-state). Similarly, upon receiving (e.g., from the controller 120) an asserted level of the laser diode switch gate driver signal GATE_{DL} 221 at the gate node of the laser diode switch M_{DL}, the laser diode switch M_{DL} is enabled. As highlighted in the plot 202, when the bypass switch M_{BP} is enabled, the rising current i_{LS} 222 begins to flow through the inductor L_{S}, thereby building magnetic flux at the inductor L_{S}. When the current i_{L}S 222 has reached a desired level (e.g., as determined by the controller 120 using sensed current, voltage, a timer circuit, or as determined by design constraints), a de-asserted level of the bypass switch gate driver signal GATE_{BP} 220 is received (e.g., from the controller 120) at the gate node of the bypass switch M_{BP}, thereby disabling the bypass switch M_{BP} (i.e., transitioned to an OFF-state). As described below, the duration of time that the bypass switch gate driver signal GATE_{BP} 220 remains de-asserted advantageously controls truncation of the light pulse emitted by the laser diode D_{L} after the gain-switching spike.

As highlighted in the plot 203, when the bypass switch M_{BP} is disabled, the current i_{LS} 222 which has built up through the inductor L_{S}, having no other current path, is redirected through the laser diode D_{L}, causing a short (e.g., 100 ps-5 ns), high-current (e.g., >30 A) pulse to flow through the laser diode D_{L}, thereby causing the laser diode D_{L} to emit a pulse of laser light. Because energy in the form of flux has been stored at the inductor L_{S}, the high-current pulse i_{DL} that flows through the laser diode D_{L} can be significantly greater than the current i_{LS} that flows through the inductor L_{S}. Values of the reactive components of the laser diode drivers disclosed herein can be advantageously selected to generate a desired current amplitude of the high-current pulse i_{DL}.

After a full or truncated light-pulse emission from the laser diode D_{L}, the bypass switch M_{BP} is reenabled by an asserted level of the bypass switch gate driver signal GATE_{Bp} 220, and the laser diode switch M_{DL} is maintained in an enabled state by an asserted level of the laser diode switch gate driver signal GATE_{DL} 221. As highlighted in the plot 204, the bypass switch M_{BP} and the laser diode switch M_{DL} are both advantageously maintained in the enabled state as the source voltage V_{S} 224 stored at the source capacitor C_{S} is discharged. As highlighted in the plot 205, while the bypass switch M_{BP} and the laser diode switch M_{DL} are maintained in the enabled state, the current i_{DL} 223 through the laser diode D_{L} (and importantly, through the parasitic inductance L_{DL} of the laser diode D_{L}) diminishes to zero. Thereafter, both the bypass switch M_{BP} and the laser diode switch M_{DL} are disabled by de-asserted levels (e.g., from the controller 120) of the bypass switch gate driver signal GATE_{Bp} 220 and the laser diode switch gate driver signal GATE_{DL} 221. Because the laser diode switch M_{DL} is not disabled until a current through the parasitic inductance L_{DL} of the laser diode D_{L} has diminished to zero, a high voltage spike advantageously does not develop at the anode of the laser diode D_{L} as there is no rapid change in current through the parasitic inductance L_{DL}. Because such high voltage spikes are advantageously mitigated, the laser diode switch M_{DL} does not need to be selected to withstand high voltages, thereby simplifying the design and reducing the cost of the pulsed laser diode drivers disclosed herein as compared to conventional solutions. Additionally, because such high voltage spikes are mitigated, the pulsed laser diode drivers disclosed herein do not require voltage snubbing circuits that are commonly used in conventional solutions, thereby further simplifying the design and reducing the cost of the pulsed laser diode drivers disclosed herein as compared to conventional solutions.

The high-current pulse 223 is a first and largest peak of the resonant waveform developed by reactive components of the pulsed laser diode driver circuit. These reactive components include the source capacitor C_{S}, the inductor L_{S}, the parasitic inductance L_{DL} of the laser diode D_{L}, and the bypass capacitor C_{BP}. In addition to the advantages described above, the bypass switch M_{BP} also reduces subsequent resonant waveform “ringing” of the resonant waveform after the high-current pulse 223 is generated. As shown in the plot 206, if a bypass switch gate driver signal GATE_{BP} 220′ is not asserted after a high-current pulse i_{DL} 223′ is generated, ringing occurs on the current i_{L}S 222′ through the inductor L_{S}, on the current i_{DL} 223′ through the laser diode D_{L}, and on the source voltage V_{S} 224′ at the source capacitor C_{S}. As shown, the high-current pulse 223 through the laser diode D_{L} corresponds to a peak (e.g., maximum, or local maximum, amplitude) current of a resonant waveform of current i_{DL} 223′ developed at the anode of the laser diode D_{L}.

As previously described, values of the source capacitor C_{S}, the inductor L_{S} and the bypass capacitor C_{BP} may be advantageously selected or “tuned” by a designer to meet desired performance criteria of the pulsed laser diode driver disclosed herein. For example, a capacitance value of the bypass capacitor C_{BP} may be selected based on a desired pulse width of the current i_{DL} through the laser diode D_{L}. The plot 207 of FIG. 2D shows the pulse 223 generated when the capacitance of the bypass capacitor C_{BP} is equal to 1 nF, and a pulse 223″ generated when the capacitance of the bypass capacitor C_{BP} is equal to 4 nF. In use cases where a wider pulse, such as the pulse 223″, is desired, the source voltage V_{S} may be raised accordingly. Additionally, in some embodiments, the width of the de-asserted portion of the bypass switch gate driver signal GATE_{BP} 220 is widened to accommodate a wider pulse or narrowed to truncate the pulse after emission of the gain-switching spike.

FIG. 2E shows a simplified plot 230 of signal 232 related to the operation of the gain-switching spike pulsed laser diode drivers disclosed herein, in accordance with some embodiments. Also shown are times of interest t₀-t₃. The plot 232 illustrates an example of a light pulse (expressed in terms of Voltage) emitted by a laser diode that is the same, or similar to, the laser diode D_{L} shown in FIG. 1A. From time to through t₁, no light is emitted by the laser diode D_{L} (i.e., during a precharge and preflux portion of a switching cycle of the pulsed laser diode driver 101).

Upon application of the current i_{DL} through the laser diode D_{L}, carrier density thereof increases until it reaches the threshold necessary for lasing, thereby transitioning the laser diode D_{L} from an off state to an active state. At this juncture, roughly between time t₁ and time t₂, a rapid onset of stimulated emission occurs, leading to a sharp initial spike in output power known as the gain-switching spike 234. Following this spike, from time t₂ to about time t₃, the laser diode D_{L} experiences relaxation oscillations due to the dynamic interplay between carrier density and photon density. These oscillations gradually dampen as current through the laser diode D_{L} stabilizes, ultimately reaching a steady-state operation after about time t₃, characterized by a constant output power where the rate of carrier injection balances the rate of stimulated emission and losses.

As mentioned above, the duration of time that the bypass switch gate driver signal GATE_{BP} is de-asserted advantageously controls the light pulse width. In some embodiments, the bypass switch gate driver signal GATE_{BP} is configured to be of a duration that is slightly longer than the gain-switching spike and significantly shorter in duration than the time required to reach steady-state operation of the laser diode D_{L}. In some embodiments, the bypass switch gate driver signal GATE_{BP} is configured to truncate the light pulse emission after the gain-switching spike portion of the light pulse concludes but before the resonant portion of the light pulse concludes. Such configuration may include a timing configuration of the controller 120 and/or be in response to a sensed voltage or current flow by the controller 120, as is understood in the art. For example, because the controller 120 is aware of, and controls, a total pulse width duration for the resonant high-current pulse, truncating the pulse emission before the normal total pulse width duration time has elapsed may be achieved by an end-user configurable timing setting of the controller 120 using a digital command and/or configuration pins or resistors. The gain-switching spike pulsed laser diode driver control methods are applicable to any of any of the laser diode driver topologies disclosed herein.

FIGS. 2F-2G show simplified corresponding plots 240 and 250 of signals related to the operation of the gain-switching spike pulsed laser diode drivers disclosed herein, in accordance with some embodiments. A plot 242 corresponds to the bypass switch gate driver signal GATE_{BP}, and a plot 252 corresponds to the current i_{DL} through the laser diode D_{L}. In the example shown, as the duration of time that the bypass switch gate driver signal GATE_{BP} 242 remains de-asserted is adjusted across a range of values, the duration of a peak amplitude pulse of the current i_{DL} 252 through the laser diode correspondingly shortens, but a leading edge 254 of the peak amplitude pulse, which is what causes the emission of the gain-switching spike (not shown) advantageously does not change.

FIG. 3 illustrates a portion of an example switching sequence 300 for operation of the pulsed laser diode drivers 101-103 shown in FIG. 1A-B, in accordance with some embodiments, and as was described with reference to FIGS. 2A-C. However, the switching sequence 300 is similar to, or the same as, respective switching sequences related to the operation of other embodiments of the pulsed laser diode drivers disclosed herein, including but not limited to the pulsed laser diode drivers 401-404, 501-504, 601-604, 701-705, 801-802, and 901-902.

At a precharge step 301, the bypass switch M_{BP} and the laser diode switch M_{DL} are off (i.e., not conducting). During the precharge step 301, the source capacitor C_{S} is charged through the source resistor R_{S}. At a preflux step 302, the bypass switch M_{BP} and the laser diode switch M_{DL} are transitioned to an ON-state, thereby allowing the current i_{L}S to flow through the inductor L_{S} to store energy in the form of magnetic flux at the inductor L_{S}. Even though both of the switches (M_{DL}, M_{BP}) are in an ON-state at the preflux step 302, the bypass path through the bypass switch M_{BP} will carry all of the current i_{LS} because a bandgap voltage of the laser diode D_{L} needs to be overcome to allow current to flow through the laser diode D_{L}.

In some embodiments, the laser diode switch M_{DL} is transitioned to an ON-state after the bypass switch M_{BP} is transitioned to an ON-state. At a pulse generation step 303, the bypass switch M_{BP} is transitioned to an OFF-state while the laser diode switch M_{DL} is maintained in an ON-state, thereby generating the high-current pulse through the laser diode D_{L}. When the bypass switch M_{BP} is transitioned to the OFF-state, voltage at the anode of the laser diode D_{L} rises quickly, until the bandgap voltage of the laser diode D_{L} is overcome and the laser diode D_{L} begins to conduct current. Because of a resonant circuit formed by the bypass capacitor C_{BP} and the parasitic inductance L_{DL} of the laser diode D_{L}, the voltage formed at the anode of the laser diode D_{L} will advantageously rise as high as necessary to overcome the bandgap voltage of the laser diode D_{L} and will generally be higher than the source voltage V_{S}. As described above, the bypass switch M_{BP} may then be transitioned to an ON-state to truncate light pulse emission either immediately after, or after a configurable amount of time following, the gain-switching spike of the light pulse.

At a discharge step 304, the bypass switch M_{BP} and the laser diode switch M_{DL} are configured in an ON-state to drain charge stored at the source capacitor C_{S}, thereby reducing the current i_{DL} through the parasitic inductance L_{DL} to advantageously eliminate a high voltage spike at the anode of the laser diode D_{L} when the laser diode switch M_{DL} is transitioned to an OFF-state. At step 305, the bypass switch M_{BP} and the laser diode switch M_{DL} are transitioned to an OFF-state, thereby returning to the precharge state at step 301. Because the source voltage V_{S} at the source capacitor C_{S} is completely discharged at the end of the discharge step 304, there is very little current through the laser diode D_{L}. Thus, there is advantageously very little overshoot when the switches M_{DL}, M_{BP} are transitioned to the OFF-state at step 305, thereby preventing damage to the laser diode D_{L} and the switches M_{DL}, M_{BP}. The time interval of the overall pulse and bypass signals is selected, in some embodiments, such that the source capacitor C_{S} is fully discharged before the switches M_{DL}, M_{BP} are transitioned to the OFF-state at step 305.

Other topologies of pulsed laser drivers, having the same or similar advantages and having similar operation as that of the pulsed laser diode drivers 101-103, are disclosed below. The example topologies disclosed herein are not an exhaustive list of possible topologies that have the same or similar advantages and similar operation as that of the pulsed laser diode drivers 101-103. For example, one of skill in the art will appreciate that some modifications can be made while still adhering to the general principle of operation disclosed herein. Such modifications include placement of the bypass capacitor C_{BP}, component values, and the addition of serially connected components that provide a DC current path.

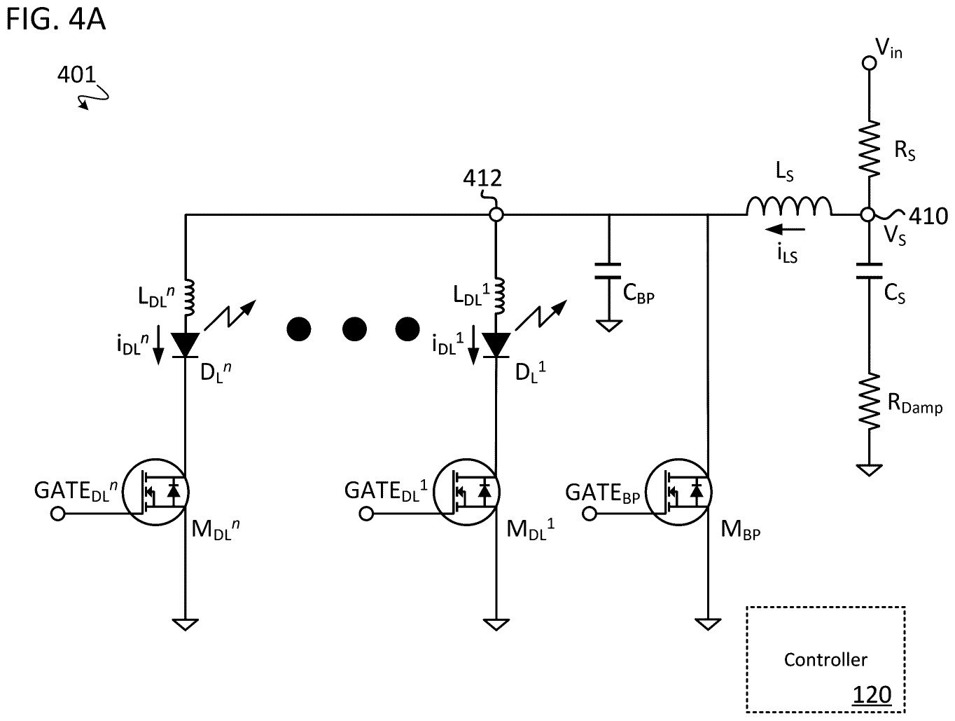

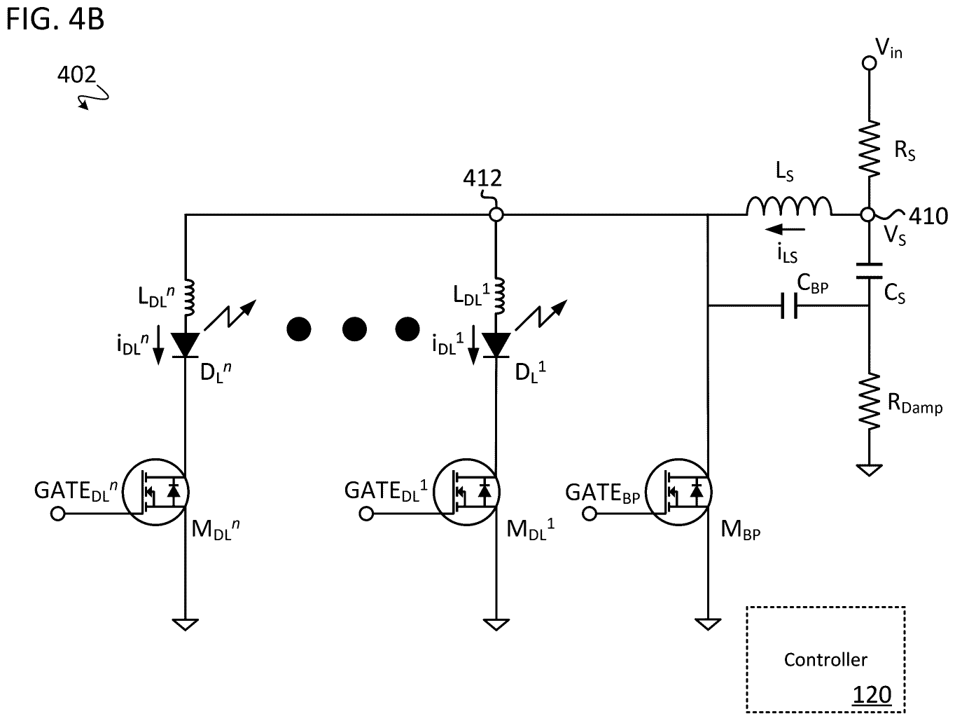

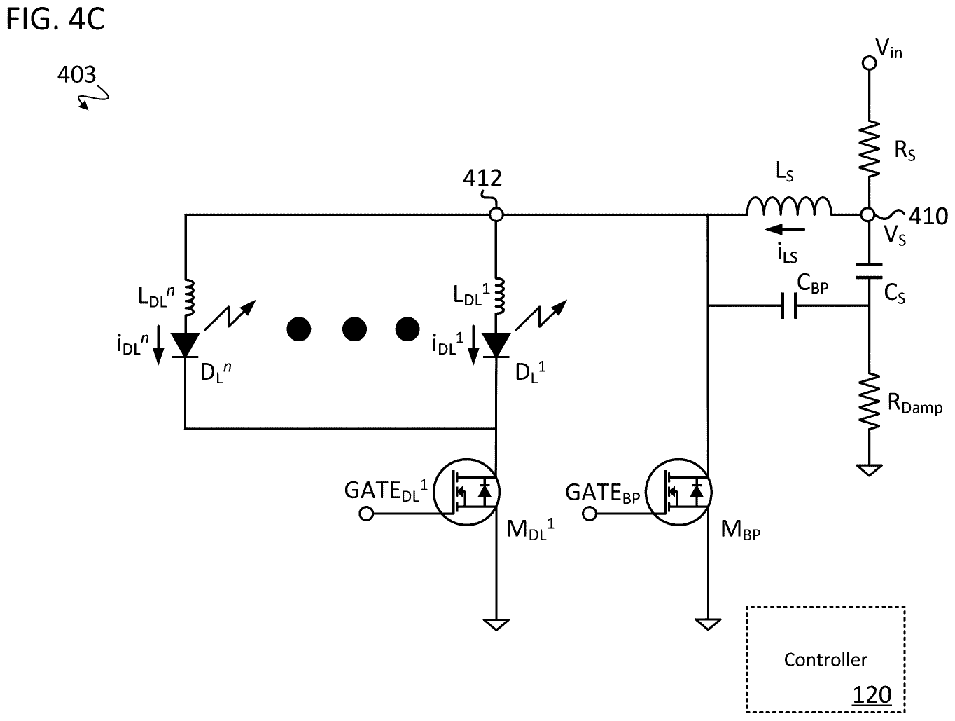

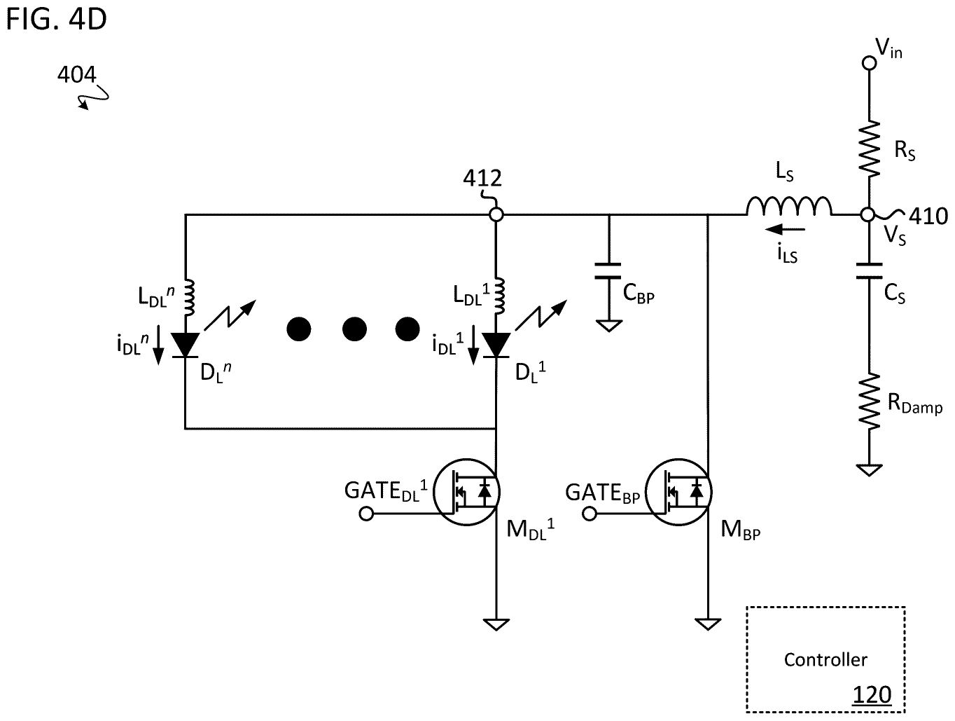

FIGS. 4A-D are simplified circuit schematics of pulsed laser diode drivers 401-404 of a second general topology that is configured to drive two or more laser diodes in a common anode arrangement, in accordance with some embodiments. The pulsed laser diode drivers 401-404 each generally include the source resistor R_{S}, the source capacitor C_{S}, the damping resistor R_{Damp}, the inductor L_{S}, the bypass capacitor C_{BP}, two or more laser diodes D_{L}¹-D_{L}n, and the bypass switch M_{BP}. The pulsed laser diode drivers 401-402 each include two or more laser diode switches M_{DL}¹-M_{DL}ⁿ, whereas the pulsed laser diode drivers 403-404 include a single laser diode switch M_{DL}¹.

Also shown is the controller 120, nodes 410, 412, respective parasitic inductances L_{DL}¹-L_{DL}ⁿ of the laser diodes D_{L}¹-D_{L}n, the DC input voltage Vᵢₙ, the source voltage V_{S} at the source capacitor C_{S}, the current i_{LS} through the inductor L_{S}, respective currents i_{DL}¹-i_{DL}ⁿ through the laser diodes D_{L}¹-D_{L}ⁿ, and the bypass switch gate driver signal GATE_{BP}. The pulsed laser diode drivers 401-402 each utilize respective laser diode switch gate driver signals GATE_{DL}¹-GATE_{DL}ⁿ, whereas the pulsed laser diode drivers 403-404 use a single laser diode switch gate driver signal GATE_{DL}¹. Electrical connections of the pulsed laser diode drivers 401-404 are similar to, or the same as, those described with respect to the pulsed laser diode drivers 101-103. Topologies of the pulsed laser diode drivers 401-404 vary with respect to the placement of the bypass capacitor C_{BP}.

As shown in the simplified circuit schematics of the pulsed laser diode driver 401 of FIG. 4A and the pulsed laser diode driver 404 of FIG. 4D, in some embodiments the first terminal of the bypass capacitor C_{BP} is directly electrically connected to the second terminal of the inductor L_{S} and to the anodes of the laser diodes D_{L}¹-D_{L}ⁿ. In such embodiments, the second terminal of the bypass capacitor C_{BP} is directly electrically connected to the bias voltage node. As shown in the simplified circuit schematic of the pulsed laser diode drivers 402-403 of FIGS. 4B-C, in some embodiments the first terminal of the bypass capacitor C_{BP} is directly electrically connected to the second terminal of the inductor L_{S} and to the respective anodes of the laser diodes D_{L}¹-D_{L}ⁿ. In such embodiments, the second terminal of the bypass capacitor C_{BP} is directly electrically connected to the second terminal of the source capacitor C_{S} and to the first terminal of the damping resistor R_{Damp}. In some embodiments, values of the DC input voltage Vᵢₙ, inductance of the inductor L_{S}, capacitance of the source capacitor C_{S}, resistance of the damping resistor R_{Damp}, and capacitance of the bypass capacitor C_{BP} are similar to, or the same as, those respective values as described with reference to the pulsed laser diode drivers 101-103. However, the values of the DC input voltage Vᵢₙ, inductance of the inductor L_{S}, capacitance of the source capacitor C_{S}, resistance of the damping resistor R_{Damp}, and capacitance of the bypass capacitor C_{BP} can advantageously be selected to achieve desired operation of the pulsed laser diode drivers 401-404 (e.g., a charge time, a pulse width, a pulse voltage, a pulse current level). Operation of the pulsed laser diode drivers 401-404 is similar to, or the same as, operation of the pulsed laser diode drivers 101-103 as explained in detail with respect to the simplified plots 201-206 of FIGS. 2A-D, as well as the example switching sequence 300 shown in FIG. 3.

In some embodiments, the controller 120 is configured to determine how many of the laser diodes D_{L}¹-D_{L}ⁿ are enabled simultaneously and to adjust a voltage level of the DC input voltage Vᵢₙ in accordance with that determination to supply a required amount of current (e.g., using a digitally adjustable voltage source (described below) controlled by a digital control signal from the controller 120).

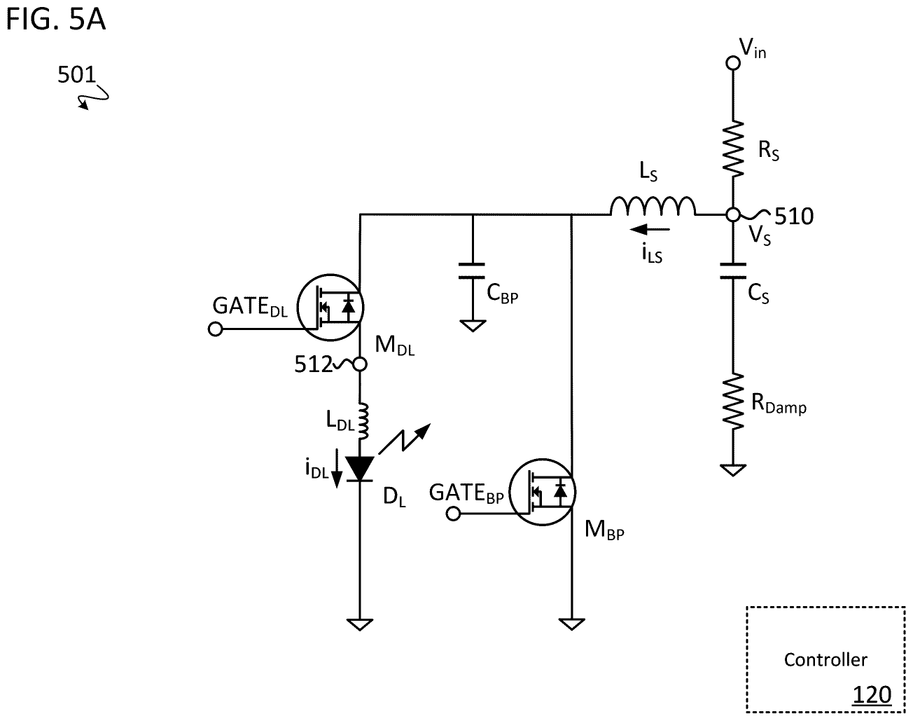

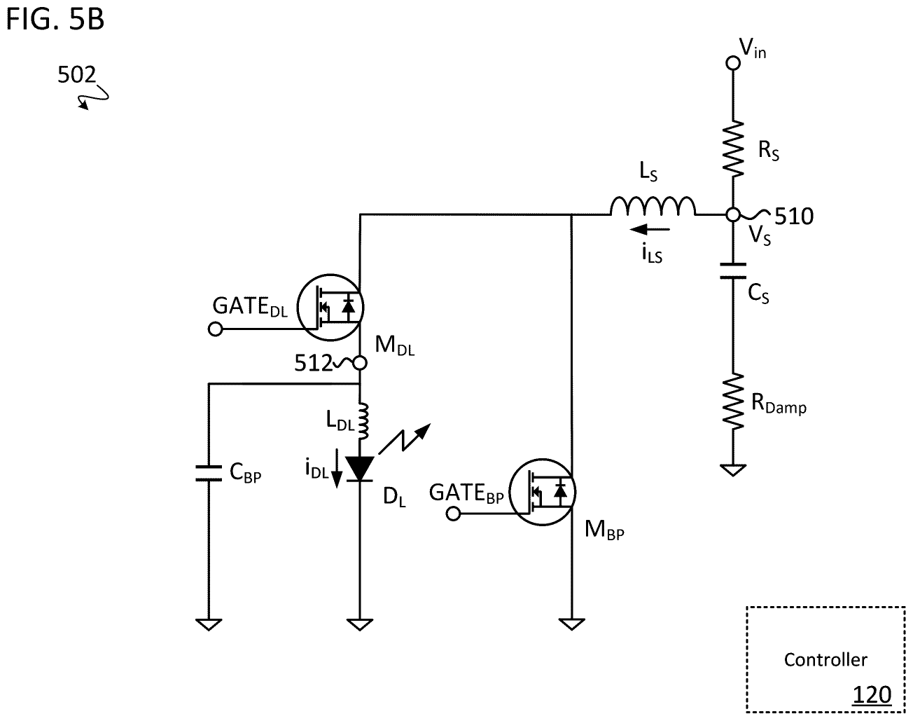

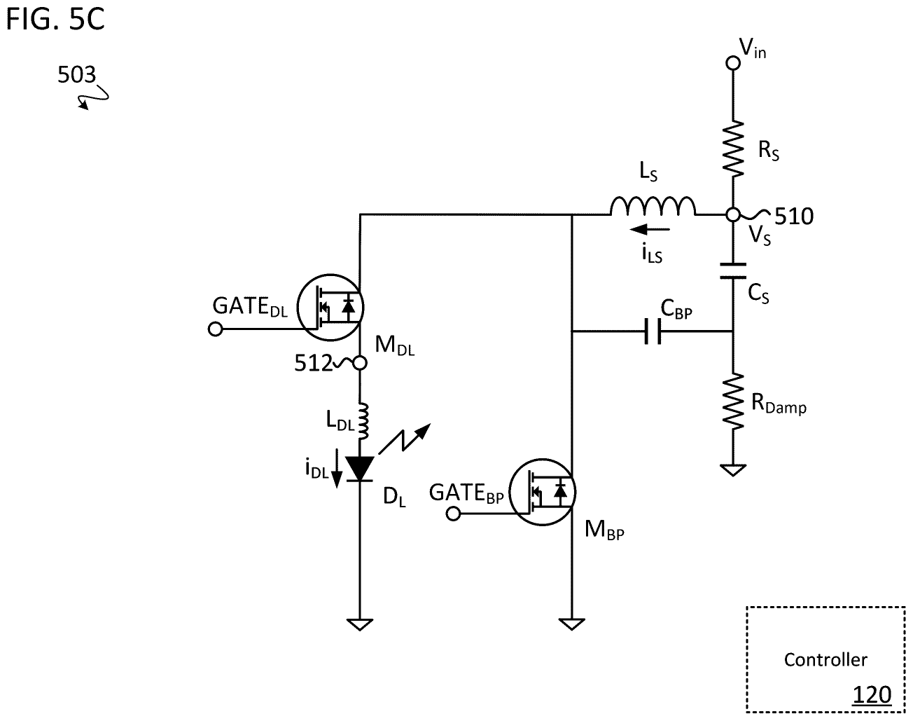

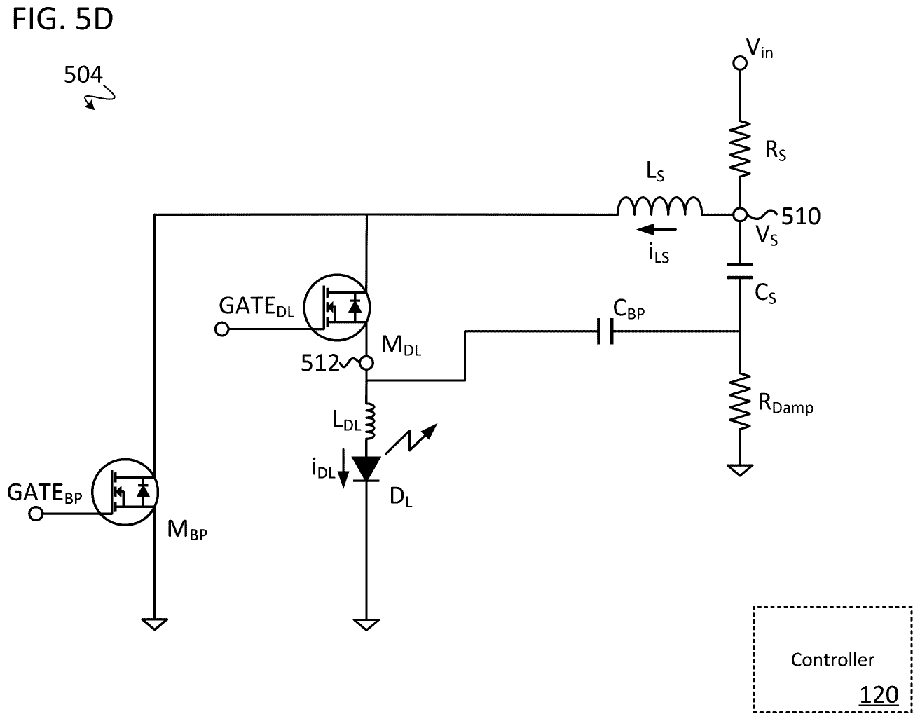

FIGS. 5A-D are simplified circuit schematics of pulsed laser diode drivers 501-504 of a third general topology that is configured to drive a laser diode using a high-side switch, in accordance with some embodiments. The pulsed laser diode drivers 501-504 each generally include the source resistor R_{S}, the source capacitor C_{S}, the damping resistor R_{Damp}, the inductor L_{S}, the bypass capacitor C_{BP}, the laser diode D_{L}, the bypass switch M_{BP}, and the laser diode switch M_{DL}. The laser diode switch M_{DL} is configured as a high-side switch.

Also shown is the controller 120, nodes 510, 512, the parasitic inductance L_{DL} of the laser diode D_{L}, the DC input voltage Vᵢₙ, the source voltage V_{S} at the source capacitor C_{S}, the current i_{L}S through the inductor L_{S}, the current i_{DL} through the laser diode D_{L}, the bypass switch gate driver signal GATE_{Bp}, and the laser diode switch gate driver signal GATE_{DL}. Most of the electrical connections of the pulsed laser diode drivers 501-504 are similar to, or the same as, those described with respect to the pulsed laser diode drivers 101-103. However, in contrast to the low-side configuration of the pulsed laser diode drivers 101-103, the drain node of the laser diode switch M_{DL} is directly electrically connected to the second terminal of the inductor L_{S} and to the drain node of the bypass switch M_{BP}. The source node of the laser diode switch M_{DL} is directly electrically connected to the anode of the laser diode D_{L}, and the cathode of the laser diode D_{L} is directly electrically connected to the bias voltage node. Topologies of the pulsed laser diode drivers 501-504 vary with respect to placement of the bypass capacitor C_{BP}.

As shown in the simplified circuit schematic of the pulsed laser diode driver 501 of FIG. 5A, in some embodiments the first terminal of the bypass capacitor C_{BP} is directly electrically connected to the second terminal of the inductor L_{S} and to the drain node of the laser diode switch M_{DL}. In such embodiments, the second terminal of the bypass capacitor C_{BP} is directly electrically connected to the bias voltage node. As shown in the simplified circuit schematic of the pulsed laser diode driver 502 of FIG. 5B, in some embodiments the first terminal of the bypass capacitor C_{BP} is directly electrically connected to the source node of the laser diode switch M_{DL} and to the anode of the laser diode D_{L}. In such embodiments, the second terminal of the bypass capacitor C_{BP} is directly electrically connected to the bias voltage node. As shown in the simplified circuit schematic of the pulsed laser diode driver 503 of FIG. 5C, in some embodiments the first terminal of the bypass capacitor C_{BP} is directly electrically connected to the second terminal of the inductor L_{S}, to the drain node of the bypass switch M_{BP}, and to the drain node of the laser diode switch M_{DL}. In such embodiments, the second terminal of the bypass capacitor C_{BP} is directly electrically connected to the second terminal of the source capacitor C_{S} and to the first terminal of the damping resistor R_{Damp}. As shown in the simplified circuit schematic of the pulsed laser diode driver 504 of FIG. 5D, in some embodiments the first terminal of the bypass capacitor C_{BP} is directly electrically connected to the source node of the laser diode switch M_{DL} and the anode of the laser diode D_{L}. In such embodiments, the second terminal of the bypass capacitor C_{BP} is directly electrically connected to the second terminal of the source capacitor C_{S} and to the first terminal of the damping resistor R_{Damp}.

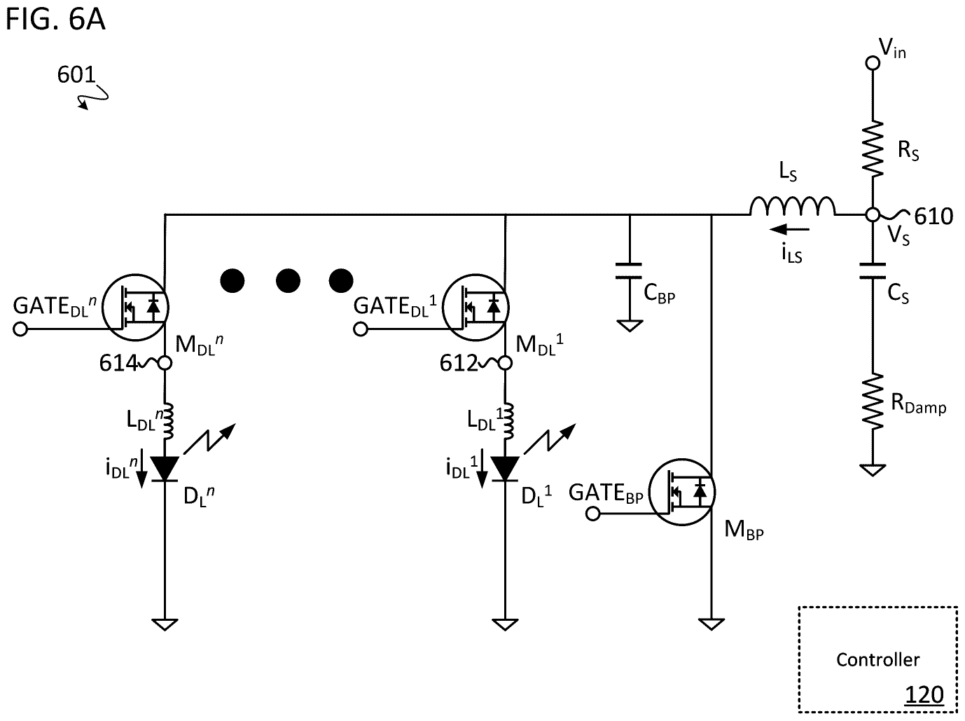

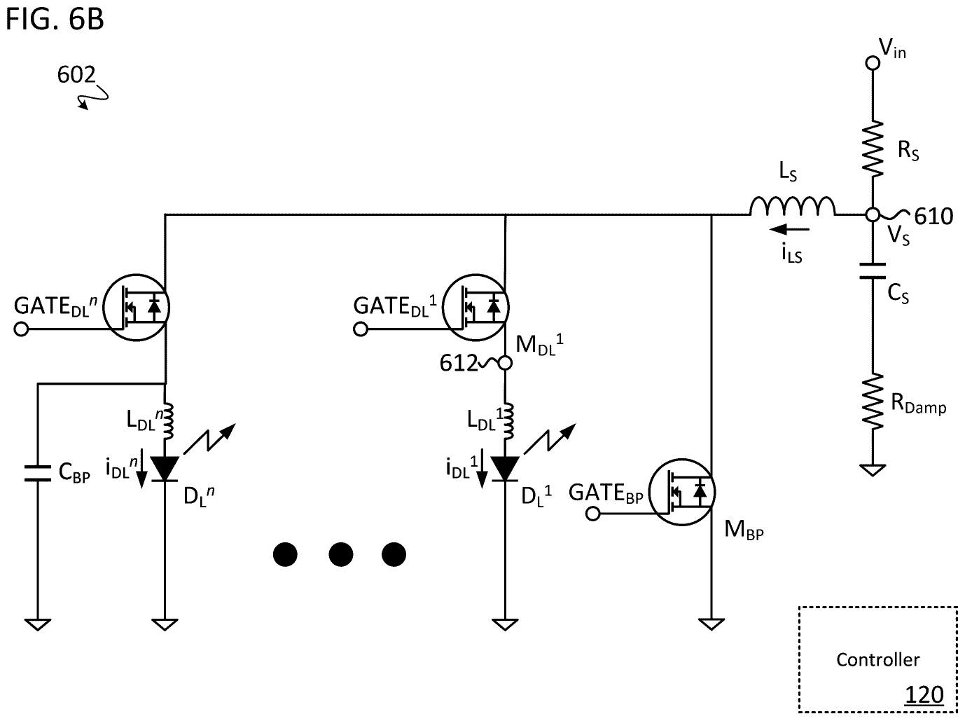

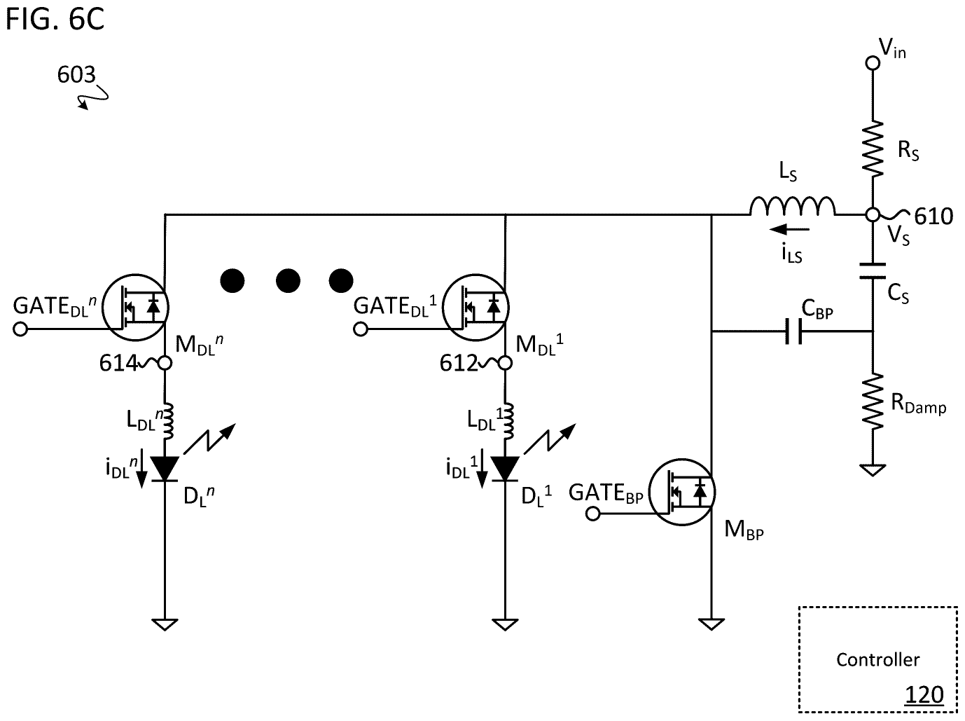

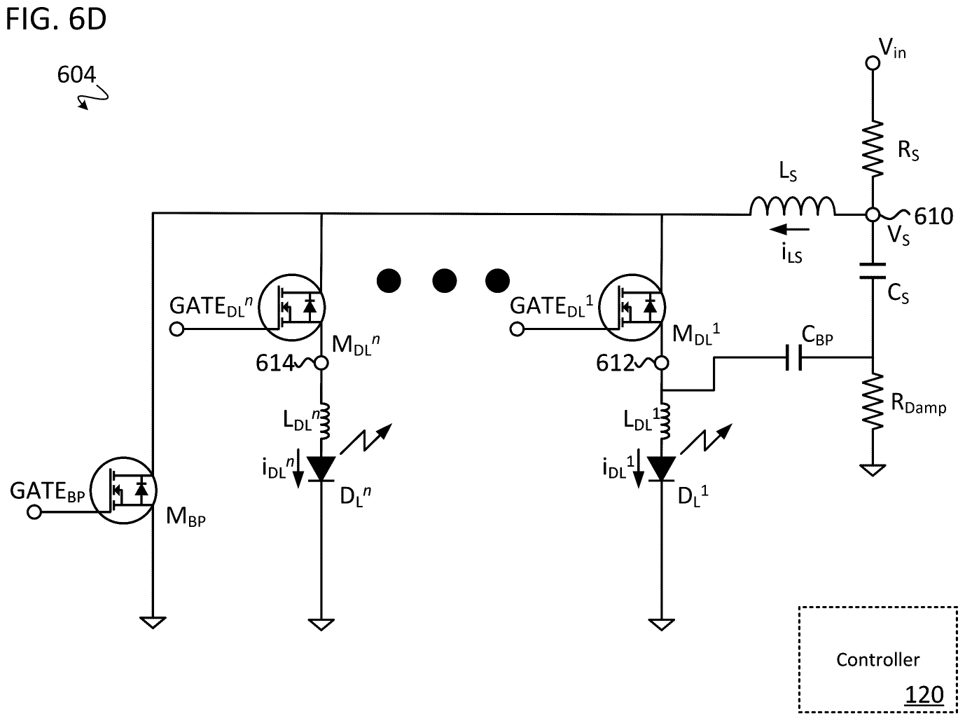

FIGS. 6A-D are simplified circuit schematics of pulsed laser diode drivers 601-604 of a fourth general topology that is configured to drive two or more laser diodes in a common cathode configuration using a high-side switch, in accordance with some embodiments. The pulsed laser diode drivers 601-604 each generally include the source resistor R_{S}, the source capacitor C_{S}, the damping resistor R_{Damp}, the inductor L_{S}, the bypass capacitor C_{BP}, the bypass switch M_{BP}, two or more laser diodes D_{L}¹-D_{L}ⁿ, and two or more respective laser diode switches M_{DL}¹-M_{DL}ⁿ.

Also shown is the controller 120, nodes 610, 612, 614, respective parasitic inductances L_{DL}¹-L_{DL}ⁿ of the laser diodes D_{L}¹-D_{L}ⁿ, the DC input voltage Vᵢₙ, the source voltage V_{S} at the source capacitor C_{S}, the current i_{L}S through the inductor L_{S}, respective currents i_{DL}¹-i_{DL}ⁿ through the laser diodes D_{L}¹-D_{L}ⁿ, the bypass switch gate driver signal GATE_{BP}, and respective laser diode switch gate driver signals GATE_{DL}¹-GATE_{DL}ⁿ of the laser diode switches M_{DL}¹-M_{DL}ⁿ.

Most of the electrical connections of the pulsed laser diode drivers 601-604 are similar to, or are the same as, those described with respect to the pulsed laser diode drivers 501-504. However, topologies of the pulsed laser diode drivers 601-604 vary from one another with respect to placement of the bypass capacitor C_{BP}.

As shown in the simplified circuit schematic of the pulsed laser diode driver 601 of FIG. 6A, in some embodiments the first terminal of the bypass capacitor C_{BP} is directly electrically connected to the second terminal of the inductor L_{S} and to respective drain nodes of the laser diode switches M_{DL}¹-M_{DL}ⁿ and the bypass switch M_{BP}. In such embodiments, the second terminal of the bypass capacitor C_{BP} is directly electrically connected to the bias voltage node. As shown in the simplified circuit schematic of the pulsed laser diode driver 602 of FIG. 6B, in some embodiments the first terminal of the bypass capacitor C_{BP} is directly electrically connected to the source node of any of the laser diode switches (M_{DL}n is shown) and to the anode of the laser diode coupled to that laser diode switch (D_{L}ⁿ is shown). In such embodiments, the second terminal of the bypass capacitor C_{BP} is directly electrically connected to the bias voltage node. In some embodiments, multiple bypass capacitors C_{BP} are used, each of the bypass capacitors being connected across a respective laser diode. As shown in the simplified circuit schematic of the pulsed laser diode driver 603 of FIG. 6C, in some embodiments the first terminal of the bypass capacitor C_{BP} is directly electrically connected to the second terminal of the inductor L_{S} and to respective drain nodes of the laser diode switches M_{DL}¹-M_{DL}ⁿ and the bypass switch M_{BP}. In such embodiments, the second terminal of the bypass capacitor C_{BP} is directly electrically connected to the second terminal of the source capacitor C_{S} and to the first terminal of the damping resistor R_{Damp}. As shown in the simplified circuit schematic of the pulsed laser diode driver 604 of FIG. 6D, in some embodiments the first terminal of the bypass capacitor C_{BP} is directly electrically connected to the source node of any of the laser diode switches (M_{DL}¹ is shown) and to the anode of the laser diode coupled to that laser diode switch (D_{L}¹ is shown). In such embodiments, the second terminal of the bypass capacitor C_{BP} is directly electrically connected to the second terminal of the source capacitor C_{S} and to the first terminal of the damping resistor R^{Damp}. In some embodiments, multiple bypass capacitors C_{BP} are used, each of the bypass capacitors C_{BP} having a first terminal that is directly electrically connected to a respective anode of each laser diode and a second terminal that is directly electrically connected to the second terminal of the source capacitor C_{S} and to the first terminal of the damping resistor R_{S}.

In some embodiments, the controller 120 is operable to determine how many of the laser diodes D_{L}¹-D_{L}ⁿ are enabled simultaneously and to adjust a voltage level of the DC input voltage Vᵢₙ in accordance with that determination to supply a required amount of current (e.g., using a digitally adjustable voltage source (described below) controlled by a digital control signal from the controller 120).

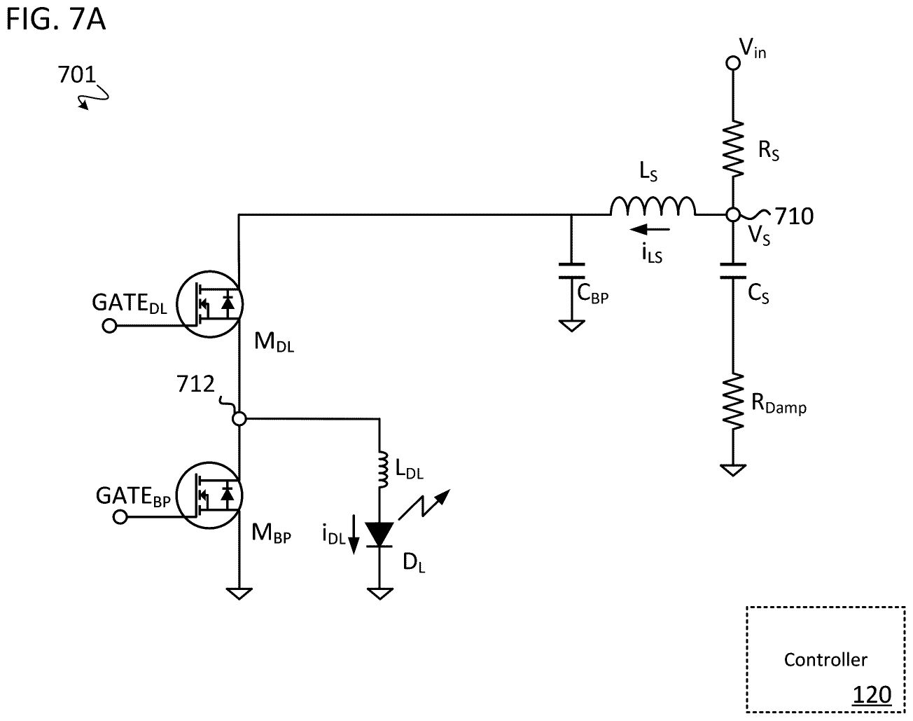

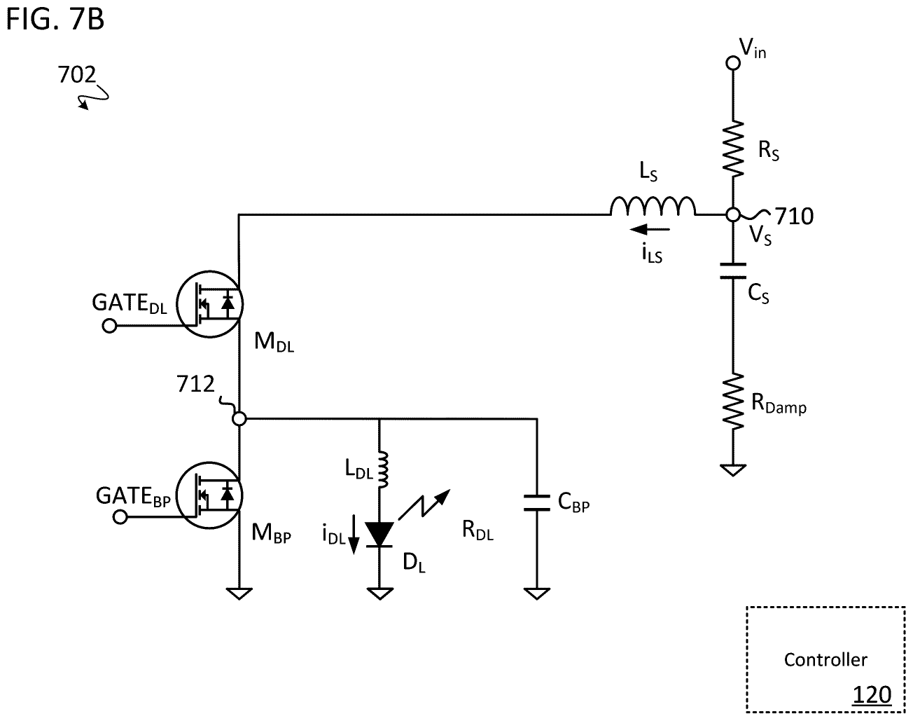

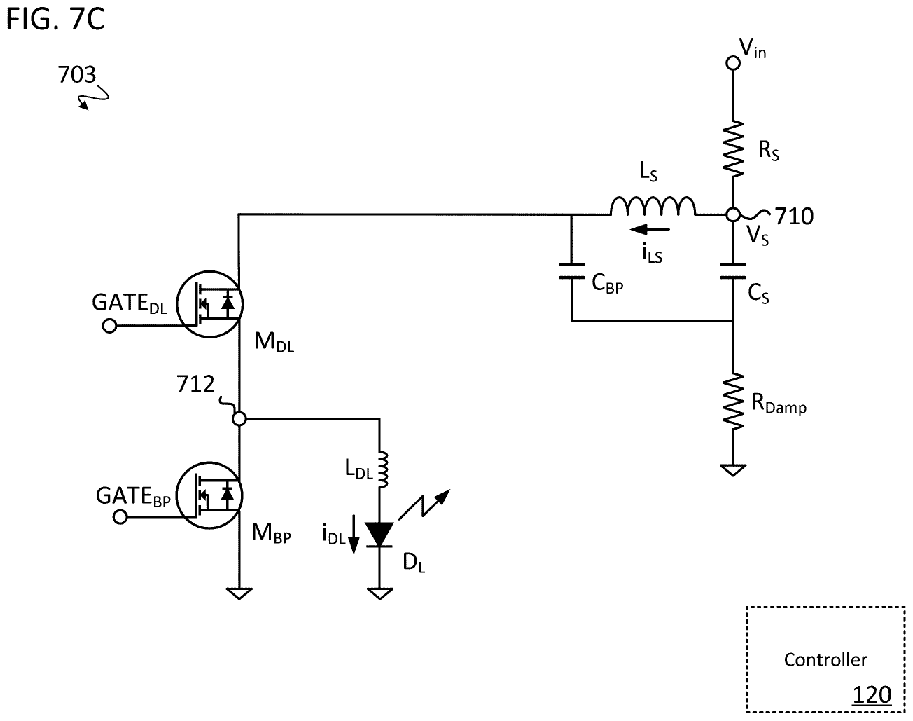

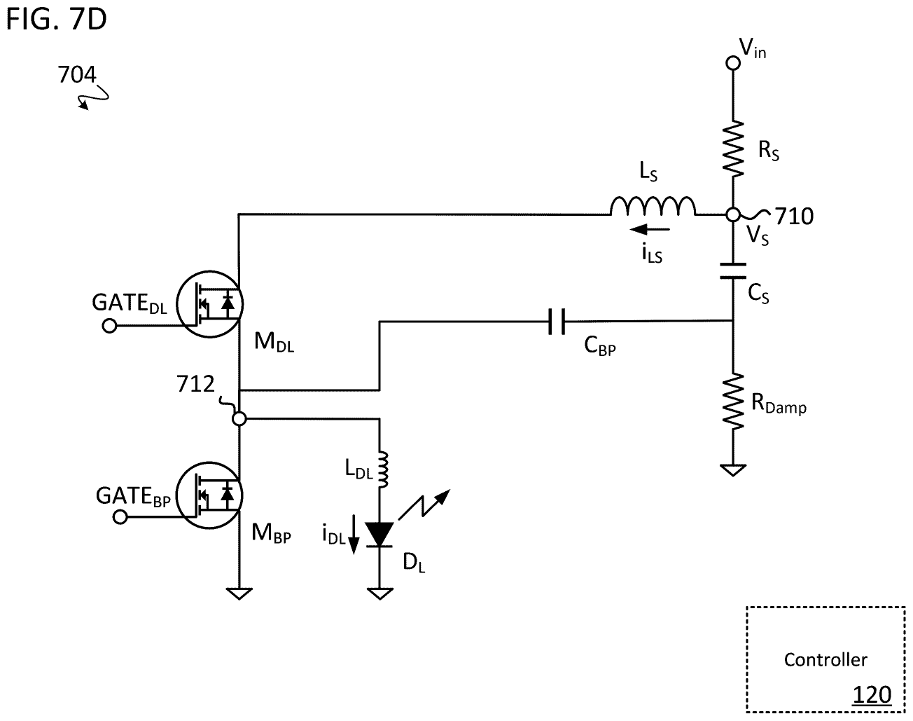

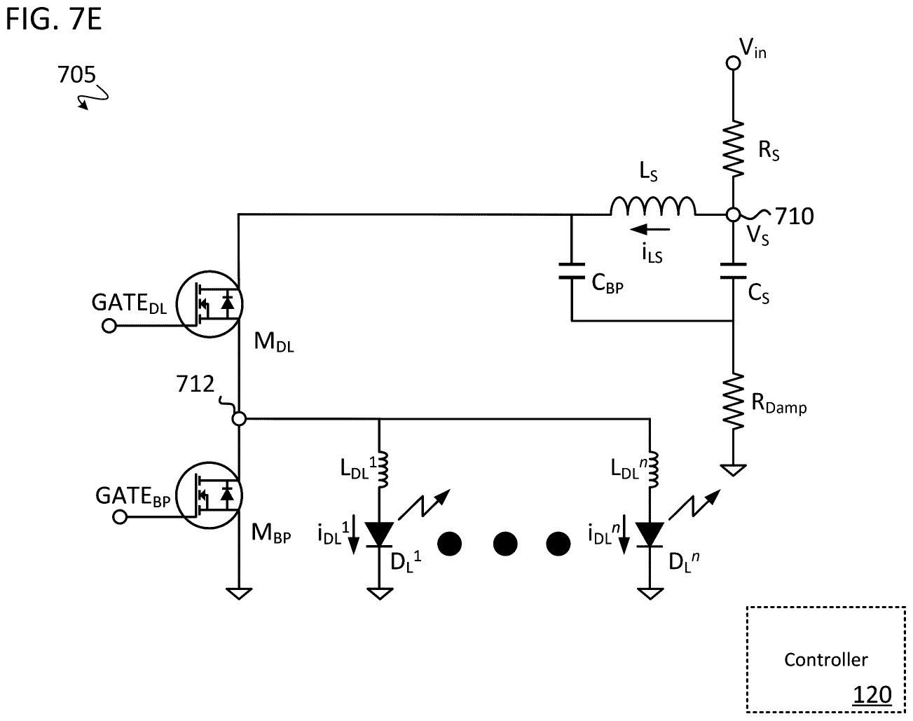

FIGS. 7A-E are simplified circuit schematics of pulsed laser diode drivers 701-705 of a fifth general topology that is configured to drive a laser diode using a half-bridge configuration, in accordance with some embodiments. The pulsed laser diode drivers 701-704 each generally include the source resistor R_{S}, the source capacitor C_{S}, the damping resistor R_{Damp}, the inductor L_{S}, the bypass capacitor C_{BP}, the bypass switch M_{BP}, the laser diode D_{L}, and the laser diode switch M_{DL}. The pulsed laser diode driver 705 additionally includes two or more laser diodes D_{L}¹-D_{L}ⁿ, rather than the single laser diode D_{L}, each of the two or more laser diodes D_{L}¹-D_{L}ⁿ having a respective parasitic inductance L_{DL}¹-L_{DL}ⁿ, and respective current representation i_{DL}¹-i_{DL}ⁿ. However, the pulsed laser diode driver 705 lacks independent control of the two or more laser diodes D_{L}¹-D_{L}ⁿ.

Also shown is the controller 120, nodes 710, 712, the parasitic inductance L_{DL} of the laser diode D_{L}, the DC input voltage Vᵢₙ, the source voltage V_{S} at the source capacitor C_{S}, the current i_{L}S through the inductor L_{S}, the current i_{DL} through the laser diode D_{L}, the currents i_{DL}¹-i_{DL}ⁿ through the two or more laser diodes D_{L}¹-D_{L}ⁿ, the bypass switch gate driver signal GATE_{BP}, and the laser diode switch gate driver signal GATE_{DL} of the laser diode switch M_{DL}.

Most of the electrical connections of the pulsed laser diode drivers 701-704 are similar to, or the same as those described with respect to the pulsed laser diode drivers 501-503. However, in contrast to the high-side configuration of the pulsed laser diode drivers 501-503, the drain node of the bypass switch M_{BP} is directly electrically connected to the source node of the laser diode switch M_{DL} and to the anode of the laser diode D_{L}. The source node of the bypass switch M_{BP} is directly electrically connected to the bias voltage node. Thus, as shown in the simplified circuit schematics of the pulsed laser diode drivers 701-704, the laser diode D_{L} may be driven by the half-bridge configuration of the bypass switch M_{BP} and the laser diode switch M_{DL}. Topologies of the pulsed laser diode drivers 701-704 vary with respect to placement of the bypass capacitor C_{BP}.

As shown in the simplified circuit schematic of the pulsed laser diode driver 701 of FIG. 7A, in some embodiments the first terminal of the bypass capacitor C_{BP} is directly electrically connected to the second terminal of the inductor L_{S} and to the drain node of the laser diode switch M_{DL}. In such embodiments, the second terminal of the bypass capacitor C_{BP} is electrically connected to the bias voltage node. As shown in the simplified circuit schematic of the pulsed laser diode driver 702 of FIG. 7B, in some embodiments the first terminal of the bypass capacitor C_{BP} is directly electrically connected to the source node of the laser diode switch M_{DL}, to the drain node of the bypass switch M_{BP}, and to the anode of the laser diode D_{L}. In such embodiments, the second terminal of the bypass capacitor C_{BP} is directly electrically connected to the bias voltage node. As shown in the simplified circuit schematic of the pulsed laser diode driver 703 of FIG. 7C, in some embodiments the first terminal of the bypass capacitor C_{BP} is directly electrically connected to the second terminal of the inductor L_{S} and to the drain node of the laser diode switch M_{DL}. In such embodiments, the second terminal of the bypass capacitor C_{BP} is directly electrically connected to the second terminal of the source capacitor C_{S} and to the first terminal of the damping resistor R_{Damp}. As shown in the simplified circuit schematic of the pulsed laser diode driver 704 of FIG. 7D, in some embodiments the first terminal of the bypass capacitor C_{BP} is directly electrically connected to the source node of the laser diode switch M_{DL}, the drain node of the bypass switch M_{BP}, and the anode of the laser diode D_{L}. In such embodiments, the second terminal of the bypass capacitor C_{BP} is directly electrically connected to the second terminal of the source capacitor C_{S} and to the first terminal of the damping resistor R_{Damp}.

As shown in the simplified circuit schematic of the pulsed laser diode driver 705 of FIG. 7E, two or more laser diodes D_{L}¹-D_{L}ⁿ may be driven simultaneously by the half-bridge configuration of the bypass switch M_{BP} and the laser diode switch M_{DL}. In the example shown, the first terminal of the bypass capacitor C_{BP} is directly electrically connected to the second terminal of the inductor L_{S} and the second terminal of the bypass capacitor C_{BP} is directly electrically connected to the second terminal of the source capacitor C_{S} and to the first terminal of the damping resistor R_{Damp}. However, other configurations of the bypass capacitor C_{BP}, such as those described with reference to FIGS. 7A-D may be used.

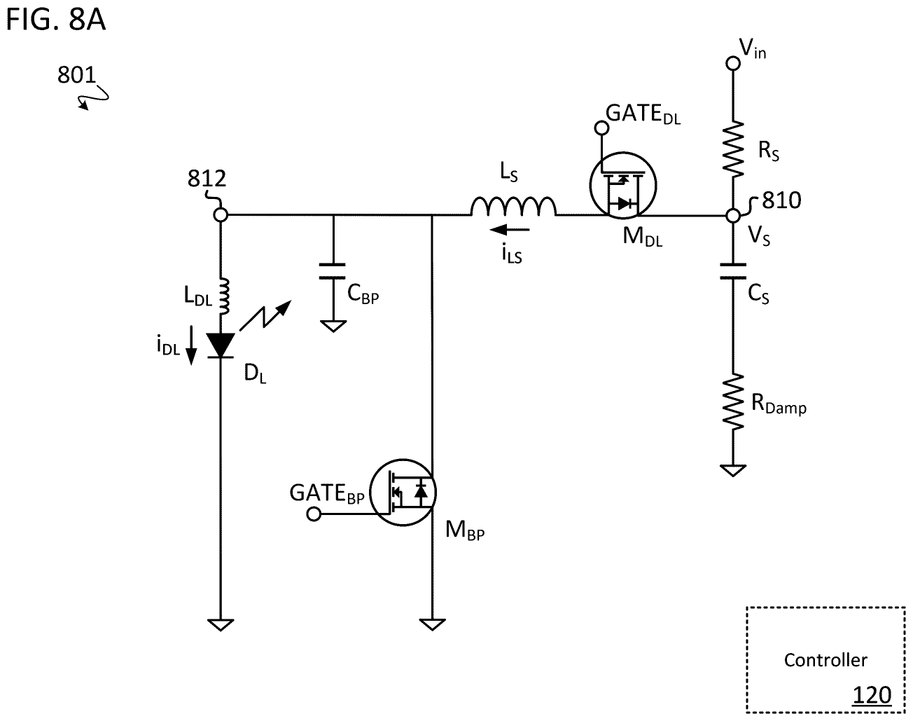

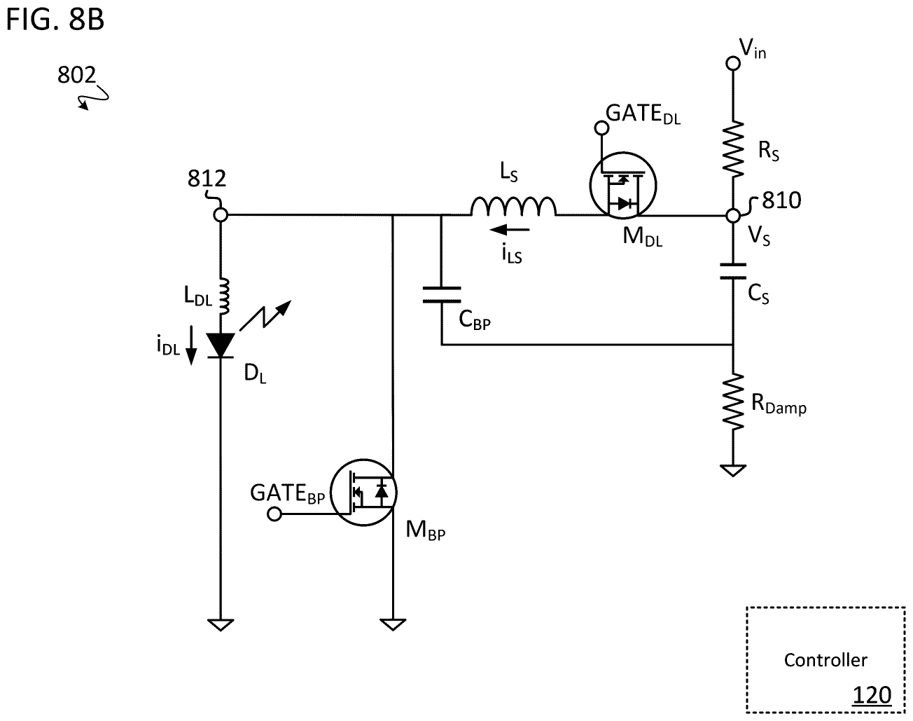

FIGS. 8A-B are simplified circuit schematics of pulsed laser diode drivers 801-802 of a sixth general topology that is configured to drive a laser diode using a high-side switch, in accordance with some embodiments. The pulsed laser diode drivers 801-802 generally include the source resistor R_{S}, the source capacitor C_{S}, the damping resistor R_{Damp}, the inductor L_{S}, the bypass capacitor C_{BP}, the laser diode D_{L}, the bypass switch M_{BP}, and the laser diode switch M_{DL}. Also shown is the controller 120, nodes 810, 812, the respective parasitic inductances L_{DL} of the laser diode D_{L}, the DC input voltage Vᵢₙ, the source voltage V_{S} at the source capacitor C_{S}, the current i_{L}S through the inductor L_{S}, the current i_{DL} through the laser diodes D_{L}, the bypass switch gate driver signal GATE_{Bp}, and the laser diode switch gate driver signal GATE_{DL}. Electrical connections of the pulsed laser diode driver 801 are similar to, or the same as those described with respect to the pulsed laser diode driver 101. The pulsed laser diode drivers 801-802 differ in that the drain node of the laser diode switch M_{DL} is directly electrically connected to the second terminal of the source resistor R_{S} and to the first terminal of the source capacitor C_{S}. The source node of the laser diode switch M_{DL} is directly electrically connected to the first terminal of the inductor L_{S}. The anode of the laser diode D_{L} is directly electrically connected to the second terminal of the inductor L_{S} and the cathode of the laser diode D_{L} is directly electrically connected to the bias voltage node. As shown, the pulsed laser diode drivers 801-802 are advantageously configured such that the laser diode switch M_{DL} is electrically connected between the inductor L_{S} and the source capacitor C_{S}. As a result, the drain node of the laser diode switch M_{DL} does not receive a high voltage spike developed at the second terminal of the inductor L_{S} when the bypass switch M_{BP} is disabled to generate the high-current pulse through the laser diode D_{L}.

The pulsed laser diode drivers 801-802 differ in placement of the bypass capacitor C_{BP}. As shown in FIG. 8A, in some embodiments, the first terminal of the bypass capacitor C_{BP} is directly electrically connected to the second terminal of the inductor L_{S}, to the anode of the laser diode D_{L}, and to the drain node of the bypass switch M_{BP}. In such embodiments, the second terminal of the bypass capacitor C_{BP} is directly electrically connected to the bias voltage node. As shown in FIG. 8B, in some embodiments, the first terminal of the bypass capacitor C_{BP} is directly electrically connected to the second terminal of the inductor L_{S}, to the anode of the laser diode D_{L}, and to the drain node of the bypass switch M_{BP}. In such embodiments, the second terminal of the bypass capacitor C_{BP} is directly electrically connected to the second terminal of the source capacitor C_{S} and to the first terminal of the damping resistor R_{Damp}.

In other embodiments, the respective positions of the inductor L_{S} and the laser diode switch M_{DL} in either of the pulsed laser diode drivers 801-802, can be exchanged such that the first terminal of the inductor L_{S} is directly electrically connected to the first terminal of the source capacitor C_{S}, and the drain terminal of the laser diode switch M_{DL} is directly electrically connected to the second terminal of the inductor L_{S}.

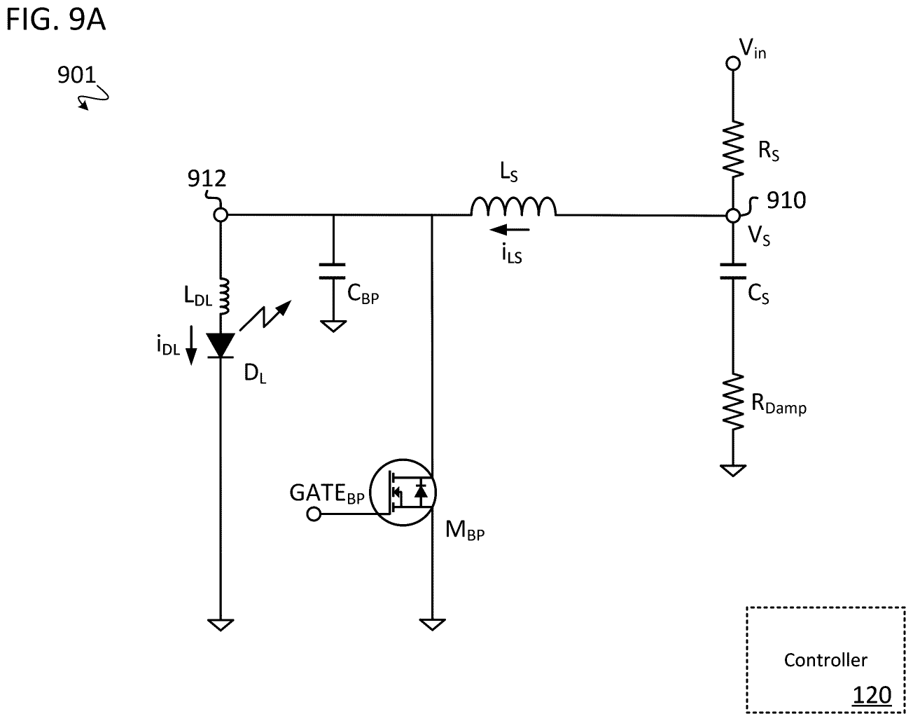

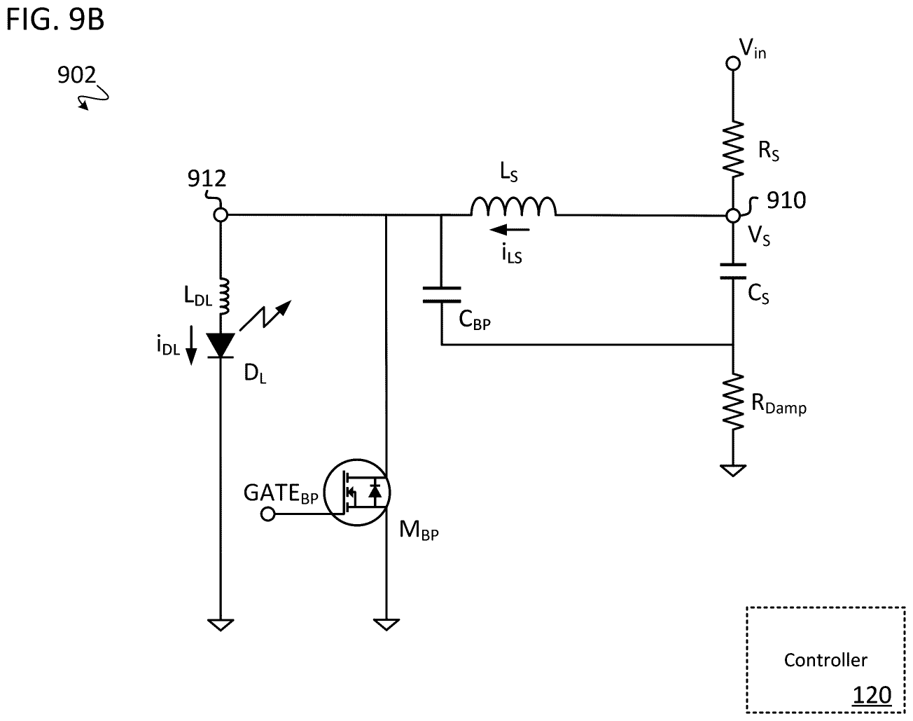

FIGS. 9A-B are simplified circuit schematics of pulsed laser diode drivers 901-902 of a seventh general topology that is configured to drive a laser diode using only a bypass switch, in accordance with some embodiments. The pulsed laser diode drivers 901-902 generally include the source resistor R_{S}, the source capacitor C_{S}, the damping resistor R_{Damp}, the inductor L_{S}, the bypass capacitor C_{BP}, the laser diode D_{L}, and the bypass switch M_{BP}. Also shown are nodes 910, 912, the respective parasitic inductances L_{DL} of the laser diode D_{L}, the DC input voltage Vᵢₙ, the source voltage V_{S} at the source capacitor C_{S}, the current i_{LS} through the inductor L_{S}, the current i_{DL} through the laser diodes D_{L}, and the bypass switch gate driver signal GATE_{BP}. Electrical connections of the pulsed laser diode drivers 901-902 are similar to, or the same as, those described with respect to the pulsed laser diode driver 101. The pulsed laser diode drivers 901-902 differ in that the laser diode switch M_{DL} is eliminated. The anode of the laser diode D_{L} is directly electrically connected to the second terminal of the inductor L_{S} and the cathode of the laser diode D_{L} is directly electrically connected to the bias voltage node. In such embodiments, the voltage level of the DC input voltage Vᵢₙ is restricted to a voltage level that does not surpass the forward bias voltage of the laser diode D_{L}, thereby maintaining the laser diode D_{L} in an OFF-state (i.e., not conducting) until a voltage higher than the forward bias voltage is developed at the second terminal of the inductor L_{S} when current flow through the bypass switch is momentarily disabled.

The pulsed laser diode drivers 901-902 differ in placement of the bypass capacitor C_{BP}. As shown in FIG. 9A, in some embodiments, the first terminal of the bypass capacitor C_{BP} is directly electrically connected to the second terminal of the inductor L_{S}, to the anode of the laser diode D_{L}, and to the drain node of the bypass switch M_{BP}. In such embodiments, the second terminal of the bypass capacitor C_{BP} is directly electrically connected to the bias voltage node. As shown in FIG. 9B, in some embodiments, the first terminal of the bypass capacitor C_{BP} is directly electrically connected to the second terminal of the inductor L_{S}, to the anode of the laser diode D_{L}, and to the drain node of the bypass switch M_{BP}. In such embodiments, the second terminal of the bypass capacitor C_{BP} is directly electrically connected to the second terminal of the source capacitor C_{S} and to the first terminal of the damping resistor R_{Damp}.

Embodiments of the pulsed laser diode drivers disclosed herein are additionally or alternatively operable to provide current pulses to devices other than laser diodes. For instance, embodiments of the pulsed laser diode drivers disclosed herein are operable to provide a current pulse to a light-emitting diode (i.e., a non-laser LED). Additionally, embodiments of the pulsed laser diode drivers disclosed herein are operable to provide a current pulse to another circuit or device, having no laser diode, that is configured to receive a current pulse for a purpose other than emitting light.

In some embodiments, two or more instances of the laser diode drivers disclosed herein are configured to drive respective laser diodes. For example, four instances of the pulsed laser diode driver 802 may be used to drive a laser diode package that includes four laser diodes. In such an embodiment, each of the laser diodes in the laser diode package is driven by an instance of the pulsed laser diode driver 802.

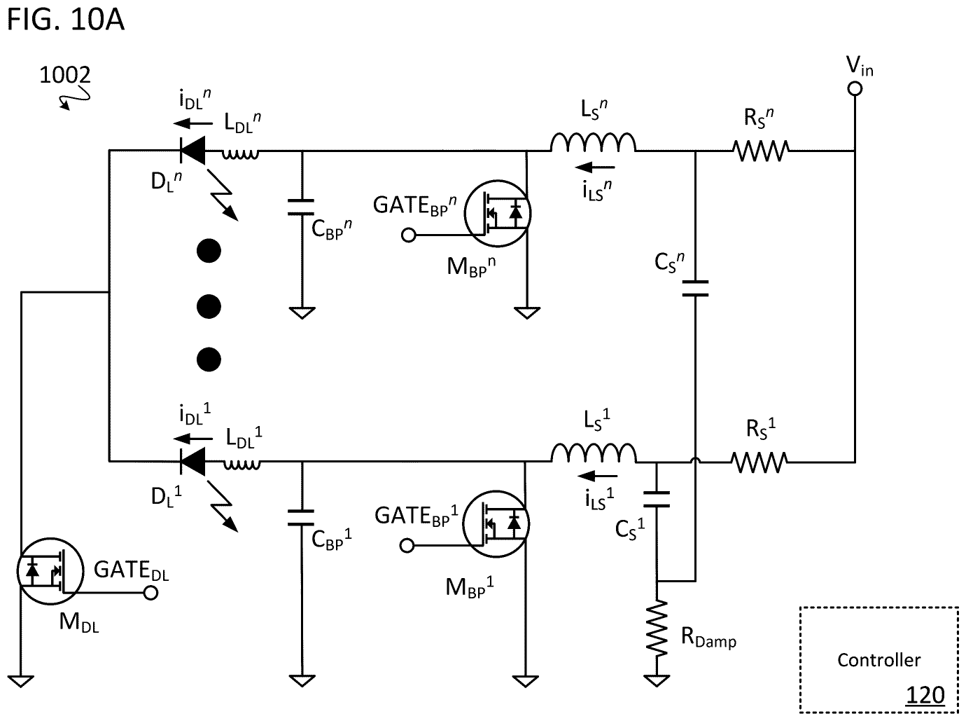

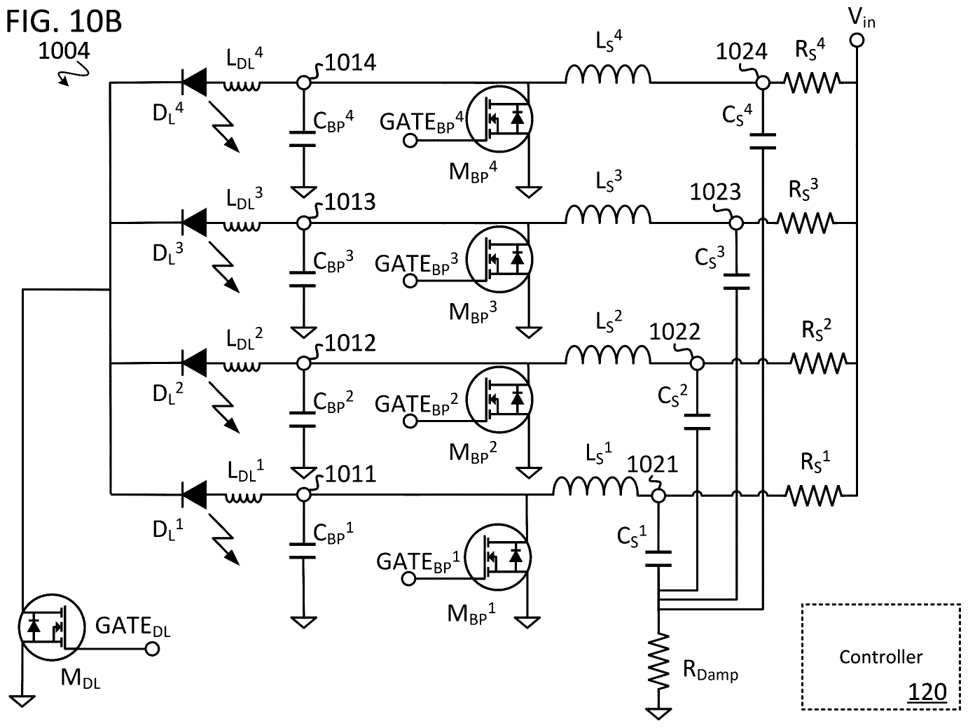

FIGS. 10A-10B are simplified circuit schematics of pulsed laser diode drivers 1002/1004 of an eighth general topology that is configured for multi-channel, individual control of multiple laser diodes, in accordance with some embodiments. The multi-channel pulsed laser diode driver 1002 shown in FIG. 10A is configured to independently drive n laser diodes where n is a number ranging from two to 128 or more. The multi-channel pulsed laser diode driver 1002 is operable to cause a pulse to be emitted from any individual laser diode of the multi-channel pulsed laser diode driver 1002 in isolation, or combined with one or more other pulses emitted from other laser diodes of the multi-channel pulsed laser diode driver 1002. The multi-channel pulsed laser diode driver 1002 generally includes n source resistors Rs¹ through Rsⁿ, n source capacitors C_{S}¹ through C_{S}ⁿ, an optional damping resistor R_{Damp, n} inductors L_{S}¹ through L_{S}ⁿ, n bypass switches M_{BP}¹ through M_{BP}ⁿ, n bypass capacitors C_{BP}¹ through C_{BP}ⁿ, n laser diodes D_{L}¹ through D_{L}ⁿ, and a laser diode switch M_{DL}, coupled as shown. Also shown is the controller 120 discussed above, respective parasitic inductances L_{DL}¹ through L_{DL}ⁿ of the laser diodes D_{L}¹ through D_{L}ⁿ, respective currents i_{LS}ⁿ through i_{LS}ⁿ of the inductors L_{S}¹ through L_{S}ⁿ, respective currents i_{DL}¹ through i_{DL}ⁿ of the laser diodes D_{L}¹ through D_{L}ⁿ, and the DC input voltage Vᵢₙ. The damping resistor R_{Damp} is used in some embodiments for current measurement purposes and can be omitted by connecting each of the source capacitors C_{S}¹ through C_{S}ⁿ to ground. In some embodiments, the bypass switches M_{BP}¹ through M_{BP}ⁿ and the laser diode switch M_{DL} are each N-type FET switches and advantageously do not require bootstrap circuitry to drive the respective gates of those switches because of their respective low-side configurations.

The source resistor Rs¹, the source capacitor C_{S}¹, the inductor Ls¹, the bypass switch M_{BP}¹, the bypass capacitor C_{BP}¹, and the laser diode D_{L}¹ are associated with a first channel of the multi-channel pulsed laser diode driver 1002. Similarly, the source resistor Rsⁿ, the source capacitor C_{S}ⁿ, the inductor Lsⁿ, the bypass switch M_{BP}ⁿ, the bypass capacitor C_{BP}ⁿ, and the laser diode D_{L}ⁿ are associated with an n^{th} channel of the multi-channel pulsed laser diode driver 1002, where n is a number greater than one (e.g., two, three, four, eight, 16, 32, 64, 128, etc.). By controlling (e.g., by the controller 120) respective switch timings (i.e., an on/off duration) of the bypass switches M_{BP}¹ through M_{BP}ⁿ in conjunction with controlling a switch timing of the laser diode switch M_{DL} each of the laser diodes D_{L}¹ through D_{L}ⁿ are advantageously independently controlled. Operation of each channel of the multi-channel pulsed laser diode driver 1002 is similar to, or the same as, operation of the pulsed laser diode driver 101 described with reference to FIG. 1A and the switching sequence 300 shown in FIG. 3. Because each of the bypass switches M_{BP}¹ through M_{BP}ⁿ and the laser diode switch M_{DL} are configured as low-side switches (i.e., a source node of each aforementioned switch is directly electrically connected to ground), a gate control signal of those switches does not need to be level-shifted by bootstrap circuitry, thereby advantageously simplifying the design and reducing the cost of the multi-channel pulsed laser diode driver 1002 as compared to a laser diode driver circuit that requires bootstrap circuitry.

An example embodiment of a four-channel (i.e., n=4) multi-channel pulsed laser diode driver 1004 is shown in FIG. 10B. The multi-channel pulsed laser diode driver 1004 is operable to independently drive four laser diodes. That is, the multi-channel pulsed laser diode driver 1004 is operable to cause a pulse to be emitted from any individual laser diode of the multi-channel pulsed laser diode driver 1004 in isolation, or combined with one or more other pulses emitted from other laser diodes of the multi-channel pulsed laser diode driver 1004. The multi-channel pulsed laser diode driver 1004 generally includes four source resistors Rs¹ through Rs⁴, four source capacitors Cs¹ through Cs⁴, the optional damping resistor R_{Damp}, four inductors L_{S}¹ through L_{S}⁴, four bypass switches M_{BP}¹ through M_{BP}⁴, four bypass capacitors C_{BP}¹ through C_{BP}⁴, four laser diodes D_{L}¹ through D_{L}⁴, and the laser diode switch M_{DL}, directly electrically connected as shown. Also shown is the controller 120, respective parasitic inductances L_{DL}¹ through L_{DL}⁴ of the laser diodes D_{L}¹ through D_{L}⁴, the DC input voltage Vᵢₙ, nodes 1011 through 1014, and nodes 1021 through 1024. The damping resistor R_{Dm}p is used in some embodiments for current measurement purposes and can be omitted by connecting each of the source capacitors C_{S}¹ through C_{S}⁴ to ground. In some embodiments, the bypass capacitors C_{BP}¹ through C_{BP}⁴ are connected to the cathodes of the laser diodes D_{L}¹ through D_{L}⁴. In some embodiments, the bypass switches M_{BP}¹ through M_{BP}⁴ and the laser diode switch M_{DL} are each N-type FET switches and advantageously do not require boot-strap circuitry to drive the respective gates of those switches as described above.

The source resistor Rs¹, the source capacitor C_{S}¹, the inductor Ls¹, the bypass switch M_{BP}¹, the bypass capacitor C_{BP}¹, and the laser diode D_{L}¹ are associated with a first channel of the multi-channel pulsed laser diode driver 1004; the source resistor Rs², the source capacitor C_{S}², the inductor Ls², the bypass switch M_{BP}², the bypass capacitor C_{BP}², and the laser diode D_{L}² are associated with a second channel of the multi-channel pulsed laser diode driver 1004; the source resistor Rs³, the source capacitor C_{S}³, the inductor L_{S}³, the bypass switch M_{BP}³, the bypass capacitor C_{BP}³, and the laser diode D_{L}³ are associated with a third channel of the multi-channel pulsed laser diode driver 1004, and the source resistor Rs⁴, the source capacitor C_{S}⁴, the inductor Ls⁴, the bypass switch M_{BP}⁴, the bypass capacitor C_{BP}⁴, and the laser diode D_{L}⁴ are associated with a fourth channel of the multi-channel pulsed laser diode driver 1004. The laser diode switch M_{DL} is associated with each of the channels of the multi-channel pulsed laser diode driver 1004.

As described above, each channel of the multi-channel pulsed laser diode driver 1004 has an associated source resistor, source capacitor, inductor, bypass switch, bypass capacitor, and laser diode. By controlling (e.g., by the controller 120) respective switch timings (i.e., an on/off duration) of the bypass switches M_{BP}¹ through M_{BP}⁴ in conjunction with controlling a switch timing of the laser diode switch M_{DL}, each of the laser diodes D_{L}¹ through D_{L}⁴ is advantageously independently controlled.

Operation of each channel of the multi-channel pulsed laser diode driver 1004 is similar to, or the same as operation of the pulsed laser diode driver 101 described with reference to FIG. 1A and the switching sequence 300 shown in FIG. 3. A channel of the multi-channel pulsed laser diode driver 1004 is selected for output by turning that channel's bypass switch off (e.g., by the controller 120) while the laser diode switch M_{DL} is off such that the DC input voltage Vᵢₙ charges that channel's source capacitor to a desired voltage level to store energy in that source capacitor (e.g., step 301 of FIG. 3). After the desired voltage level is reached at the source capacitor, a selected channel's bypass switch is turned on (e.g., by the controller 120), such that current builds in that channel's inductor between that channel's bypass switch and that channel's source capacitor (e.g., step 302 of FIG. 3). If that channel's bypass switch is thereafter turned off for a short time and the laser diode switch M_{DL} is turned on, that channel's inductor current will resonate with the anode capacitance of that channel's laser diode, thereby creating a voltage across that channel's laser diode that is higher than the DC input voltage Vᵢₙ and the developed current will be forced to flow through that channel's laser diode (e.g., step 303 of FIG. 3) to emit a laser pulse. In some embodiments, a discharge sequence similar to step 304 of FIG. 3 is performed, whereby both that channel's bypass switch and the laser diode switch M_{DL} are turned on may then follow. By sequentially selecting each channel of the multi-channel laser diode driver 1004, that channel's laser diode can be independently pulsed. A channel of the multi-channel pulsed laser diode driver 1004 is unselected for output by leaving that channel's bypass switch on (e.g., by the controller 120) through each of the steps 301 through 305 shown in FIG. 3, thereby preventing the DC input voltage Vᵢₙ from charging that channel's source capacitor.

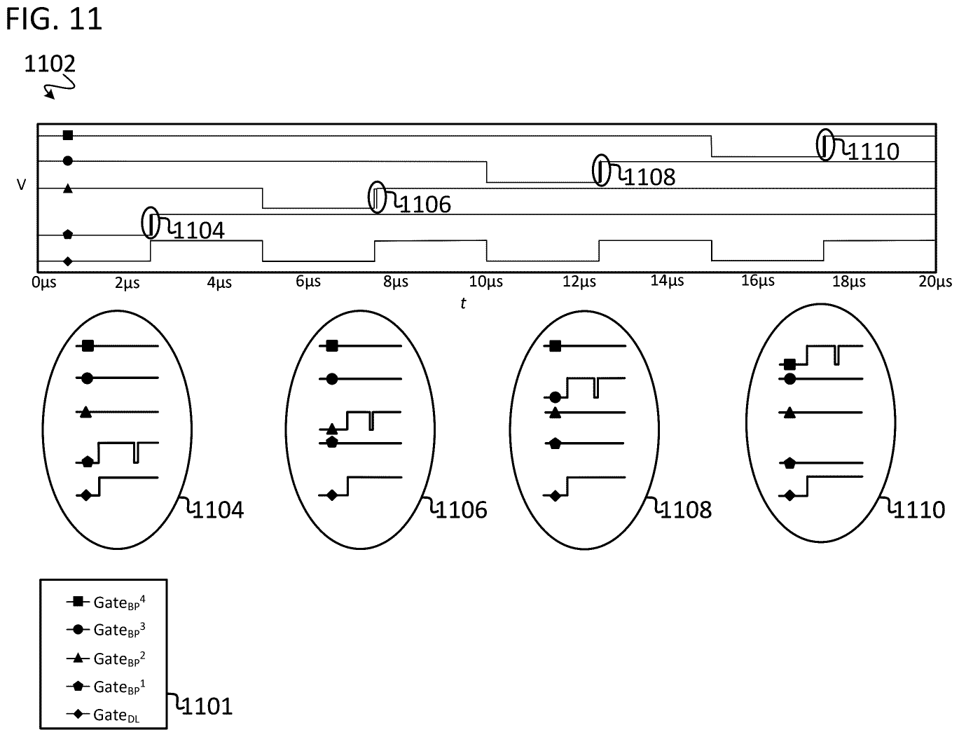

Simplified example waveforms 1102 of signals related to the operation of the multi-channel pulsed laser diode driver 1004 are shown in FIG. 11, in accordance with some embodiments. Also shown is a legend 1101 and expanded regions of interest 1104, 1106, 1108, and 1110 of the waveforms 1102.

As indicated by the legend 1101, the simplified waveforms 1102 of FIG. 11 include a laser diode switch gate driver signal Gate_{DL}, a first bypass switch gate driver signal Gate_{BP}¹, a second bypass switch gate driver signal Gate_{BP}², a third bypass switch gate driver signal Gate_{BP}³ and a fourth bypass switch gate driver signal Gate_{BP}⁴ over a 20 μs duration. With reference to FIG. 10B, the laser diode switch gate driver signal Gate_{DL} is operable to control the laser diode switch M_{DL}, the first bypass switch gate driver signal Gate_{BP}¹ is operable to control the bypass switch M_{BP}¹, the second bypass switch gate driver signal Gate_{BP}² is operable to control the bypass switch M_{BP}², the third bypass switch gate driver signal Gate_{BP}³ is operable to control the bypass switch M_{BP}³, and the fourth bypass switch gate driver signal Gate_{BP}⁴ is operable to control the bypass switch M_{BP}⁴.

Each of the expanded regions of interest 1104, 1106, 1108, and 1110 illustrate a pre-flux interval of a selected channel during which an inductor current of that channel's inductor is ramping up, a very short pulse interval during which current through that channel's inductor is directed through that channel's laser diode, and a discharge interval in accordance with steps 301 through 305 described with reference to FIG. 3. Per the description above, the region of interest 1104 illustrates pulse generation for the first channel (i.e., laser diode D_{L}¹) of the multi-channel laser diode driver 1004, the region of interest 1106 illustrates pulse generation for the second channel (i.e., laser diode D_{L}²) of the multi-channel laser diode driver 1004, the region of interest 1108 illustrates pulse generation for the third channel (i.e., laser diode D_{L}³) of the multi-channel laser diode driver 1004, and the region of interest 1110 illustrates pulse generation for the fourth channel (i.e., laser diode D_{L}²) of the multi-channel laser diode driver 1004.

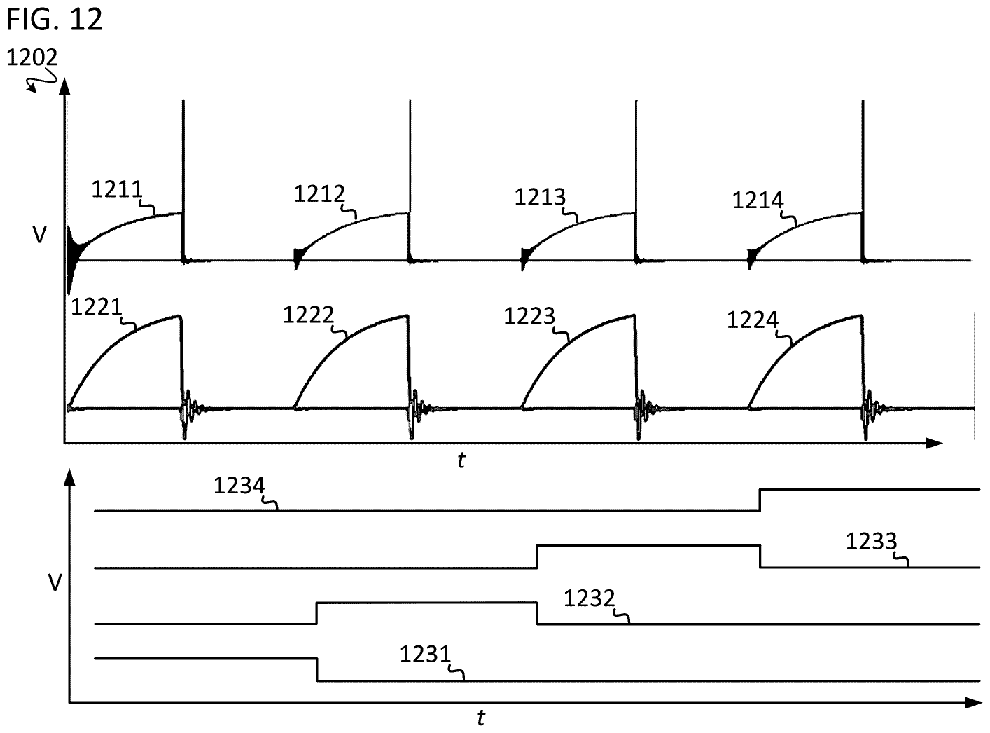

Additional simplified example waveforms 1202 of signals related to the operation of the multi-channel pulsed laser diode driver 1004 of FIG. 10B are shown in FIG. 12. The simplified example waveforms include waveforms 1211 through 1214 illustrating respective anode voltages of the laser diodes D_{L}¹ through D_{L}⁴ at the nodes 1011 through 1014, and waveforms 1221 through 1224 illustrating respective voltages of the source capacitor C_{S}¹ through C_{S}⁴ at the nodes 1021 through 1024. Also shown are waveforms 1231 through 1234 which illustrate when a respective channel of the multi-channel pulsed laser diode driver 1004 is enabled.

As shown, when a first channel of the multi-channel pulsed laser diode driver 1004 is enabled (illustrated by waveform 1231), an anode voltage 1211 at node 1011 of the laser diode D_{L}¹ rises in conjunction with a rising voltage at node 1021 of the source capacitor C_{S}¹. Upon enabling the laser diode switch M_{DL} and momentarily disabling the bypass switch M_{BP}¹, current flows through the laser diode D_{L}¹, thereby emitting a laser pulse as described above. Similarly, when a second channel of the multi-channel pulsed laser diode driver 1004 is enabled (illustrated by waveform 1232), an anode voltage 1212 at node 1012 of the laser diode D_{L}² rises in conjunction with a rising voltage at node 1022 of the source capacitor C_{S}². Upon enabling the laser diode switch M_{DL} and momentarily disabling the bypass switch M_{BP}², current flows through the laser diode D_{L}², thereby emitting a laser pulse as described above. Operation of the third and fourth channels of the multi-channel laser diode driver 1004 are similar.

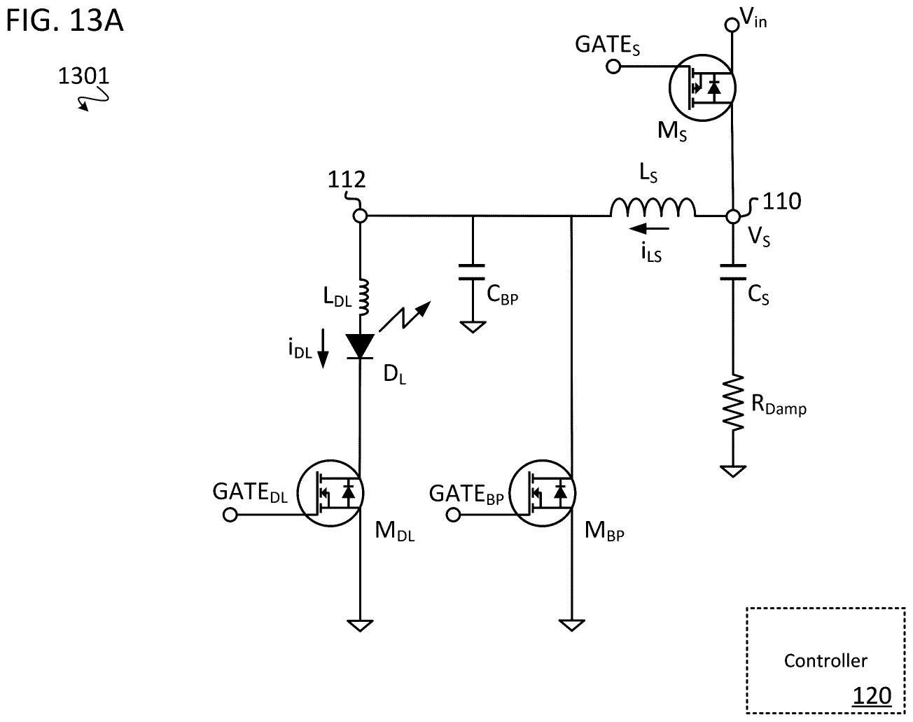

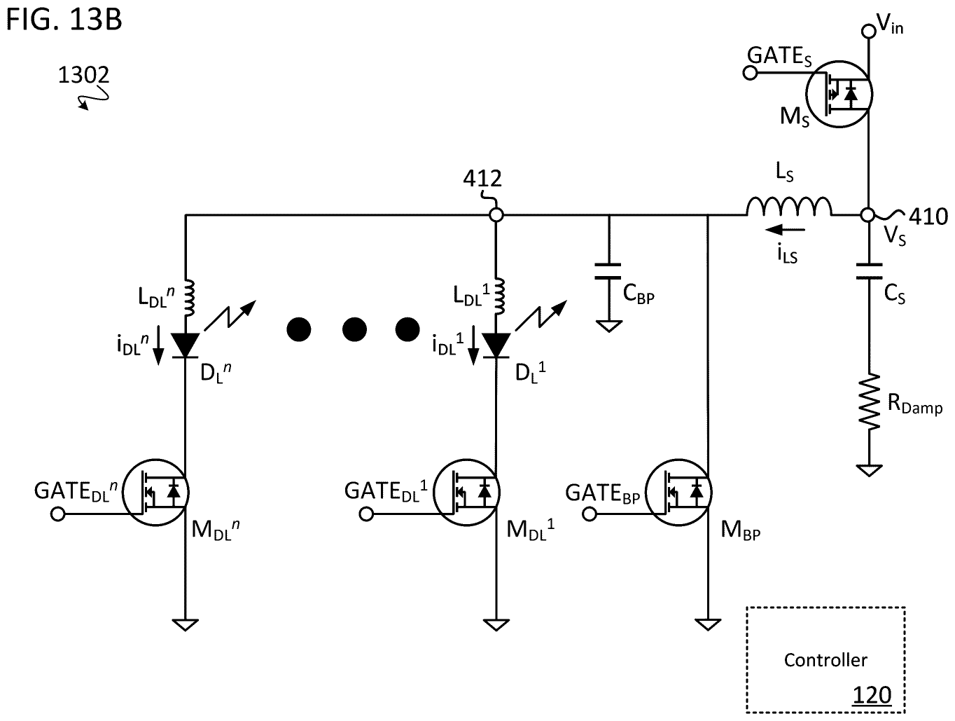

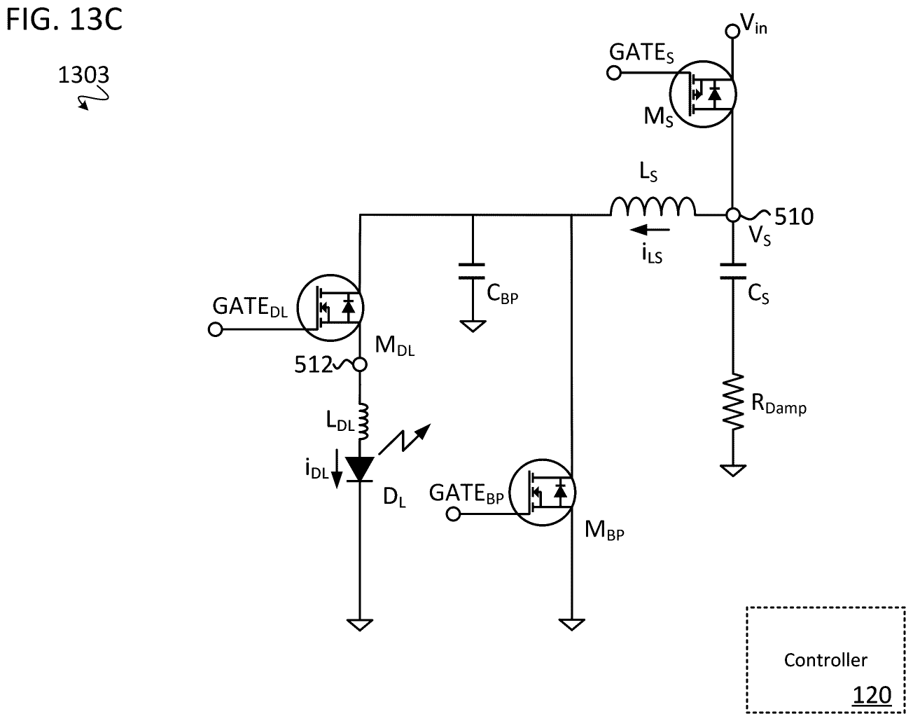

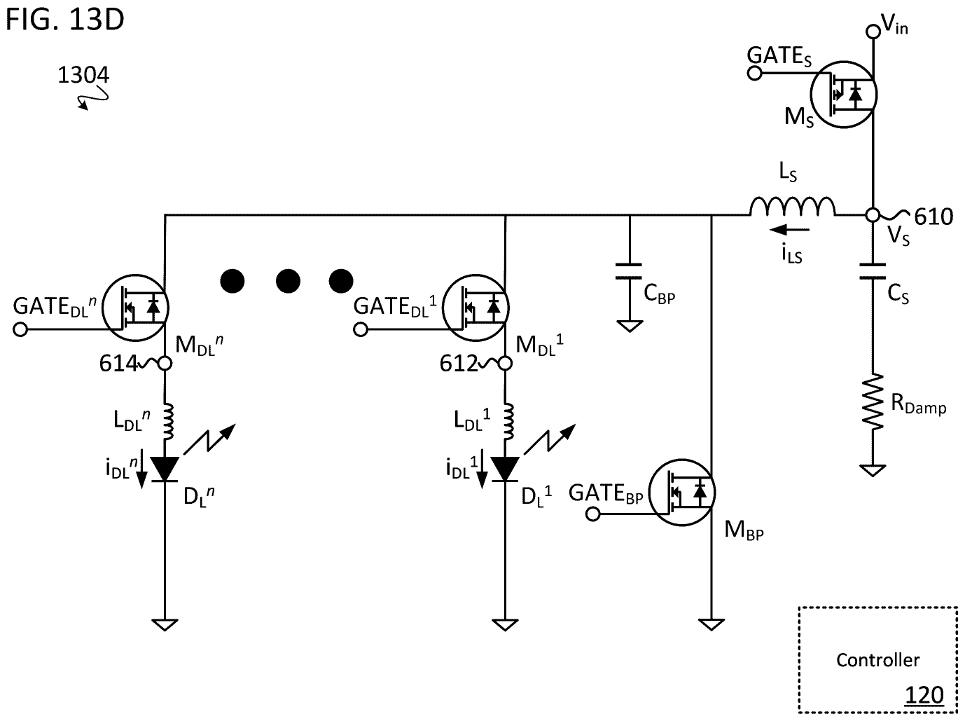

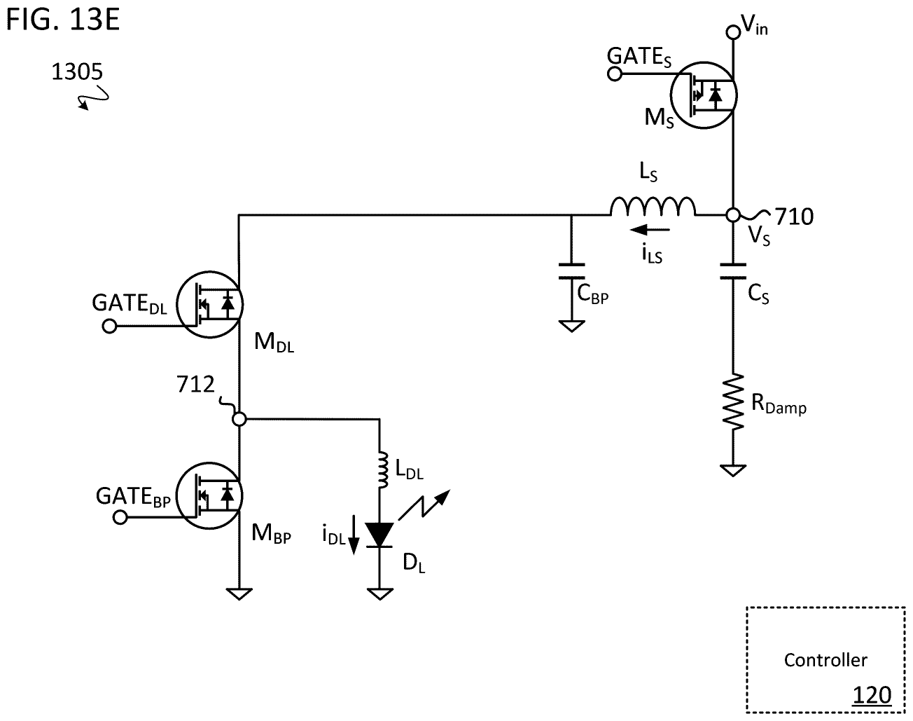

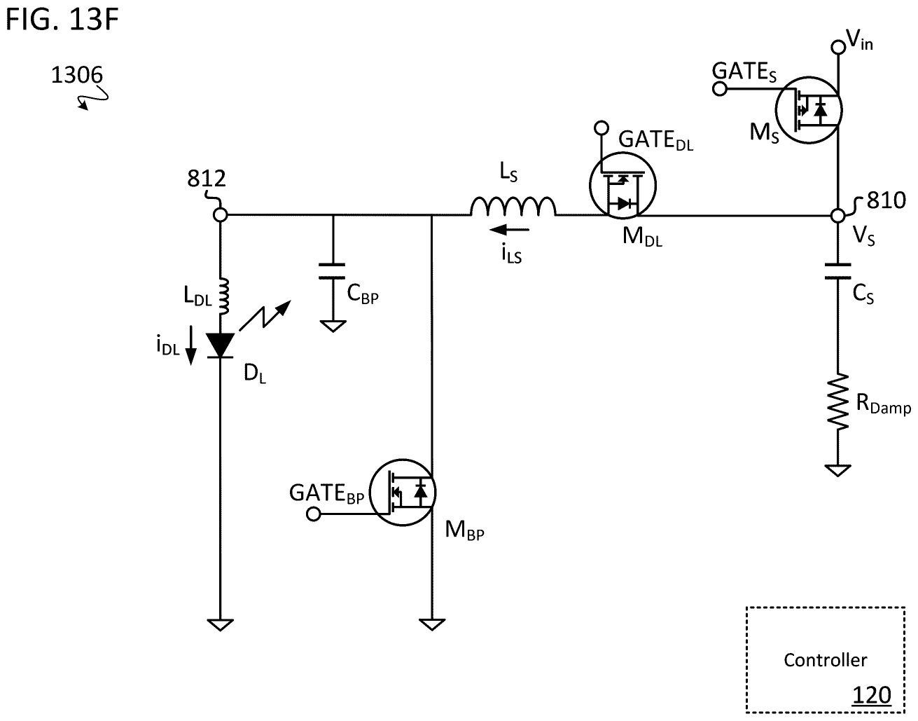

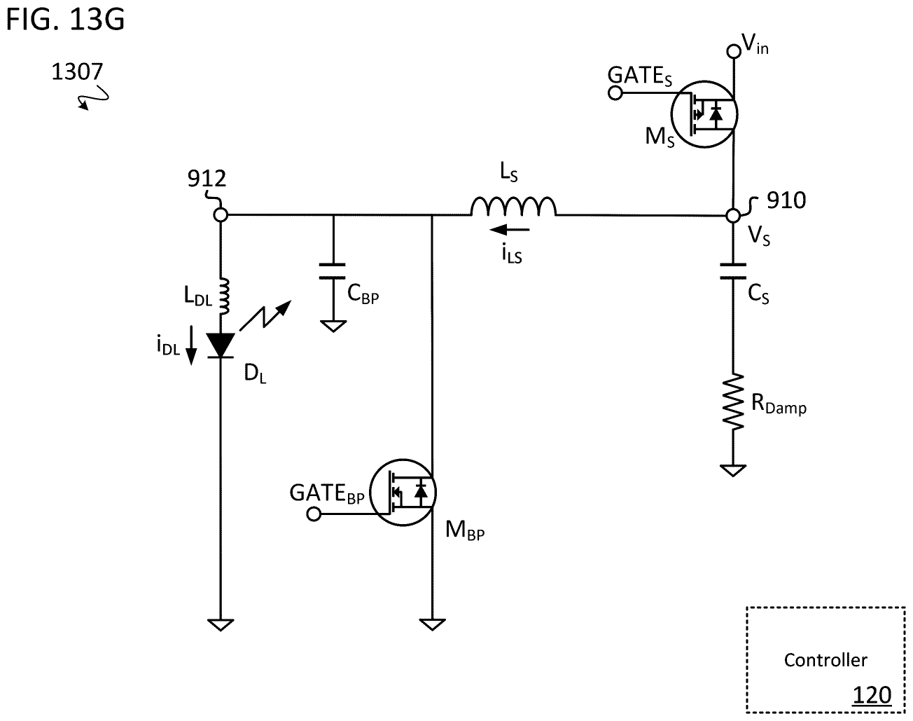

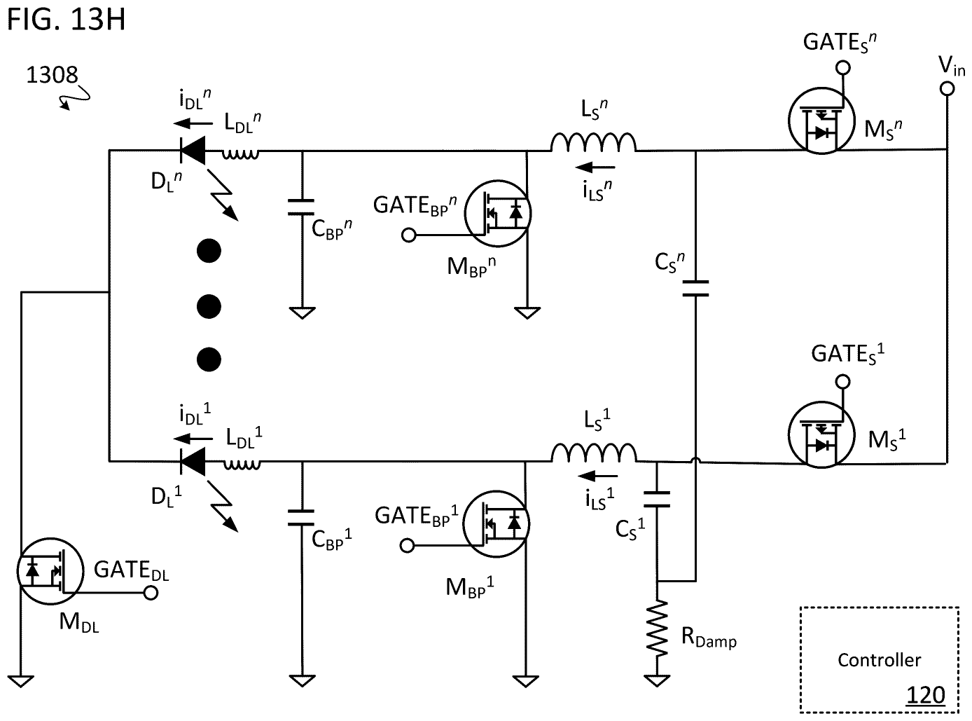

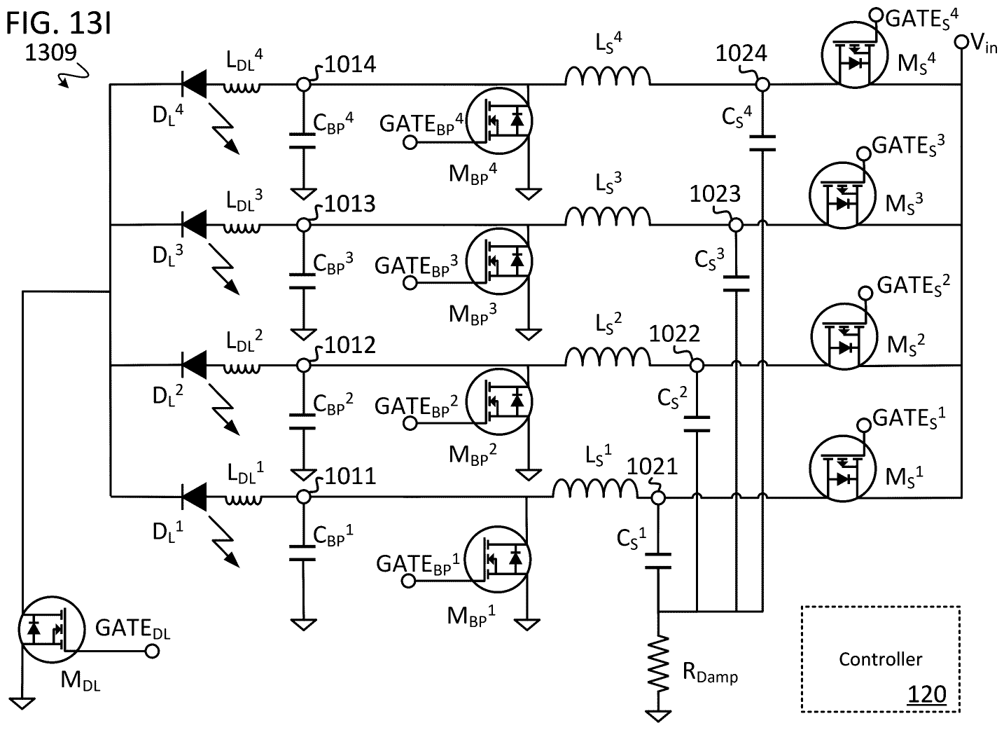

A repetition rate of the multi-channel pulsed laser diode driver 1004, as well as each of the pulsed laser diode drivers described above, is limited by a charging time of each channel's source capacitor. The pulsed laser diode drivers described above create narrow (e.g., 1 psec-5 nsec) high-current pulses (e.g., 40 amp) through a driven laser diode. The instantaneous power in the driven laser diode is therefore high (e.g., in the order of hundreds of watts). However, for many applications (e.g., LiDAR), the duty cycle of the pulse is generally 0.01% or less to limit the total power dissipated in the laser diode which results in an upper limit to a repetition rate. In conventional laser diode driver applications, a resistor is used to charge storage (i.e., source) capacitors during each cycle. In such conventional solutions, an RC time constant of such charging circuits is typically not an issue because the duty cycle is so low. However, for applications that require a high repetition rate for laser pulses, the RC time constant of conventional charging circuits creates an undesirable limitation. In any of the embodiments disclosed herein, each source resistor of a given pulsed laser diode driver may be advantageously replaced by an actively controlled source switch that quickly charges an associated source capacitor. Activation of the source switch is synchronized with switching the one or more bypass switches and one or more laser diode switches of a given pulsed laser diode driver such that the source switch is enabled prior to a laser diode pulse generation interval. FIG. 13A through FIG. 13I provide examples of previously described laser diode drivers in which the respective source resistor R_{S} has been replaced by an actively controlled source switch M_{S} to rapidly charge the respective source capacitor C_{S}. In some embodiments, the actively controlled source switch is implemented as a P-type switch which advantageously does not require bootstrap circuitry. Respective actively controlled source switches M_{S} shown in FIG. 13A through FIG. 13I are activated only during a pre-charge step (i.e., during step 301 as described with reference to FIG. 3), and thus prior to a pre-flux step (i.e., prior to step 302 as described with reference to FIG. 3).

FIG. 13A shows a first example embodiment of a pulsed laser diode driver 1301 having all of the components, signals, and nodes described above with reference to the pulsed laser diode driver 101 of FIG. 1A, with the exception of the source resistor R_{S} of FIG. 1A which has advantageously been replaced in FIG. 13A by an actively controlled (e.g., by the controller 120 using gate control signal GATE_{S}) source switch M_{S} to rapidly charge the source capacitor C_{S}. In other example embodiments (not shown), the respective source resistors Rs of the pulsed laser diode driver 102 of FIG. 1B and the pulsed laser diode driver 103 of FIG. 1C are similarly replaced by a respective actively controlled source switch to rapidly charge the respective source capacitors C_{S} of the laser diode drivers 102/103.

FIG. 13B shows a second example embodiment of a pulsed laser diode driver 1302 having all of the components, signals, and nodes described above with reference to the pulsed laser diode driver 401 of FIG. 4A, with the exception of the source resistor Rs of FIG. 4A which has advantageously been replaced in FIG. 13B by an actively controlled (e.g., by the controller 120 using gate control signal GATE_{S}) source switch M_{S} to rapidly charge the source capacitor C_{S}. In other example embodiments (not shown), the respective source resistors Rs of the pulsed laser diode driver 402 of FIG. 4B, the pulsed laser diode driver 403 of FIG. 4C, and the pulsed laser diode driver 404 of FIG. 4D are similarly replaced by a respective actively controlled source switch to rapidly charge the respective source capacitors C_{S} of the laser diode drivers 402/403/404.

FIG. 13C shows a third example embodiment of a pulsed laser diode driver 1303 having all of the components, signals, and nodes described above with reference to the pulsed laser diode driver 501 of FIG. 5A, with the exception of the source resistor Rs of FIG. 5A which has advantageously been replaced in FIG. 13C by an actively controlled (e.g., by the controller 120 using gate control signal GATE_{S}) source switch M_{S} to rapidly charge the source capacitor C_{S}. In other example embodiments (not shown), the respective source resistors Rs of the pulsed laser diode driver 502 of FIG. 5B, the pulsed laser diode driver 503 of FIG. 5C, and the pulsed laser diode driver 504 of FIG. 5D are similarly replaced by a respective actively controlled source switch to rapidly charge the respective source capacitors C_{S} of the laser diode drivers 502/503/504.

FIG. 13D shows a fourth example embodiment of a pulsed laser diode driver 1304 having all of the components, signals, and nodes described above with reference to the pulsed laser diode driver 601 of FIG. 6A, with the exception of the source resistor Rs of FIG. 6A which has advantageously been replaced in FIG. 13D by an actively controlled (e.g., by the controller 120 using gate control signal GATE_{S}) source switch M_{S} to rapidly charge the source capacitor C_{S}. In other example embodiments (not shown), the respective source resistors Rs of the pulsed laser diode driver 602 of FIG. 6B, the pulsed laser diode driver 603 of FIG. 6C, and the pulsed laser diode driver 604 of FIG. 6D are similarly replaced by a respective actively controlled source switch to rapidly charge the respective source capacitors C_{S} of the laser diode drivers 602/603/604.

FIG. 13E shows a fifth example embodiment of a pulsed laser diode driver 1305 having all of the components, signals, and nodes described above with reference to the pulsed laser diode driver 701 of FIG. 7A, with the exception of the source resistor Rs of FIG. 7A which has advantageously been replaced in FIG. 13E by an actively controlled (e.g., by the controller 120 using gate control signal GATE_{S}) source switch M_{S} to rapidly charge the source capacitor C_{S}. In other example embodiments (not shown), the respective source resistors Rs of the pulsed laser diode driver 702 of FIG. 7B, the pulsed laser diode driver 703 of FIG. 7C, the pulsed laser diode driver 704 of FIG. 7D, and the pulsed laser diode driver 705 of FIG. 7E are similarly replaced by a respective actively controlled source switch to rapidly charge the respective source capacitors C_{S} of the laser diode drivers 702/703/704/705.

FIG. 13F shows a sixth example embodiment of a pulsed laser diode driver 1306 having all of the components, signals, and nodes described above with reference to the pulsed laser diode driver 801 of FIG. 8A, with the exception of the source resistor Rs of FIG. 8A which has advantageously been replaced in FIG. 13F by an actively controlled (e.g., by the controller 120 using gate control signal GATE_{S}) source switch M_{S} to rapidly charge the source capacitor C_{S}. In other example embodiments (not shown), the source resistor Rs of the pulsed laser diode driver 802 of FIG. 8B is similarly replaced by an actively controlled source switch to rapidly charge the source capacitor C_{S} of the pulsed laser diode driver 802.

FIG. 13G shows a seventh example embodiment of a pulsed laser diode driver 1307 having all of the components, signals, and nodes described above with reference to the pulsed laser diode driver 901 of FIG. 9A, with the exception of the source resistor Rs of FIG. 9A which has advantageously been replaced in FIG. 13G by an actively controlled (e.g., by the controller 120 using gate control signal GATE_{S}) source switch M_{S} to rapidly charge the source capacitor C_{S}. In other example embodiments (not shown), the source resistor Rs of the laser diode driver 902 of FIG. 9B is similarly replaced by an actively controlled source switch to rapidly charge the source capacitor C_{S} of the laser diode driver 902.

FIG. 13H shows an eighth example embodiment of a pulsed laser diode driver 1308 having all of the components, signals, and nodes described above with reference to the multi-channel pulsed laser diode driver 1002 of FIG. 10A, with the exception of the source resistors R_{S}¹ though R_{S}ⁿ of FIG. 10A which have advantageously been replaced in FIG. 13H by respective actively controlled (e.g., by the controller 120 using gate control signals GATE_{S}¹ through GATE_{S}ⁿ) source switches M_{S}¹ through M_{S}ⁿ to rapidly charge the source capacitors CS¹ through C_{S}ⁿ.

FIG. 13I shows a ninth example embodiment of a pulsed laser diode driver 1309 having all of the components, signals, and nodes described above with reference to the multi-channel pulsed laser diode driver 1004 of FIG. 10B, with the exception of the source resistors R_{S}¹ through R_{S}⁴ of FIG. 10B which have advantageously been replaced in FIG. 13I by respective actively controlled (e.g., by the controller 120 using gate control signals GATE_{S}¹ through GATE_{S}⁴) source switches M_{S}¹ through M_{S}⁴ to rapidly charge the source capacitors C_{S}¹ through C_{S}⁴.

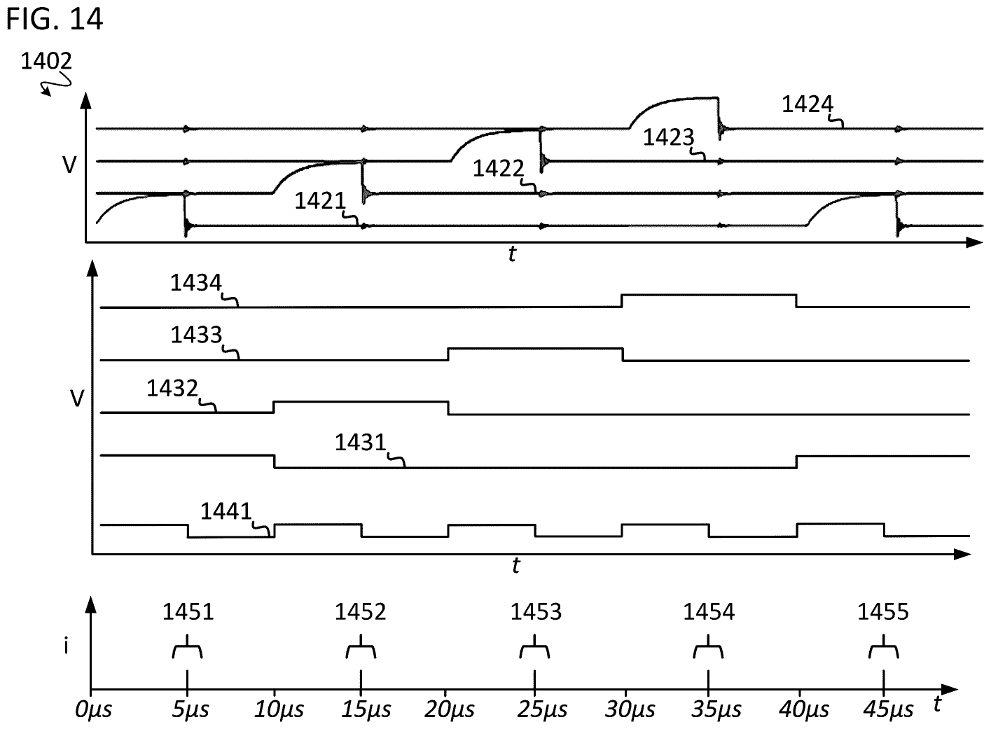

Simplified example waveforms 1402 of signals related to the operation of the multi-channel pulsed laser diode driver 1309 of FIG. 13I are shown in FIG. 14, in accordance with some embodiments. The simplified example waveforms 1402 include waveforms 1421 through 1424 illustrating respective voltages across the source capacitor C_{S}¹ through C_{S}⁴ at nodes 1021 through 1024 of FIG. 13I, respectively. Also shown are waveforms 1431 through 1434 which illustrate when a respective channel of the multi-channel pulsed laser diode driver 1309 is enabled, a clock signal 1441, and high-current pulses 1451 through 1455. As shown, the multi-channel pulsed laser diode driver 1309 is operable to emit a high-current pulse 1451 through 1455 to drive a respective laser diode D_{L}¹ through D_{L}⁴, a pulse being emitted every 10 μs. The examples shown in FIGS. 13A-13I are merely select examples of pulsed laser diode driver circuits configured to advantageously use a source switch (i.e., M_{S}) for rapid charging of a source capacitor (i.e., C_{S}). In some embodiments, any of the pulsed laser diode drivers 101-103, 401-404, 501-504, 601-604, 701-705, 801-802, 901-902, 1002-1004 are configured to use a source switch (i.e., M_{S}) instead of a source resistor (i.e., R_{S}) to rapidly charge a source capacitor (i.e., C_{S}).

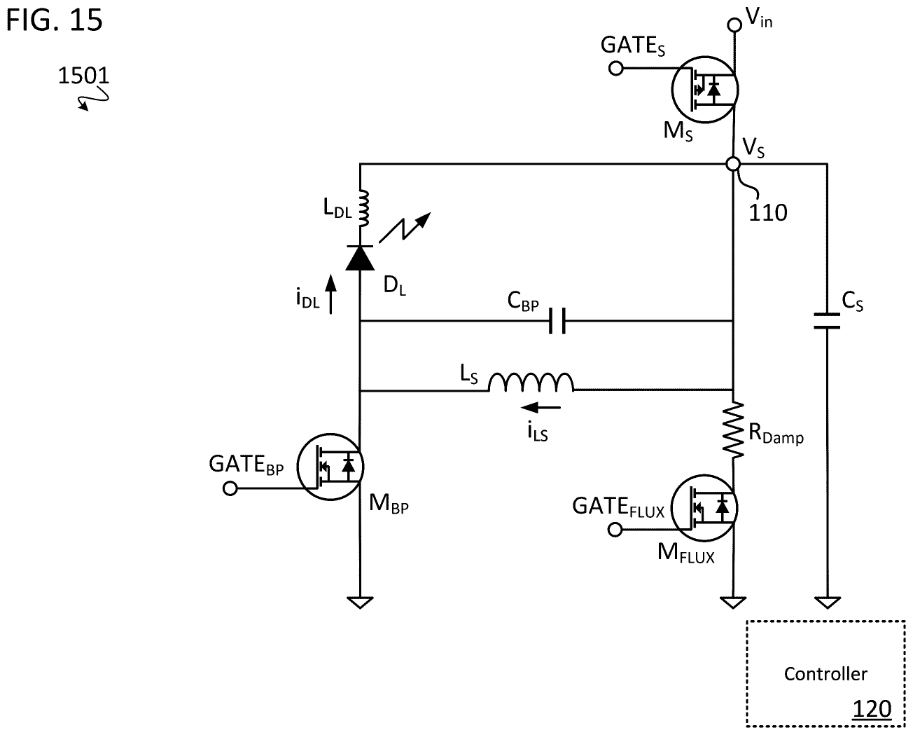

FIG. 15 shows a simplified circuit schematic of a pulsed laser diode driver 1501 of a ninth general topology, in accordance with some embodiments. The pulsed laser diode driver 1501 generally includes a source switch M_{S}, a source capacitor C_{S}, a damping resistor R_{Damp}, an inductor L_{S}, a bypass capacitor C_{BP}, a laser diode D_{L}, a bypass switch M_{BP}, and an optional flux switch M_{FLUX}. The flux switch M_{FLUX} is configured as a low-side switch. Also shown is the controller 120, node 110, a parasitic inductance L_{DL} of the laser diode D_{L}, a DC input voltage Vᵢₙ, a source voltage V_{S} at the source capacitor C_{S}, a current i_{LS} through the inductor L_{S}, a current i_{DL} through the laser diode D_{L}, a bypass switch gate driver signal GATE_{BP}, and a flux switch gate driver signal GATE_{FLUX}.

As shown in FIG. 15, a first terminal of the source switch M_{S} is directly electrically connected to the DC input voltage Vᵢₙ. In other embodiments (not shown), the source switch M_{S} may be replaced with a source resistor R_{S}. A second terminal of the source switch M_{S} is directly electrically connected to a first terminal of the source capacitor C_{S}. A second terminal of the source capacitor C_{S} is directly electrically connected to a bias voltage node such as ground. The second terminal of the source switch M_{S} is directly electrically connected to a cathode of the laser diode D_{L}, a first terminal of the damping resistor R_{Damp}, a first terminal of the bypass capacitor C_{BP}, and a first terminal of the inductor L_{S}. A second terminal of the damping resistor R_{Dm}p is directly electrically connected to a first terminal of the flux switch M_{FLUX}, and a second terminal of the flux switch M_{FLUX} is directly electrically connected to a bias voltage node such as ground. An anode of the laser diode D_{L} is directly electrically connected to a second terminal of the bypass capacitor C_{BP}, a second terminal of the inductor L_{S}, and to a first terminal of the bypass switch M_{BP}. A second terminal of the bypass switch M_{BP} is directly electrically connected to a bias voltage node such as ground.

The bypass switch M_{BP} is configured to receive the bypass switch gate driver signal GATE_{BP} at a gate node (e.g., from the controller 120), the bypass switch gate driver signal GATE_{BP} being operable to turn the bypass switch M_{BP} on or off based on a voltage level of the bypass switch gate driver signal GATE_{BP}. The source switch M_{S} is configured to receive the source switch gate driver signal GATE_{S} at a gate node (e.g., from the controller 120), the source switch gate driver signal GATE_{S} being operable to turn the source switch M_{S} on or off based on a voltage level of the source switch gate driver signal GATE_{S}. Similarly, the flux switch M_{FLUX} is configured to receive the flux switch gate driver signal GATE_{FLUX} at a gate node (e.g., from the controller 120), the flux switch gate driver signal GATE_{FLUX} being operable to turn the flux switch M_{FLUX} on or off based on a voltage level of the flux switch gate driver signal GATE_{FLUX}. Any or all of the bypass switch M_{BP}, the source switch M_{S}, and/or the flux switch M_{FLUX} can be implemented as N-type switches or P-type switches. In some embodiments, the bypass switch M_{BP}, the source switch M_{S}, and/or the flux switch M_{FLUX} are implemented as Silicon-based or Silicon-Carbide-based field-effect transistors (FETs).

In some embodiments, the pulsed laser diode driver 1501 is configured to receive the DC input voltage Vᵢₙ having a voltage range from about 10V to 20V, which is advantageously lower than an input voltage used by many conventional pulsed laser diode drivers. The inductor L_{S} is a physical component added to the pulsed laser diode driver 1501 (i.e., as opposed to a representation of a parasitic inductance caused by components or interconnections such as bond wires). Similarly, the bypass capacitor C_{BP} is a physical component added to the pulsed laser diode driver 1501 (i.e., as opposed to a representation of a parasitic capacitance). One advantage of using physical inductor and capacitor components rather than using parasitic inductances and capacitances is that values of the inductor L_{S} and the bypass capacitor C_{BP} can be easily modified by a designer or even an end-user. By comparison, conventional designs that rely on parasitic reactances may require re-design and/or re-layout to change an operating parameter.

As disclosed herein, values of the DC input voltage Vᵢₙ, the inductance of the inductor L_{S}, the capacitance of the source capacitor C_{S}, the resistance of the damping resistor R_{Damp}, and the capacitance of the bypass capacitor C_{BP} can advantageously be selected (“tuned”) to achieve a desired operation of the pulsed laser diode driver 1501 (e.g., a charge time, a pulse width, a pulse voltage, a pulse current). For example, a pulse width of the current i_{DL} flowing through the laser diode D_{L} can be tuned by adjusting the capacitance value of the bypass capacitor C_{BP}. A peak current level of the pulse of current i_{DL} flowing through the laser diode D_{L} can be tuned by adjusting the source voltage V_{S} on the supply capacitor C_{S}. A capacitance value of the source capacitor C_{S} can be tuned to adjust a timing delay of the high-current pulse and an upper range of the current i_{DL} through the laser diode D_{L}. Resistance values of the damping resistor R_{Damp} are dependent on the capacitance value of the supply capacitor C_{S} and can be tuned within a range of values such that at a lower resistance, a lower frequency resonance of the pulsed laser diode drivers disclosed herein is underdamped (e.g., at about R_{Damp}=0.1 Ohm), or is critically damped (e.g., at about R_{Damp}=0.4 Ohm). The damping resistor R_{Damp} is operable to prevent current of the generated resonant waveform from becoming negative which could thereby enable a body diode of the bypass switch M_{BP} or the flux switch M_{FLUX}. Although a resulting maximum current level of the current i_{DL} through the laser diode D_{L} is lower for the critically damped case, the current level can be easily adjusted by raising the voltage level of the DC input voltage Vᵢₙ.

In some embodiments, the DC input voltage Vᵢₙ is about 15V, the inductance of the inductor L_{S} is about 6 nH, the capacitance of the source capacitor C_{S} is about 100 nF, the resistance of the damping resistor R_{Damp} is about 0.1 Ohm, and the capacitance of the bypass capacitor C_{BP} is about 1 nF. In some embodiments, a voltage at the first terminal of the damping resistor R_{Damp} is received by the controller 120 to provide an indication of a current flow through the damping resistor R_{Damp}.

Typical resonant driver designs often require a damping resistor to minimize ringing duration. However, the added damping resistor R_{Damp} dissipates power which may lower the overall power efficiency of the design as compared to a resonant driver that does not have a damping resistor. Thus, in some embodiments, the pulsed laser diode driver 1501 advantageously allows current to flow through the damping resistor R_{Damp} during portions of a switching sequence (e.g., the switching sequence 300) in which the damping resistor R_{Damp} critically damps ringing, and prevents current from flowing through the damping resistor R_{Damp} during portions of the switching sequence when the damping resistor R_{Damp} is not needed to damp ringing. The pulsed laser diode driver 1501 allows current to flow through the damping resistor R_{Damp} by enabling the flux switch M_{FLUX} and prevents current from flowing through the damping resistor R_{Damp} by disabling the flux switch M_{FLUX}. Such dynamic control of current flow through the damping resistor R_{Damp} advantageously increases an overall power efficiency of the pulsed laser diode driver 1501 as compared to a pulsed laser diode driver circuit that allows current to flow through a damping resistor for the entirety of a switching sequence.

During operation, the source capacitor C_{S} is discharged through the inductor L_{S} by the bypass switch M_{BP}. This configuration provides a maximum peak current through the laser diode D_{L}, but requires the series damping resistor R_{Damp} to prevent the waveform from ringing for a long duration. Until the ringing stops and the voltage and current are zero, the bypass switch M_{BP} cannot be turned off. Unfortunately, the damping resistor R_{Damp} dissipates power as long as current flows through the damping resistor R_{Damp}. Thus, the pulsed laser diode driver 1501 advantageously provides an optimal power efficiency by preventing current from flowing through the damping resistor R_{Damp} during an initial precharge step (e.g., step 301 of FIG. 3), a preflux step (e.g., step 302 of FIG. 3), and a pulse generation step (e.g., step 303 of FIG. 3) of a switching sequence (e.g., the switching sequence 300 of FIG. 3). However, current is allowed, by the flux switch M_{FLUX}, to flow through the damping resistor R_{Damp} after the high-current pulse has been generated (e.g., at step 303 of FIG. 3) to remove remaining ringing by critically damping the RLC network of the pulsed laser diode driver 1501.

During the precharge step (e.g., step 301 of FIG. 3), the preflux step (e.g., step 302 of FIG. 3), and the pulse generation step (e.g., step 303 of FIG. 3) of the switching sequence (e.g., the switching sequence 300 of FIG. 3), the flux switch M_{FLUX} is disabled, thereby creating an undamped LC network. However, after pulse generation, the flux switch M_{FLUX} is enabled and the damping resistor R_{Damp} creates a parallel RLC network to critically damp ringing and thereby provide a maximum power efficiency and fast recovery of the pulsed laser diode driver 1501 to start a next switching sequence.

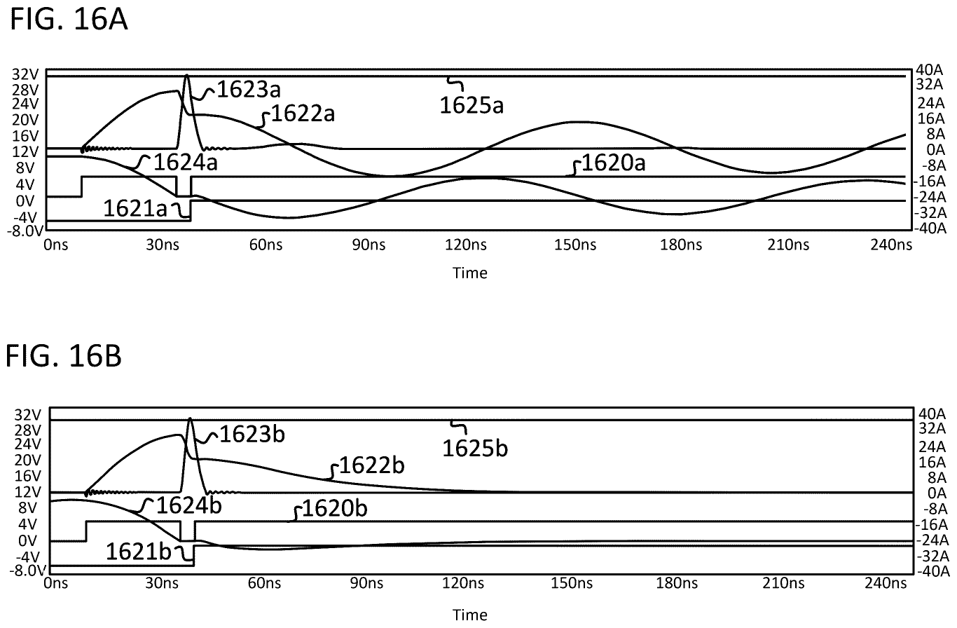

For example, FIGS. 16A-16B show simplified plots, 1620a-b, 1621a-b, 1622a-b, 1623a-b, 1624a-b, and 1625a-b, of signals related to operation of the pulsed laser diode driver 1501 shown in FIG. 15, in accordance with some embodiments. In particular, FIG. 16A illustrates operation of the pulsed laser diode driver 1501 when a damping resistor (i.e., the damping resistor R_{Damp}) underdamps ringing of the pulsed laser diode driver 1501. In comparison, FIG. 16B illustrates operation of the pulsed laser diode driver 1501 when a damping resistor (i.e., the damping resistor R_{Damp}) is used to critically damp ringing of the pulsed laser diode driver 1501.

With reference to FIGS. 16A-16B, the simplified plots illustrate voltage plots of the bypass switch gate driver signal GATE_{BP} 1620a-b, voltage plots of the flux switch gate driver signal GATE_{FLUX} 1621a-b, current plots of the current i_{L}S through the inductor L_{S} 1622a-b, current plots of the current i_{DL} through the laser diode D_{L} 1623a-b, voltage plots of the source voltage V_{S} 1624a-b at the source capacitor C_{S}, and voltage and current plots 1625a-b of a voltage and current source used to establish a plot scale, all over the same duration of time. Details of these signals are described below. The voltage plots of the bypass switch gate driver signal GATE_{BP} 1620a-b and the flux switch gate driver signal GATE_{FLUX} 1621a-b have been level-shifted for readability, but are, in actuality, low voltage inputs. Additionally, the voltage plots of the bypass switch gate driver signal GATE_{BP} 1620a-b and the flux switch gate driver signal GATE_{FLUX} 1621a-b assume that the flux switch M_{FLUX} and the bypass switch M_{BP} are NFET devices. However, if PFET devices are used instead, the polarity of the bypass switch gate driver signal GATE_{BP} 1620a-b and the flux switch gate driver signal GATE_{FLUX} 1621a-b are inverted.

In the example shown in FIG. 16A, with reference to FIG. 15, a resistance value of 10 Ohms is used for the damping resistor R_{Damp} of the pulsed laser diode driver 1501 in which L_{S}=6 nH, and C_{BP}=1 nF, and L_{DL} is about 1 nH. As expected, the waveforms 1622a and 1624a are very underdamped as shown by prolonged oscillations (i.e., “ringing”). As is known in the art, for a parallel RLC circuit, the damping coefficient d is expressed as:

$$d = \frac{1}{2 R} \times \sqrt{\frac{L}{C}} . \qquad ( Equation 1 )$$

Thus, if a critically damped waveform is desired, an optimal resistance R value of the damping resistor R_{Damp} can be determined by setting the damping coefficient d in Equation 1 to a value of d=1 and solving Equation 1 for R using the values mentioned above. In the example shown in FIG. 16B, a resistance value of 0.175 Ohms is used for the damping resistor R_{Damp} of the pulsed laser diode driver 1501. As expected, the waveforms 1622b and 1624b are thereby critically damped as shown by the absence of prolonged oscillations (i.e., “ringing”).

In some embodiments, the damping resistor R_{Damp} can be eliminated by using a weak switch having an on-resistance Rdson that is about the desired resistance value determined using Equation 1. In such embodiments, if adjustment of the resistance value is desired, a segmented FET can be used to thereby allow the on-resistance Rdson to be modified to match the damping resistance required.

Additionally, although it would initially appear that placing the source capacitor C_{S} in series with the laser diode D_{L} would raise the required anode voltage to pulse the laser diode D_{L}, the voltage and current of the source capacitor C_{S} are 90-degrees out of phase with one another. As shown by waveforms 1624a-b, because the current pulse (i.e., 1623a-b) through the laser diode D_{L} is advantageously aligned with a peak current amplitude, voltage at the source capacitor C_{S} at that time is zero due to the 90-degree phase shift. In some embodiments, a beginning of the high-current pulse could be determined by sensing when the source voltage V_{S} at the source capacitor C_{S} is at zero, at which point the high-current pulse through the laser diode D_{L} should begin.

For some applications, the amplitude of a high-current pulse delivered by a resonant circuit such as any of those disclosed herein may need to be adjusted in amplitude from pulse-to-pulse. Thus, in some embodiments, any of the pulsed laser drivers disclosed herein are advantageously operable to configure an amplitude of the high-current pulse delivered to one or more laser diodes on a pulse-to-pulse basis.

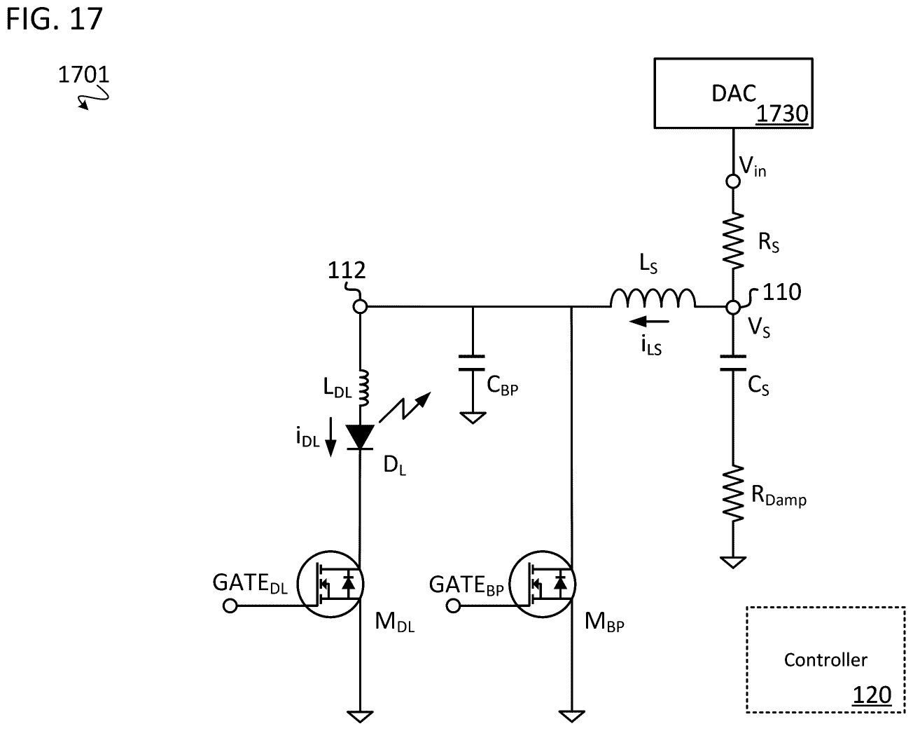

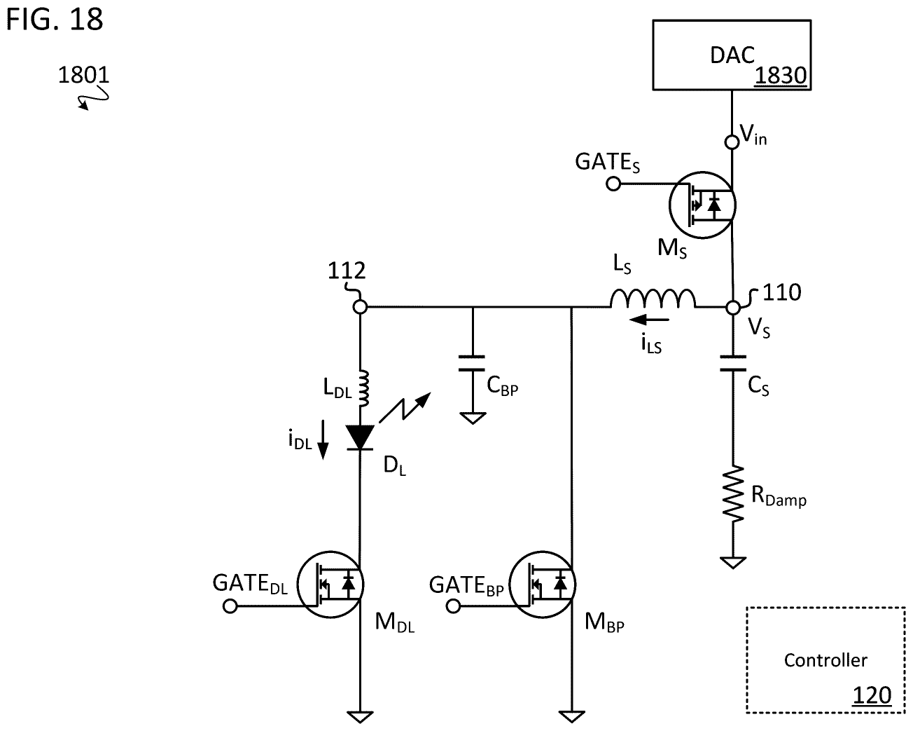

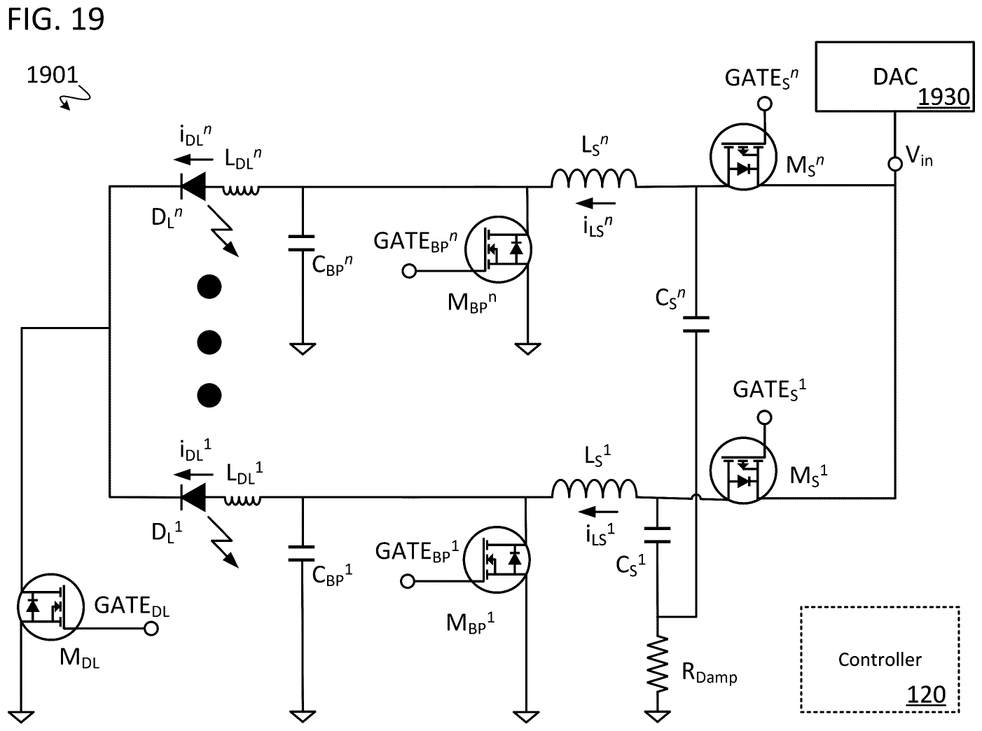

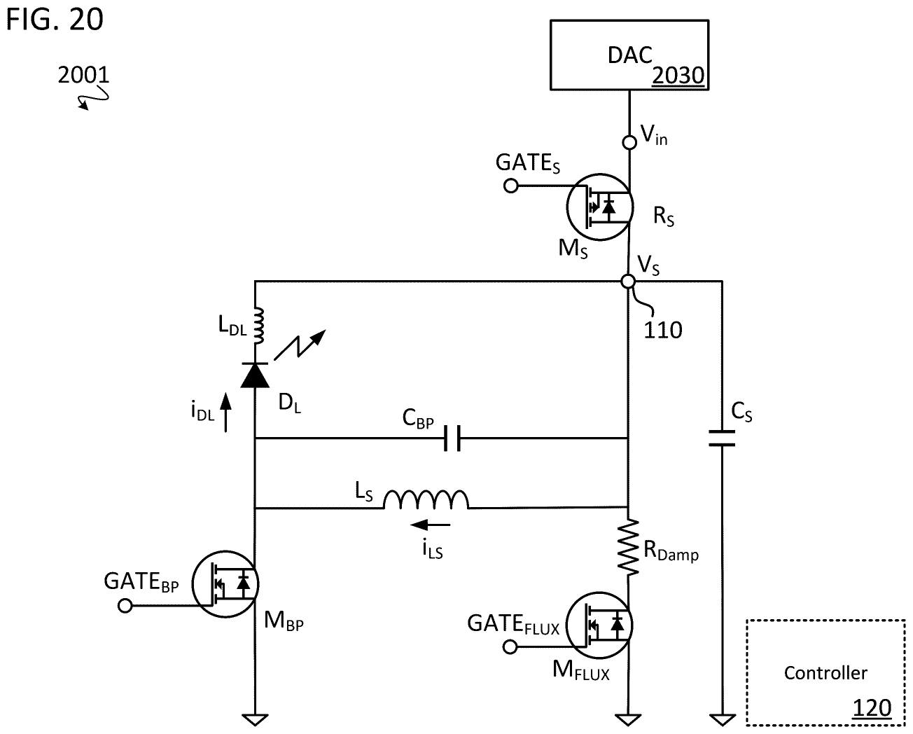

As shown in FIG. 17, FIG. 18, FIG. 19, and FIG. 20, the DC input voltage Vᵢₙ is advantageously provided by an adjustable voltage supply (i.e., a digital-to-analog converter (DAC)). In some embodiments, an output voltage level of the adjustable voltage supply is set using the controller 120. For example, FIG. 17 illustrates a pulsed laser diode driver circuit 1701 that is the same as the pulsed laser diode driver 101 shown in FIG. 1A with the exception that the DC input voltage Vᵢₙ is generated by a DAC 1730. FIG. 18 illustrates a pulsed laser diode driver circuit 1801 that is the same as the pulsed laser diode driver 1301 shown in FIG. 13A with the exception that the DC input voltage Vᵢₙ is generated by a DAC 1830. FIG. 19 illustrates a pulsed laser diode driver circuit 1901 that is the same as the pulsed laser diode driver 1308 shown in FIG. 13H with the exception that the DC input voltage Vᵢₙ is generated by a DAC 1930. FIG. 20 illustrates a pulsed laser diode driver circuit 2001 that is the same as the pulsed laser diode driver 1501 shown in FIG. 15 with the exception that the DC input voltage Vᵢₙ is generated by a DAC 2030. The examples shown in FIG. 17, FIG. 18, FIG. 19, and FIG. 20 are merely select examples of pulsed laser diode driver circuits configured to receive a DC input voltage from an adjustable voltage source (e.g., a DAC or a different adjustable voltage source as is known in the art). In some embodiments, any of the pulsed laser diode drivers 101-103, 401-404, 501-504, 601-604, 701-705, 801-802, 901-902, 1002-1004, 1301-1309, and/or 1501 are configured to receive the DC input voltage Vᵢₙ from an adjustable voltage source such as a DAC.

Use of an adjustable voltage supply, such as a DAC, to provide the DC input voltage Vᵢₙ to the pulsed laser diode driver circuits disclosed herein is possible because of the advantageously low input voltage requirements for such embodiments. In some embodiments, the adjustable voltage supply is clocked such that the adjustable voltage supply charges the source capacitor C_{S} described herein only during a first portion of a clock period (e.g., a positive portion). As such, the value of the DC input voltage Vᵢₙ and a current amplitude of the high-current pulse delivered to the laser diode(s) disclosed herein may be advantageously varied between consecutive high-current pulses through the laser diode(s).

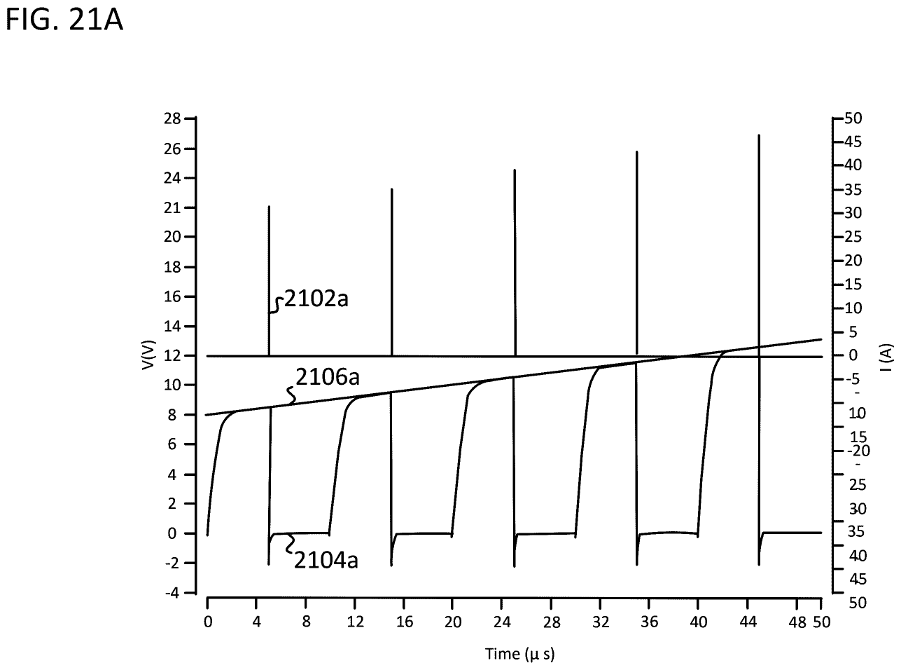

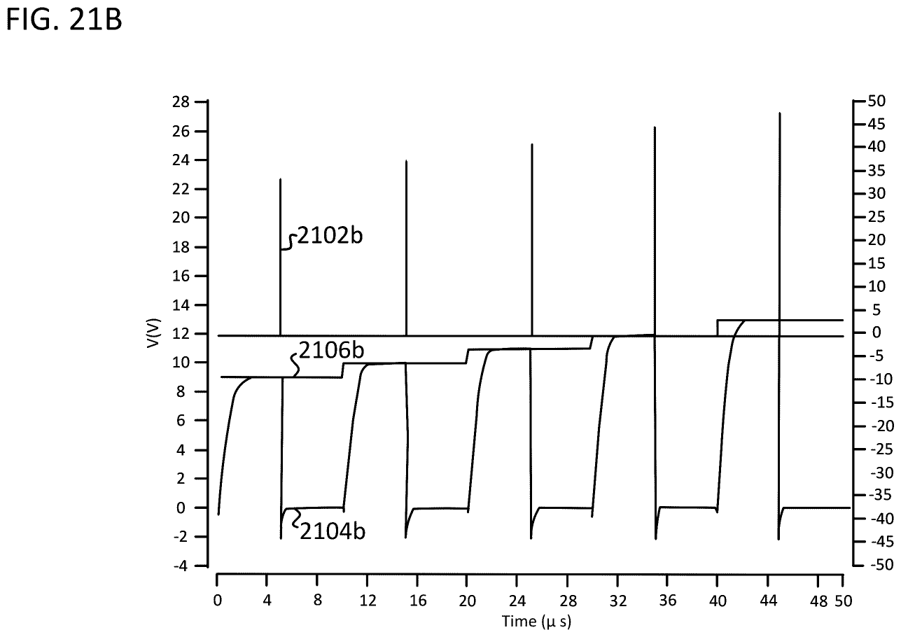

FIGS. 21A-21B show simplified plots, 2102a-b, 2104a-b, 2106a-b, of signals related to operation of the pulsed laser diode drivers shown in FIGS. 17, 18, 19, and 20, in accordance with some embodiments.

FIG. 21A includes examples of high-current pulses 2102a (i.e., through the laser diode(s) D_{L}), a source voltage V_{S} at the source capacitor C_{S} 2106a, and a linearly varying supply voltage 2106a of a variable input voltage supply (e.g., a DAC) that provides the DC input voltage Vᵢₙ. As shown, a current amplitude of the high-current pulses 2102a is advantageously varied from pulse to pulse.

FIG. 21B includes examples of high-current pulses 2102b (i.e., through the laser diode(s) D_{L}), a source voltage V_{S} at the source capacitor C_{S} 2106b, and a stepped supply voltage of a variable input voltage supply (e.g., a DAC) that provides the DC input voltage Vᵢₙ. As shown, a current amplitude of the high-current pulses 2102b is advantageously varied from pulse to pulse. Although an output voltage transition of the variable input voltage supply is fast, change in the source voltage level V_{S} at the source capacitor C_{S} 2106b is limited by the time constant of the source capacitor C_{S} and an on-resistance of an input switch (e.g., the source switch M_{S} described above) or an input resistor (e.g., the source resistor R_{S} described above).

### Multi-Channel Common-Cathode Pulsed Laser Diode Driver

Many applications using laser diodes, including, but not limited to, LiDAR, require the selective firing of one or more laser diodes having a common cathode that are part of a multiple-laser system. However, firing only one, or any number less than all of the lasers together is difficult using conventional solutions that have a common-cathode arrangement. As such, many (if not all) conventional LiDAR systems having multiple lasers address this difficulty by using separate lasers with separate anodes and cathodes.

Several examples of multi-channel common-cathode pulsed laser diode drivers are disclosed herein. As compared to conventional multi-channel laser diode driver circuits, the laser diode drivers disclosed herein transfer energy from a per-channel inductor rather than a capacitor to pulse a given laser diode. Energy is developed in a selected channel's inductor through the use of a respective per-channel “bypass switch” that creates flux in the inductor. By selectively generating flux in a desired channel's inductor, only laser diodes having flux stored in their channel's respective inductor will be pulsed. The other laser(s), whose inductor(s) have no energy stored, will not be pulsed.

Additionally, some example multi-channel common-cathode laser diode driver circuits disclosed below are advantageously configured to use only one energy storage capacitor (“source capacitor”) for providing the energy required to flux a given channel's inductor. In addition to providing for a smaller bill-of-materials as compared to implementations that use multiple charge storage capacitors, using a single capacitor also simplifies per-channel amplitude matching for a given laser diode driver circuit.

To elaborate, some use contexts for multi-channel laser diode drivers require that the channel-to-channel laser pulse light amplitude and/or duration not differ more than a given threshold (e.g., each pulse should differ no more than 5% as compared to other pulses of the laser diode driver). To accomplish this, a manufacturer may need to tightly control device value tolerances of components used within a given laser diode driver circuit. However, an LC circuit formed by a per-channel inductor and a per-channel energy storage capacitor (if used) may create a complicated manufacturing process in that the combination of components must be considered in addition to each component in isolation. By utilizing a single energy storage capacitor for multiple channels, component tolerance matching is simplified in that only the inductors must be within tolerance across each channel since the energy storage is common to each channel.

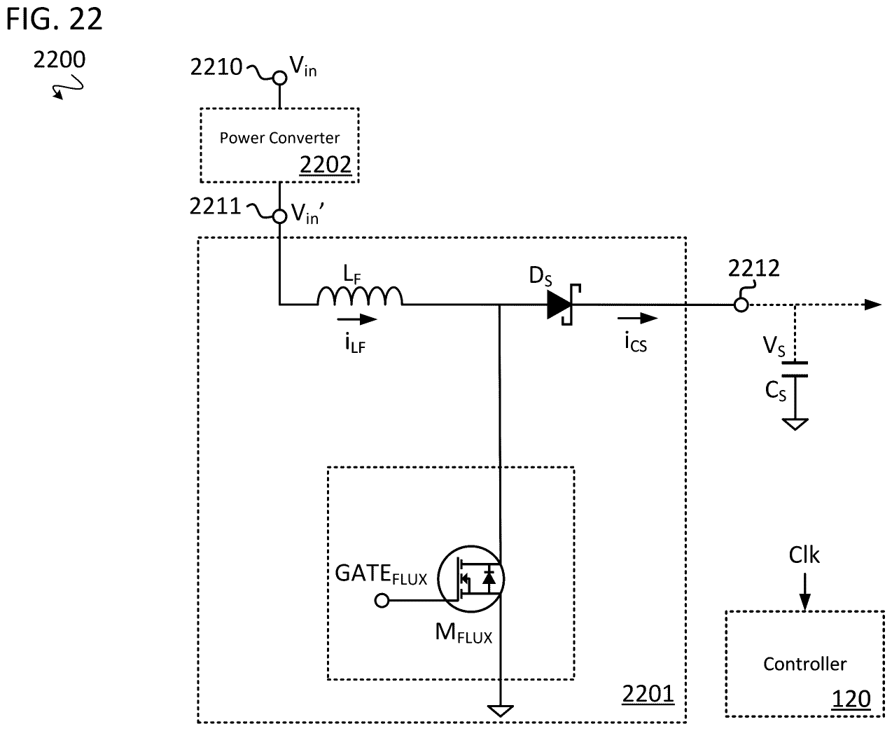

FIGS. 22-26E depict simplified circuits and operation details for multi-channel common-cathode pulsed laser diode driver circuits, in accordance with some examples.

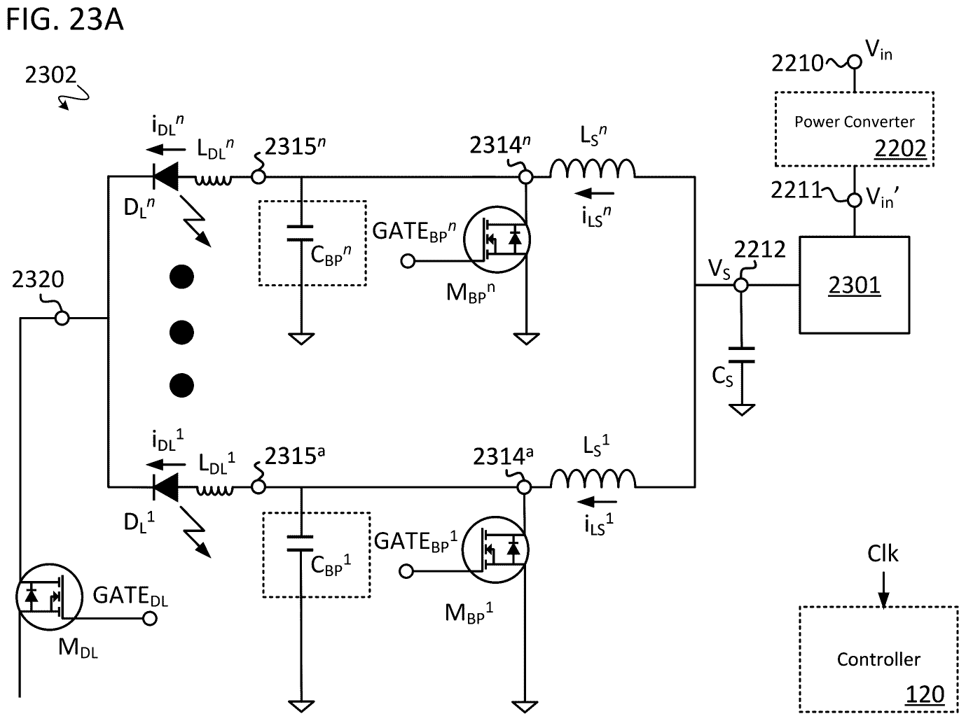

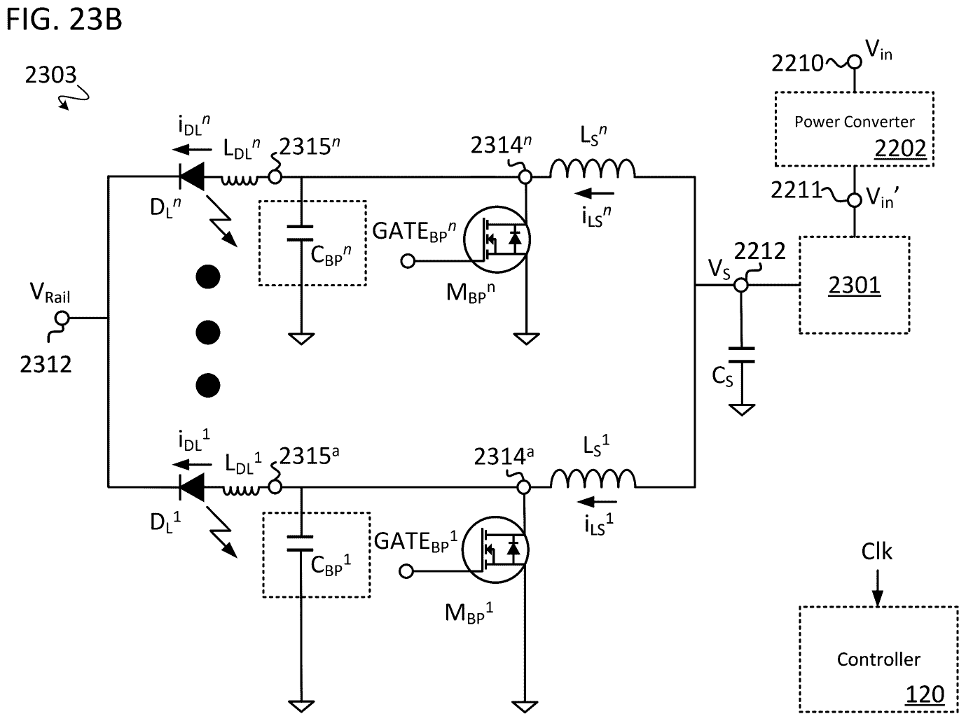

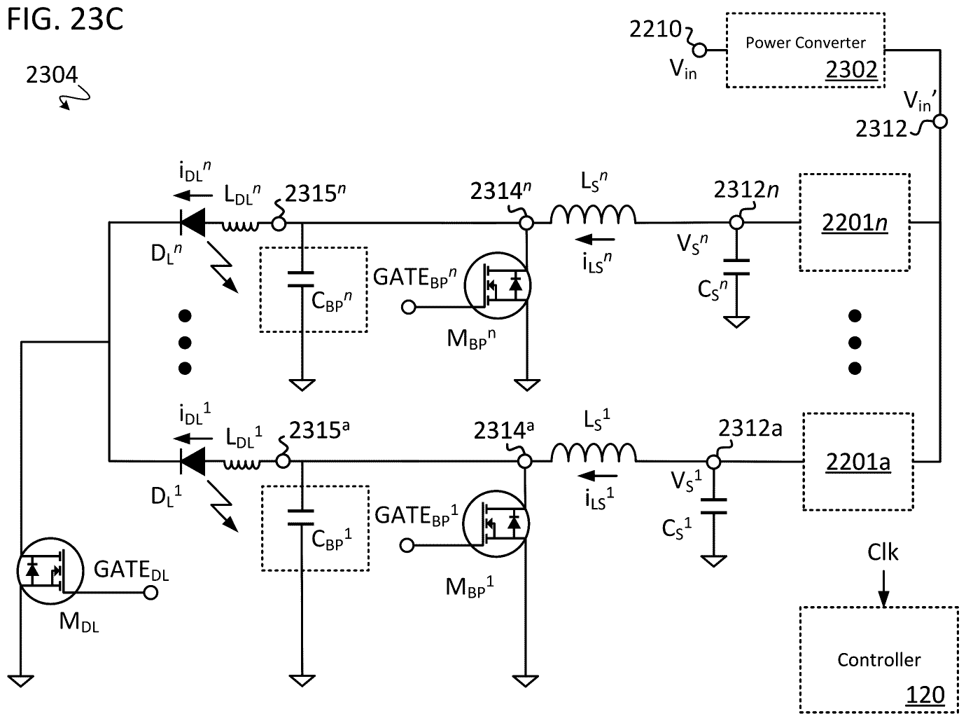

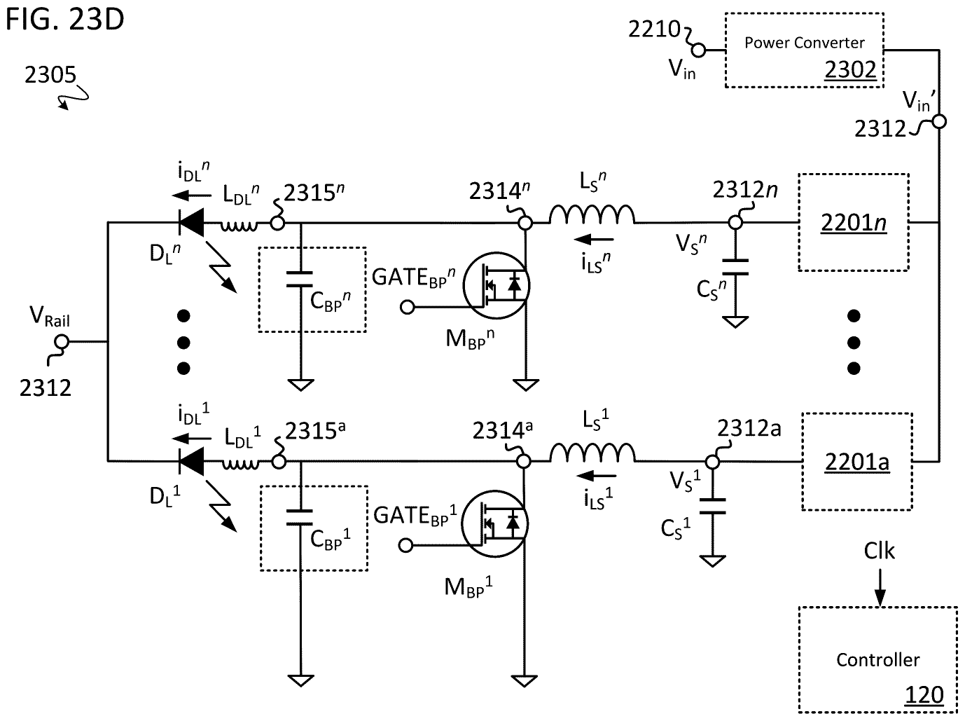

FIG. 22 shows a simplified schematic 2200 that includes a source capacitor (i.e., an energy storage capacitor) refresh circuit 2201 for rapidly recharging one or more source capacitors C_{S} shown in FIG. 23A through FIG. 23D. The simplified circuit schematic 2200 includes an optional power converter 2202 (e.g., a switch-mode power supply, a buck converter, a boost converter, etc.), an inductor L_{F} (i.e., a physical component that is not representative of a parasitic inductance of another component), a fluxing switch M_{FLUX}, and a Schottky diode D_{S}, connected as shown. A cathode of the Schottky diode D_{S} is configured to be directly electrically connected to one or more source capacitors C_{S} (i.e., a physical component that is not representative of a parasitic capacitance of another component). In some embodiments, the Schottky diode D_{S} may be replaced by a different circuit element (not shown) that is operable to control a current flow between the inductor L_{F} and the source capacitor C_{S} (e.g., a PN diode, or an actively controlled switch).

Also shown is the optional controller 120 described herein, a master clock signal Clk received by the controller 120, nodes 2210, 2211, 2212, a DC input voltage Vᵢₙ, a regulated input voltage Vᵢₙ′, a source voltage V_{S} developed at the source capacitor C_{S} based on a source capacitor refresh current i_{CS}, a current i_{LF} through the inductor L_{F}, and a fluxing switch gate driver signal GATE_{FLUX}.

In some examples, the regulated input voltage Vᵢₙ′ is generated by the optional power converter 2202 and is a higher or lower voltage level as compared to the DC input voltage Vᵢₙ. In other embodiments, the optional power converter 2202 is not present and the regulated input voltage Vᵢₙ′ is the same voltage level as compared to the DC input voltage Vᵢₙ. For example, in such examples, the regulated input voltage Vᵢₙ′ node connected to the inductor L_{F} may be configured to receive 3V to 12V from a battery or other power source.

As shown, a first terminal of the inductor L_{F} is configured to receive an input voltage (either the input voltage Vᵢₙ or the regulated input voltage Vᵢₙ′). A second terminal of the inductor L_{F} is directly electrically connected to a drain node of the fluxing switch M_{FLUX} and to an anode of the diode D_{S}. A source node of the fluxing switch M_{FLUX} is directly electrically connected to ground. A cathode of the diode D_{S} is configured to be directly electrically connected to a first terminal of one or more source capacitors C_{S} at the node 2212.

The optional controller 120 is operable to receive the master clock signal Clk to generate the fluxing switch gate driver signal GATE_{FLUX}. The fluxing switch M_{FLUX} is configured to receive the fluxing switch gate driver signal GATE_{FLUX} at a gate node, the fluxing switch gate driver signal GATE_{FLUX} being operable to turn the fluxing switch M_{FLUX} ON or OFF based on a voltage level of the fluxing switch gate driver signal GATE_{FLUX}. In some examples, the fluxing switch M_{FLUX} is implemented as a Gallium Nitride (GaN) Field Effect Transistor (FET). In other examples, the fluxing switch M_{FLUX} is implemented as a Silicon-based or Silicon-Carbide-based field-effect transistor (FET).

In some non-limiting examples, the regulated input voltage Vᵢₙ′ ranges from 3V to 80V, the inductance of the inductor L_{F} ranges from 10 nH to 1 uH, and the capacitance of the source capacitor C_{S} ranges from 20 pF to 20 nF. However, it is understood that the voltage ranges and component values may be extended beyond the ranges provided based on design and application requirements. For example, a high capacitance value for the source capacitor C_{S} could be used such that the source voltage V_{S} is not significantly reduced during laser channel firing as long as the source voltage V_{S} is kept below the forward threshold voltage of the laser diodes D_{L}¹n shown in FIG. 23A through FIG. 23D. A small amount of current in a laser diode is permittable as long as it does not exceed the current level at which the laser diode begins to emit light.

As mentioned above, the controller 120 is operable to generate one or more gate drive signals having a voltage level that is sufficient to control the fluxing switch M_{FLUX}. Additionally, the optional controller 120 is operable to sense a voltage and/or current at any of the nodes 2210, 2211, 2212, and at nodes that are similar to, or the same as those nodes, or at still other nodes described herein. The optional controller 120 may include one or more timing circuits, look-up tables, processors, memory, or other modules.

In the example shown, charge stored at the one or more source capacitors C_{S} is refreshed using the inductor L_{F}, a coupled inductor, or a transformer in a single switching cycle. The configuration shown in 2201 is a boost configuration; however in some examples, a buck configuration can be used, with a switch between node 2211 and the inductor L_{F}, a diode or another switch connected from that same inductor L_{F} terminal to ground, and the other terminal of the inductor L_{F} directly connected to node 2212. In other examples, a non-inverting buck-boost configuration or even a linear regulator can be used for 2201.

In the example shown, the current i_{LF} is developed through the inductor L_{F} by briefly connecting the inductor L_{F} from an input voltage source at node 2211 to ground by enabling the fluxing switch M_{FLUX}. After a sufficient current/flux is developed through the inductor L_{F}, the inductor L_{F} is operable to provide all the needed charge to the source capacitor C_{S} in one cycle by disabling the fluxing switch M_{FLUX}, thereby generating the source capacitor refresh current i_{CS}. In some examples, in order to reduce the time between pulse emission for different laser diodes, the fluxing switch M_{FLUX} can be enabled while an inductor current for a selected laser diode channel is ramping and/or during pulse emission for a laser diode, or for longer durations between pulse emission. In general, refreshing charge stored at the source capacitor C_{S} may occur at any time in between laser diode pulse emissions. In some embodiments, the fluxing switch M_{FLUX} is not present, in which case the inductor will charge the source capacitor(s) C_{S} to a voltage level that is higher than Vᵢₙ′(1.5×Vin′ to 2×Vᵢₙ′ depending on the losses in the circuit) each time after one or more laser diodes are pulsed, thereby discharging the source voltage V_{S} to near zero Volts. In some such examples in which the fluxing switch M_{FLUX} is not present, the inductor L_{F} and diode D_{S} refresh the source capacitor voltage V_{S} to a voltage level that is higher than the DC input voltage Vᵢₙ′ (minus the diode Vf) each time that the source capacitor voltage V_{S} is discharged below the DC input voltage Vᵢₙ′ (minus the diode Vf).

FIG. 23A through FIG. 23D show simplified circuit schematics of multi-channel common-cathode pulsed laser diode drivers, in accordance with some examples.

Each of the respective laser diode drivers shown in FIG. 23A-D are configured for multi-channel, individual control of multiple laser diodes. For example, the laser diode driver 2302 shown in FIG. 23A is configured to independently drive n laser diode channels, each having one or more laser diodes, where n is a number ranging from two to 128 or more. The laser diode driver 2302 is operable to cause a light pulse to be emitted from any individual laser diode of the multi-channel pulsed laser diode driver 2302 in isolation or combined with one or more other light pulses emitted from other laser diodes of the laser diode driver 2302.

The laser diode driver 2302 generally includes an optional power converter 2202 introduced and described with reference to FIG. 22, a source capacitor refresh circuit 2301 that is operable to refresh the charge stored at one or more source capacitors C_{S}, n inductors L_{S}¹ through L_{S}ⁿ, n bypass switches M_{BP}¹ through M_{BP}ⁿ, n optional bypass capacitors C_{BP}¹ through C_{BP}ⁿ, n laser diodes D_{L}¹ through D_{L}ⁿ, and a laser diode switch M_{DL}, coupled as shown. Also shown is the controller 120 discussed above, respective parasitic inductances L_{DL}¹ through L_{DL}ⁿ of the laser diodes D_{L}¹ through D_{L}n respective currents i_{LS}¹ through i_{LS}ⁿ of the inductors L_{S}¹ through L_{S}ⁿ, respective currents i_{DL}¹ through i_{DL}ⁿ of the laser diodes D_{L}¹ through D_{L}ⁿ, and nodes 2210, 2211, 2212, 2314^{a-n}, 2315a-n, and 2320.

The optional controller 120 is operable to generate one or more gate drive signals having a voltage level that is sufficient to control the switches M_{BP}¹⁻ⁿ and M_{DL}. Additionally, the optional controller 120 is operable to sense a voltage and/or current at any of the nodes 2210, 2211, 2212, 2314^{a-n}, 2315^{a-n}, and 2320, and at nodes that are similar to, or the same as those nodes, or at still other nodes described herein.

The capacitor refresh circuit 2301 may be implemented using the capacitor refresh circuit 2201 shown and described with reference to FIG. 22, or may be any other circuit that is operable to refresh a stored charge at the source capacitor C_{S} such circuits generally including switch-mode power supplies, boost converters, buck converters, etc.

In some embodiments, the bypass switches M_{BP}¹ through M_{BP}ⁿ and the laser diode switch M_{DL} are each N-type FET switches and advantageously do not require bootstrap circuitry to drive the respective gates of those switches because of their respective low-side configurations.

The inductor L_{S}¹, the bypass switch M_{BP}¹, the optional bypass capacitor C_{BP}¹, and the laser diode D_{L}¹ are associated with a first channel of the laser diode driver 2302. Similarly, the inductor L_{S}ⁿ, the bypass switch M_{BP}ⁿ, the optional bypass capacitor C_{BP}ⁿ, and the laser diode D_{L}ⁿ are associated with an n^{th} channel of the multi-channel pulsed laser diode driver 1002, where n is a number greater than or equal to two (e.g., two, three, four, eight, 16, 32, 64, 128, etc.). In contrast, a single source capacitor C_{S} in the example shown is advantageously shared by all n channels of the laser diode driver 2302. As mentioned above, use of a single source capacitor C_{S} not only reduces a bill-of-materials for manufacturing the laser diode driver circuit 2302 as compared to circuits having a per-channel source capacitor but also simplifies device tolerance matching as compared to circuits having a per-channel source capacitor.

By controlling (e.g., by the controller 120) respective switch timings (i.e., an on/off duration) of the bypass switches M_{BP}¹ through M_{BP}ⁿ in conjunction with controlling a switch timing of the laser diode switch M_{DL}, each of the laser diodes D_{L}¹ through D_{L}ⁿ are advantageously independently controlled.

A simplified example for operating the laser diode driver 2302 is described as follows. At a first time, while the bypass switches M_{BP}¹⁻ⁿ and the laser diode switch M_{DL} are OFF, the source capacitor C_{S} is charged to a defined level via the source capacitor refresh current i_{cs} such that the source capacitor C_{S} stores sufficient energy to fire the number of laser diodes desired. Because a single source capacitor C_{S} is used to drive each of the n channels of the laser diode driver 2302, the charging time for each channel is advantageously the same, thereby simplifying control of the laser diode driver 2302 as compared to a circuit that uses a dedicated source capacitor for each channel.

At a next time, energy is transferred from the source capacitor C_{S} to one or more inductors L_{S}¹⁻ⁿ by enabling the bypass switch M_{BP}¹⁻ⁿ for the selected channel(s) for a prescribed amount of time (‘T_{flux}”). Due to the way energy is transferred from a capacitor to an inductor, that time (to first order) is defined by the following equation:

$${T}_{fl ux} = 0.5 \times π \times \sqrt{{L}_{S} \times {C}_{S}} . \qquad ( Equation 2 )$$

In some examples, the T_{flux} time can be increased or decreased slightly to reduce the ringing and possibility of unwanted current in the laser that was pulsed or any of the other lasers. By turning on a desired channel's bypass switch M_{BP}¹⁻ⁿ for T_{flux} time, the source capacitor C_{S} will be fully discharged (i.e., the source voltage V_{S} will be at or near zero-Volts) and that channel's inductor current i_{LS}¹⁻ⁿ will be at its peak. Because the source capacitor C_{S} is discharged below the forward threshold voltage of the laser diodes D_{L}¹⁻ⁿ during time T_{flux}, the laser diode switch M_{DL} can be turned on during that channel's pulse emission without building positive current in any other channel's inductors L_{S}¹⁻ⁿ.

After time T_{flux} (or at a point during time T_{flux} where the source voltage C_{S} has dropped below the forward threshold voltage of the laser diodes D_{L}¹n), the selected channel's bypass switches M_{BP}¹⁻ⁿ are turned OFF and the laser diode switch M_{DL} is enabled. Energy is thereby transferred from the selected channel's inductor L_{S}¹⁻ⁿ to that channel's laser diode D_{L}¹⁻ⁿ as a high-current pulse (e.g., 20 A) thereby causing laser light pulse emission.

The laser's pulse width will be determined by the value of the bond wire and other parasitic inductances, L_{DL}¹⁻ⁿ, in combination with an output capacitance of that channel's bypass switch M_{BP}¹⁻ⁿ.

In some examples, a pulse width of the high-current pulse may be “tuned” by adding additional capacitance in parallel with that channel's bypass switch M_{BP}¹⁻ⁿ using the optional bypass capacitors C_{BP}¹⁻ⁿ as described in detail above.

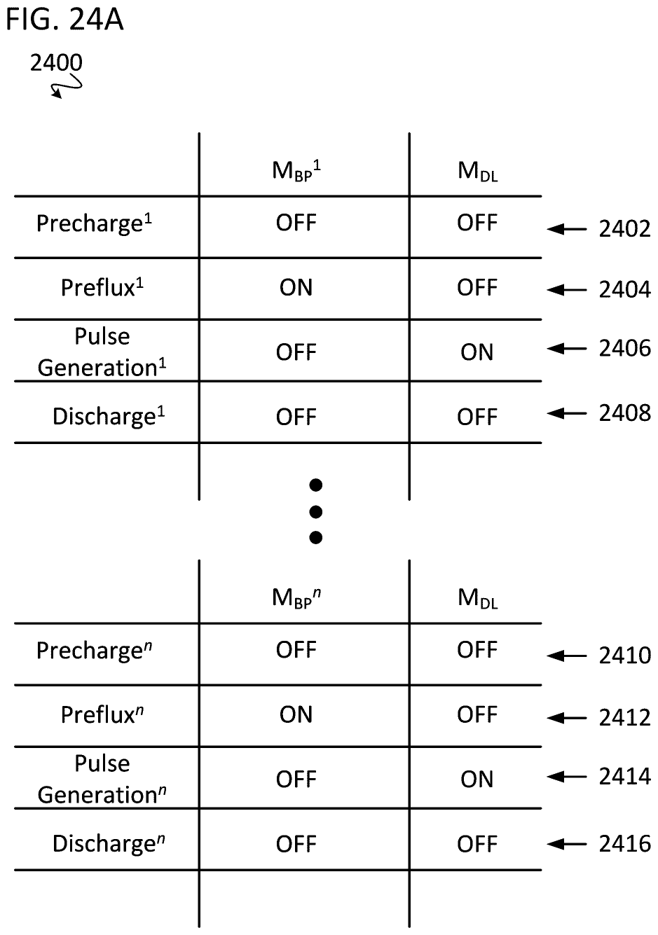

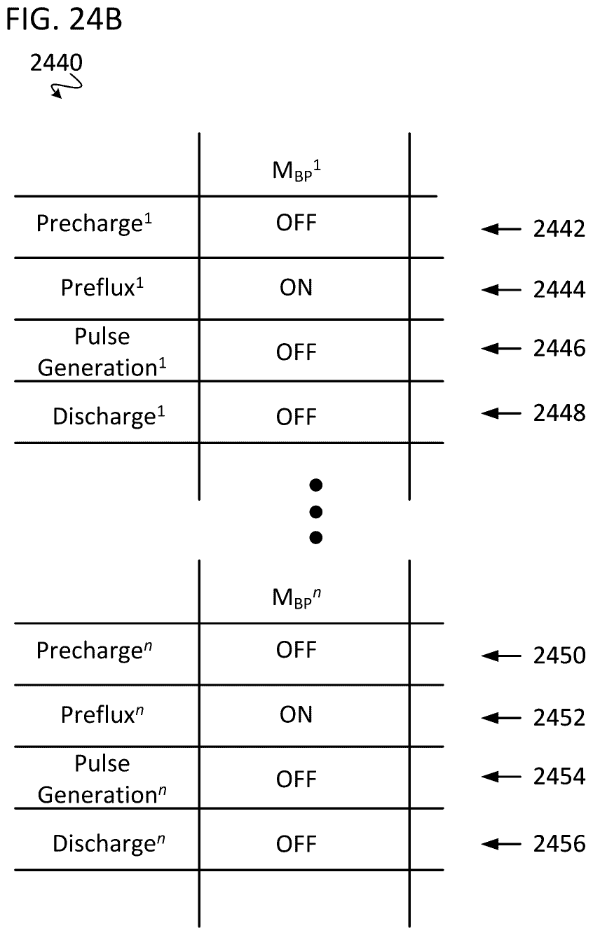

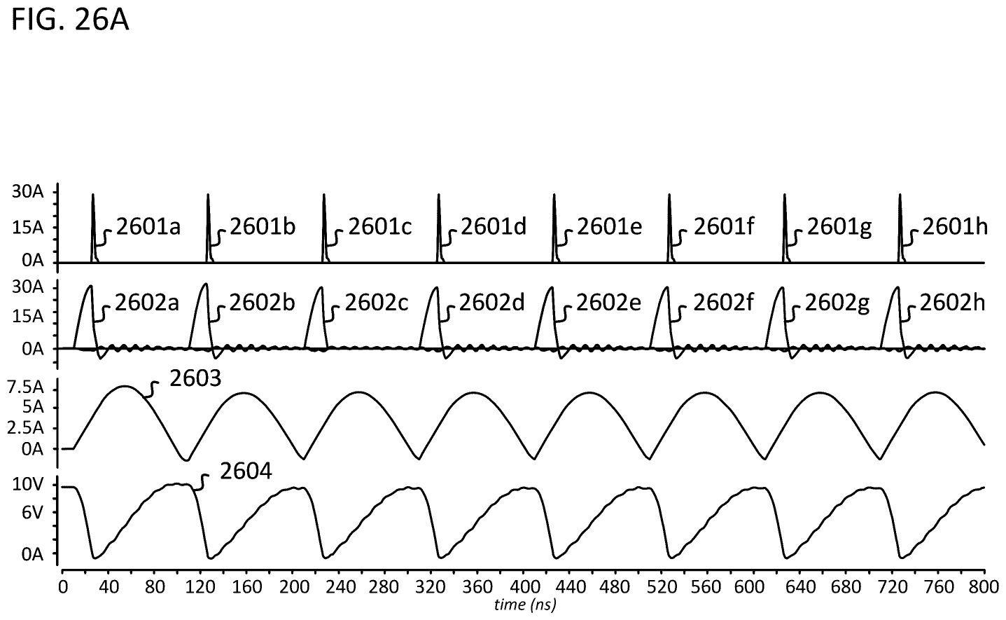

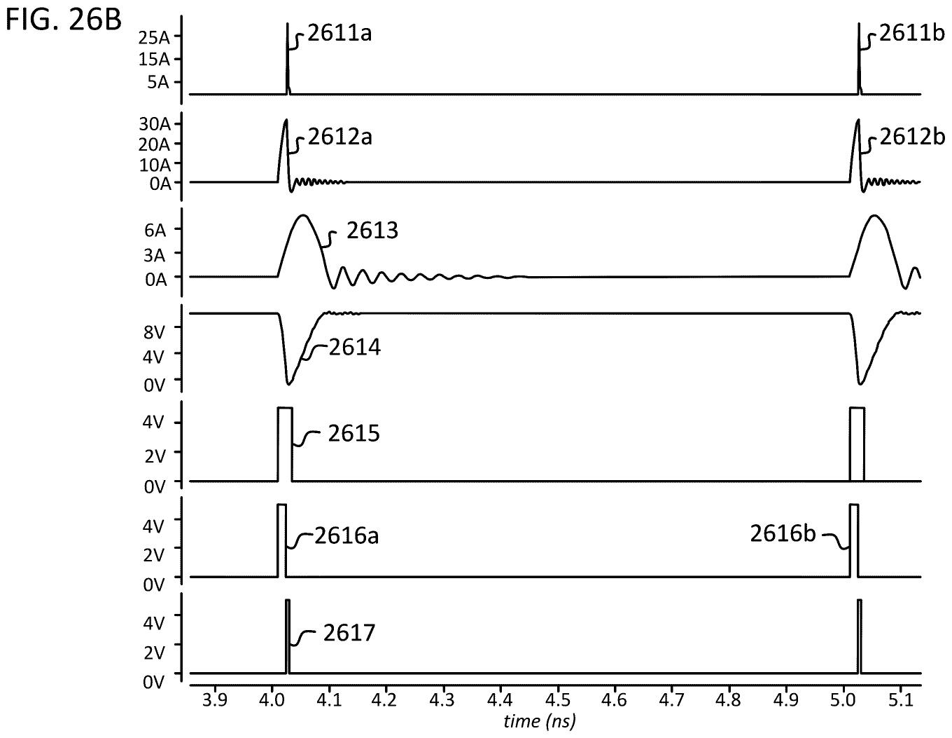

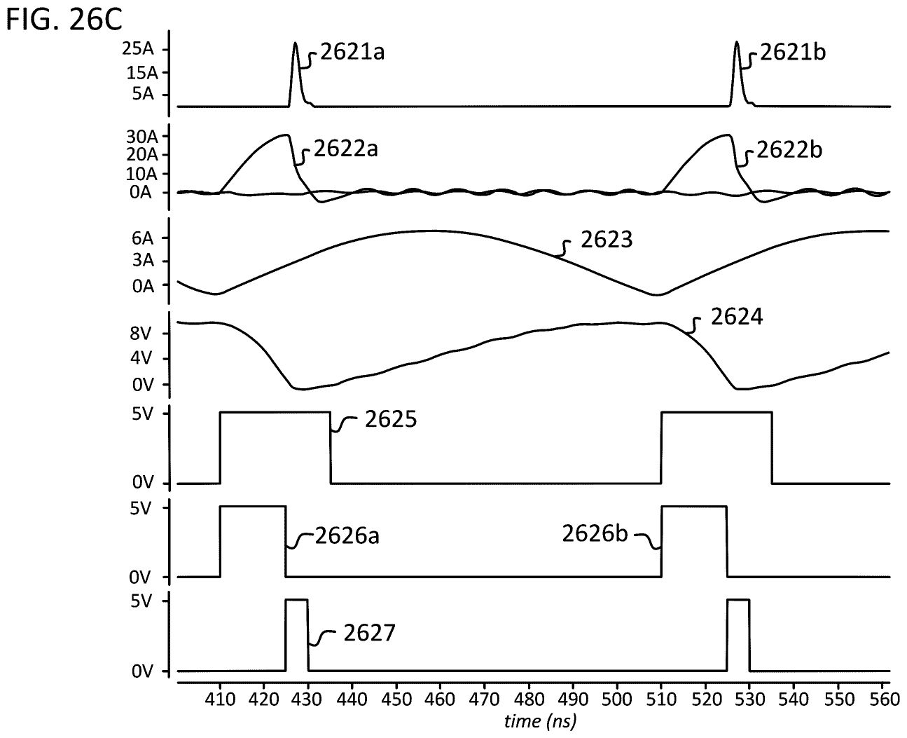

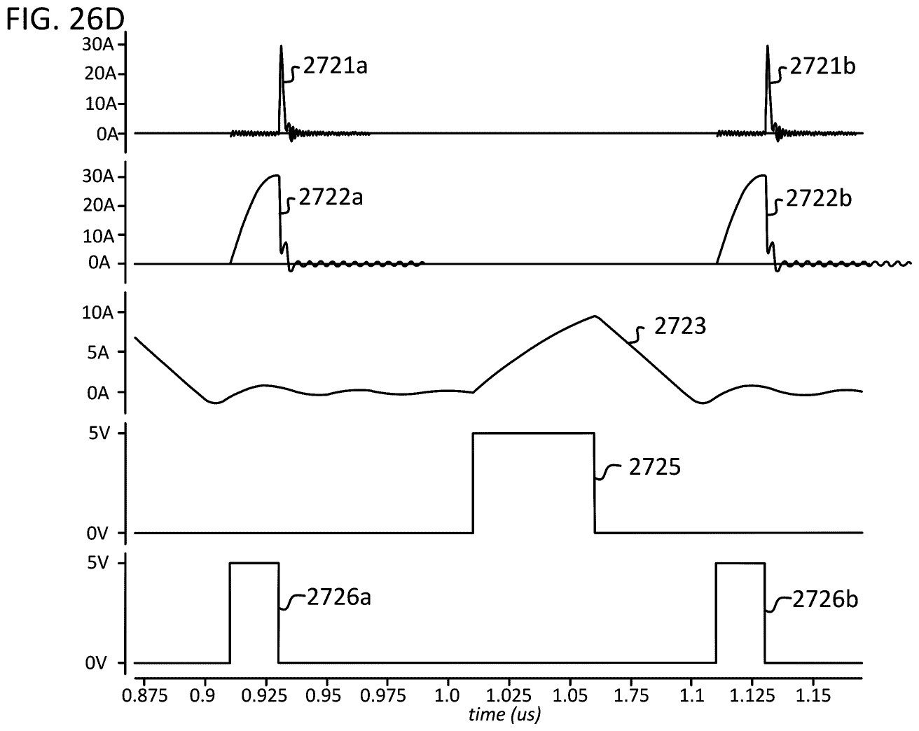

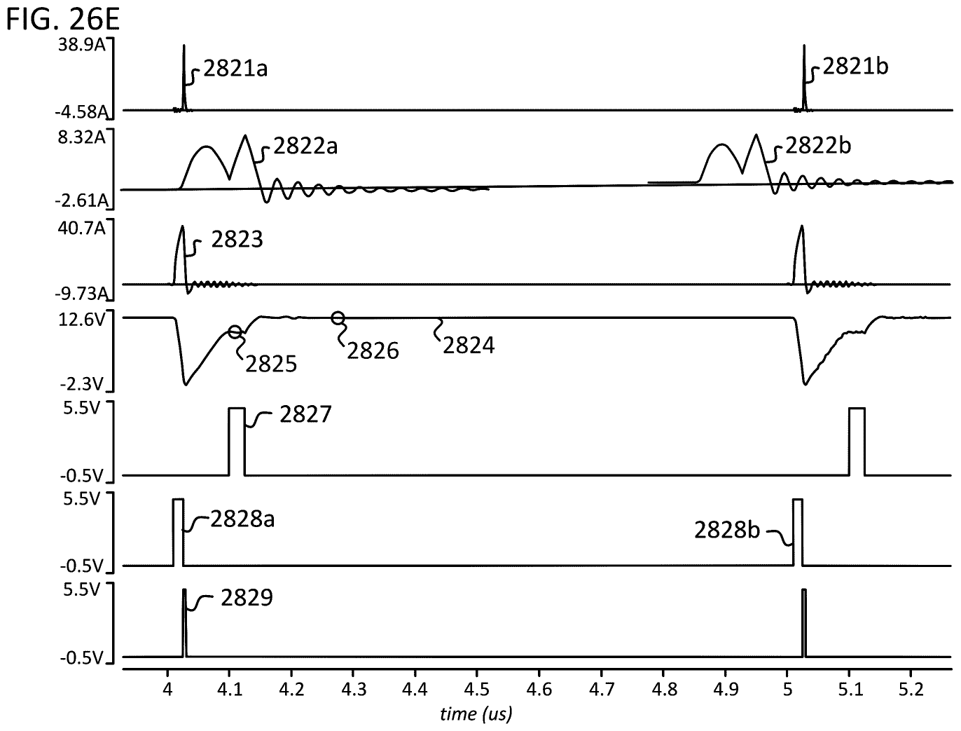

After the high-current pulse emission duration has elapsed, the laser diode switch M_{DL} is turned OFF, or the laser diode may fire again, although at a lower power, due to ringing. After the laser diode switch M_{DL} and the selected channel's bypass switches M_{BP}¹⁻ⁿ are turned OFF, the source voltage V_{S} will be naturally charged above zero (to Vᵢₙ′ minus the forward-voltage of the Schottky diode D_{S}) due to current in the inductor L_{F} (shown in FIG. 22). However, because the laser diode switch M_{DL} is OFF, the common cathode node 2320 of the laser diodes D_{L}¹⁻ⁿ will rise to a high enough voltage to prevent current in the lasers. At this point, pulse emission for the same channel or a different channel may commence in the same manner as described above. Operation details are further described in detail with reference to FIG. 24A and FIG. 26A through FIG. 26E.

In some examples, after the high-current pulse emission duration has elapsed, the bypass switches M_{BP}¹⁻ⁿ associated with the laser diode or laser diodes that were pulsed may also be turned back on for a brief time (for example 10 ns) in order to fully discharge the source capacitor(s) C_{S} and prevent ringing in the associated inductor L_{S}¹⁻ⁿ due to any remaining current.

In another example circuit, the laser diode driver 2303 shown in FIG. 23B is configured to independently drive n laser diodes where n is a number ranging from two to 128 or more and generally includes all of the elements introduced and described with reference to FIG. 23A. However, as compared to the laser diode driver 2302 shown in FIG. 23A, the laser diode driver 2303 advantageously omits the laser diode switch M_{DL} and instead includes a node 2312 that is tied to a low impedance voltage source or reference level V_{Rail} (e.g., ground, V_{S}, Vᵢₙ′, or Vᵢₙ). In some examples, V_{Rail} may be ground, or a DC supply voltage source such as Vᵢₙ at node 2210 or Vᵢₙ′ at node 2211. The laser diode switch M_{DL} may be omitted in some designs because some laser diode implementations stack many (for example 8) P-N junctions in series and therefore achieve a relatively high forward voltage (for example 6V) in order to emit any light. In some examples, one or more diodes can be included (not shown) with their anodes connected to the common cathode node 2312 and their cathode(s) connected to V_{Rail} (e.g., ground, V_{S}, Vᵢₙ′, or Vᵢₙ) to reduce the negative voltage developed across the laser diodes.

In yet another example, the laser diode driver 2304 shown in FIG. 23C is configured to independently drive n laser diodes where n is a number ranging from two to 128 or more and generally includes all of the elements introduced and described with reference to FIG. 23A. However, as compared to the laser diode driver 2302 shown in FIG. 23A, the laser diode driver 2304 includes two or more source capacitors C_{S}¹⁻ⁿ. In some examples, each channel of the laser diode driver 2304 is directly electrically connected to a respective source capacitor. In other examples, several channels of the laser diode driver 2304 may grouped together with a respective source capacitor for that group. In such examples, though the bill-of-materials is increased for the laser diode driver 2304 as compared to that of the laser diode drivers 2302 and 2303, pulse emission may occur more rapidly because a first channel(s) dedicated source capacitor may be advantageously recharged during a second channel(s) laser diode pulse emission.

In still yet another example, the laser diode driver 2305 shown in FIG. 23D is configured to independently drive n laser diodes where n is a number ranging from two to 128 or more and generally includes all of the elements introduced and described with reference to FIG. 23C. However, as compared to the laser diode driver 2304 shown in FIG. 23C, the laser diode driver 2305 advantageously omits the laser diode switch M_{DL} and instead includes a node 2312 which is tied to a low impedance voltage source or reference level V_{Rail} (e.g., ground, V_{S}, Vᵢₙ′, or Vᵢₙ). In some examples, V_{Rail} may be ground, or a DC supply voltage source such as Vᵢₙ at node 2210 or Vᵢₙ′ at node 2211. As described above, the laser diode switch M_{DL} may be omitted in some designs because some laser diode implementations stack many (for example 8) P-N junctions in series and therefore achieve a relatively high forward voltage (for example 6V) in order to emit any light. In some examples, one or more diodes can be included (not shown) with their anodes connected to the common cathode node 2312 and their cathode(s) connected to V_{S}, Vᵢₙ′, or Vᵢₙ to reduce the negative voltage developed across the laser diodes.

FIG. 24A illustrates a portion of an example switching sequence 2400 for multi-channel operation of the pulsed laser diode drivers 2302 or 2304 shown in FIG. 23A/FIG. 23C respectively. In the example shown, each channel of the pulsed laser diode driver 2302/2304 is fired sequentially and in isolation.

At a first precharge step 2402 for a first channel, a first bypass switch M_{BP}¹ and the laser diode switch M_{DL} are OFF. At a preflux stage for the first channel at step 2404, the first bypass switch M_{BP}¹ is enabled and the laser diode switch M_{DL} remains OFF. In some examples, step 2404 is conducted directly before a pulse generation stage at step 2406. In other embodiments, step 2404 is conducted earlier than directly before the pulse generation stage at step 2406. In either example, at the pulse generation stage for the first channel at step 2406, the first bypass switch M_{BP}¹ is disabled and the laser diode switch M_{DL} is enabled. When the laser diode switch M_{DL} is enabled, voltage at the anode of the laser diode D_{L}¹ rises quickly until the bandgap voltage of the laser diode D_{L}¹ is overcome and a high-current resonant pulse is generated through the laser diode D_{L}¹, thereby causing light emission. Because of a resonant circuit formed by the parasitic inductance L_{DL} of the laser diode D_{L}¹, the voltage developed at the anode of the laser diode D_{L}¹ will advantageously rise as high as necessary to overcome the bandgap voltage of the laser diode D_{L}¹ and will generally be higher than the source voltage V_{S}. In some examples, a pulse-width of the laser light emission can be advantageously reduced (e.g., to increase the spatial resolution of a laser-based distance measurement system) by turning off the laser diode switch M_{DL} while there is still current in the laser diode or even before the current in the laser diode reaches its peak.

At a discharge stage for the first channel at step 2408, the first bypass switch M_{BP}¹ and the laser diode switch M_{DL} are both disabled, and any remaining charge on the source capacitor C_{S}, or the source capacitor associated with the first channel (e.g., C_{S}¹) may be fully discharged by turning the associated bypass switch M_{BP}¹ back on for a short amount of time (e.g., 10 ns). By allowing the source capacitor C_{S} to fully discharge, the timing required to fully charge the source capacitor for the next channel remains consistent cycle-to-cycle.

Pulse generation is then performed similarly for the same or additional channels of the laser diode pulsed laser diode drivers 2302 or 2304 as desired. For example, at an n^{th} precharge step 2410 for an n^{th} channel, an n^{th} bypass switch M_{BP}ⁿ and the laser diode switch M_{DL} are off. At a preflux stage for the n^{th} channel at step 2412, the n^{th} bypass switch M_{BP}ⁿ is enabled to develop current through an n^{th} inductor L_{S}ⁿ, and the laser diode switch M_{DL}n remains OFF. At a pulse generation stage for the n^{th} channel at step 2414, the n^{th} bypass switch M_{BP}ⁿ is disabled and the laser diode switch M_{DL} is enabled to generate a high-current pulse through the laser diode D_{L}n. At a discharge stage for the n^{th} channel at step 2416, the n^{th} bypass switch M_{BP}ⁿ and the laser diode switch M_{DL} are both disabled, and any remaining charge on the source capacitor C_{S}, or the source capacitor associated with the n^{th} channel (e.g., C_{S}″) may be fully discharged.

FIG. 24B illustrates a portion of an example switching sequence 2440 for multi-channel operation of the pulsed laser diode drivers 2303 or 2305 shown in FIG. 23B/FIG. 23D, respectively, in accordance with some examples. In the example shown, each channel of the pulsed laser diode driver 2303 or 2305 is fired sequentially and in isolation. However, as mentioned above, the common cathode node 2312 of the laser diodes D_{L}¹⁻ⁿ is tied to a low impedance voltage node V_{Rail} such that the laser diode switch MDL may advantageously be omitted.

At a first precharge step 2442 for a first channel, a first bypass switch M_{BP}¹ is off. At a preflux stage for the first channel at step 2444, the first bypass switch M_{BP}¹ is enabled to develop current through that channel's inductor L_{S}¹. At a pulse generation stage for the first channel at step 2446, the first bypass switch M_{BP}, is disabled. When the bypass switch M_{BP}¹ is transitioned to the OFF-state, voltage at the anode of the laser diode D_{L}¹ rises quickly, until the bandgap voltage of the laser diode D_{L}¹ is overcome and the laser diode D_{L}¹ begins to generate current to generate a high-current pulse and thereby cause light-pulse emission. Because of a resonant circuit formed by the parasitic inductance L_{DL} of the laser diode D_{L}¹, the voltage formed at the anode of the laser diode D_{L}¹ will advantageously rise as high as necessary to overcome the bandgap voltage of the laser diode D_{L}¹ and will generally be higher than the source voltage V_{S}.

At a discharge stage for the first channel at step 2448, the first bypass switch M_{BP}¹ remains disabled, and any remaining charge on the source capacitor C_{S}, or the source capacitor associated with the first channel (e.g., C_{S}¹) may be fully discharged. By allowing the source capacitor to fully discharge, the timing required to fully charge the source capacitor for the next channel remains consistent cycle-to-cycle.

Pulse generation is then performed similarly for the same or additional channels of the laser diode pulsed laser diode drivers 2303 or 2305 as desired. For example, at an n^{th} precharge step 2450 for an n^{th} channel, an n^{th} bypass switch M_{BP}ⁿ is off. At a preflux stage for the n^{th} channel at step 2452, the n^{th} bypass switch M_{BP}ⁿ is enabled to develop current through that channel's inductor L_{S}ⁿ. At a pulse generation stage for the n^{th} channel at step 2454, the n^{th} bypass switch M_{BP}ⁿ is disabled to generate a high-current pulse through the laser diode D_{L}ⁿ. At a discharge stage for the n^{th} channel at step 2456, the n^{th} bypass switch M_{BP}ⁿ remains disabled and any remaining charge on the source capacitor C_{S}, or the source capacitor associated with the first channel (e.g., C_{S}ⁿ) may be fully discharged.

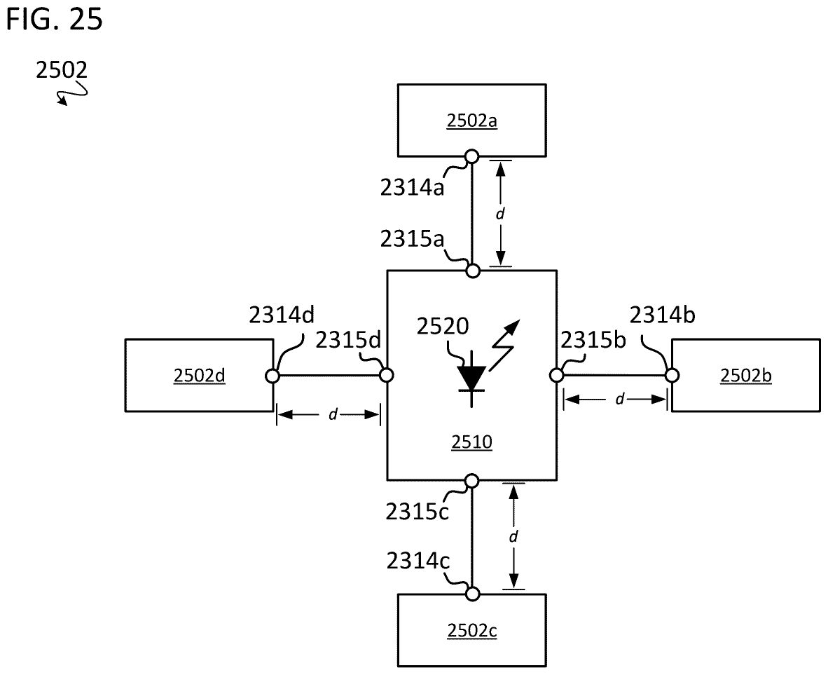

FIG. 25 illustrates a high-level depiction of a physical layout for the laser diode drivers 2302, 2303, 2304, and 2305 shown in FIG. 23A-23D, in accordance with some examples. In some examples, the inductors L_{S}¹⁻ⁿ and bypass switches M_{BP}¹⁻ⁿ are arrayed symmetrically around a group of common-cathode laser diodes on the same chip in order to match impedances for each fluxing circuit (i.e., a circuit including a respective inductor L_{S}¹⁻ⁿ and associated bypass switch M_{BP}¹⁻ⁿ) to each laser diode D_{L}¹⁻ⁿ being driven. In some such examples, the fluxing circuits can be placed on the top and the bottom of a board in order to reduce the total area and impedance for driving many laser diodes. For such a configuration, the laser diode switch M_{DL} (if used) can be placed on the bottom of the board under the common cathode laser diodes.

In the example shown, laser diodes 2520 having a common cathode node (e.g., a quad-pack, 8, 16, 32, or more) similar to the laser diodes D_{L}¹⁻ⁿ are arranged on a central circuit board or circuit board region 2510. Two or more laser diode driver circuits 2502a-2502d (fluxing circuits, as described above) each include at least a respective bypass switch M_{BP} and inductor L_{S} (not shown) electrically configured as shown in FIG. 23A-23D. In the example shown, nodes 2314a-d are directly electrically connected with a drain node of a respective bypass switch and a node terminal of a respective inductor of that laser diode driver circuit.

As shown, laser diode driver circuits 2502a-d are spatially arranged around the circuit board region 2510 at an equal distance and/or conduction length d (i.e., paths having equal impedance) between a laser diode anode node 2315a-d (introduced in FIG. 23A) and a respective node 2314a-d (also introduced in FIG. 23A) at the drain node of each channel's respective bypass switch. As such, each respective impedance of the connection between nodes 2314a-d of the laser diode driver circuits 2502a-2502d and a respective anode of the nodes 2315a-d of the circuit board region 2510 is the same, or is nearly the same. In some examples, a laser diode switch M_{DL} (not shown) is arranged on the rear surface of the circuit board region 2510 and has a drain node connected to a common cathode terminal of the laser diodes of the circuit board region 2510, similar to the electrical configuration of the laser diode switch M_{DL} shown in FIG. 23A and FIG. 23D.

In some examples, a central controller chip such as the controller 120 (not shown) can also be placed on the top or bottom of the board 2510 near to, or directly under, the laser diodes 2520 such that a single timing circuit or multiple timing circuits on the same die can achieve very accurate matching (e.g., substantially, exactly, or nearly exactly matched) between timing of the bypass switches M_{BP}¹⁻ⁿ when controlling respective current flows through the inductors L_{S}¹⁻ⁿ. In some examples, a separate driver chip (not shown) is used for each bypass switch M_{BP}¹⁻ⁿ and the laser diode switch M_{DL}. In some examples, some or all of the bypass switches M_{BP}¹⁻ⁿ share the same driver chip. In some examples, the controller chip directly drives some or all of the bypass switches M_{BP}¹⁻ⁿ and/or the laser diode switch MDL.

Simplified example waveforms of current and voltage signals related to the operation of the multi-channel pulsed laser diode drivers 2302, 2303, 2304, and/or 2305 are shown in FIG. 26A through FIG. 26E, in accordance with some examples.

The simplified waveforms shown in FIG. 26A include a current waveform 2603 of the current i_{LF} formed through the inductor L_{F} of the capacitor refresh circuit 2201, a voltage waveform 2604 of the source voltage V_{S} formed at one or more source capacitors C_{S}, a pulsed current i_{DL}*2601a-h (where ‘*’ represents a respective channel indicator 1−n) through respective laser diodes D_{L} of the pulsed laser diode driver, and a fluxing current i_{L}S*2602a-h through respective inductors L_{S} of the pulsed laser diode driver. For example, the current pulse 2601a may be associated with a first channel of the pulsed laser diode driver 2302 shown in FIG. 23A, in which case the pulsed current i_{DL}*2601a is representative of the pulsed current i_{DL}¹, and the fluxing current i_{LS}*2602a is representative of the fluxing current i_{LS}¹. Similarly, the pulsed laser diode driver 2302 may have n=4 channels, and as such current pulses 2601a and 2601e may be associated with a first channel of the laser diode driver, current pulses 2601b and 2601f may be associated with a second channel of the laser diode driver, and so on.

The simplified waveforms shown in FIG. 26B illustrate operation of a multi-channel pulsed laser diode driver that is the same or is similar to the laser diode driver 2302 shown in FIG. 23A or the laser diode driver 2304 shown in FIG. 23C, in accordance with some examples. The simplified waveforms of FIG. 26B show a zoomed-in portion for two pulse emissions (i.e., two channels) of a switching cycle that repeats at a 1 MHz rate. The waveforms include a current waveform 2613 of the current i_{LF} formed through the inductor L_{F} of the capacitor refresh circuit 2201, a voltage waveform 2614 of the source voltage V_{S} formed at one or more source capacitors C_{S}, fluxing switch M_{FLUX} gate control signals GATE_{FLUX} 2615 of the capacitor refresh circuit 2201, respective bypass switch M_{BP}*gate control signals GATE_{BP}*2616a-b, and laser diode switch M_{DL} gate control signals GATE_{DL} 2617. In the example shown, a current pulse 2611a may be associated with a first channel of the pulsed laser diode driver 2302 shown in FIG. 23A, in which case the pulsed current i_{DL} 2611a is representative of the pulsed current i_{DL}¹, and a fluxing current i_{LS}*2612a is representative of the fluxing current i_{LS}¹. Similarly, the current pulses 2611b and 2612b may be associated with a second channel of the pulsed laser diode driver 2302 shown in FIG. 23A.

The simplified waveforms shown in FIG. 26C illustrate operation of a multi-channel pulsed laser diode driver that is the same or is similar to the laser diode driver 2302 shown in FIG. 23A, or the laser diode driver 2304 shown in FIG. 23C, in accordance with some examples. The simplified waveforms of FIG. 26C show a zoomed-in portion for two pulse emissions (i.e., two channels) of a switching cycle that repeats at a 10 MHz rate. The waveforms include a current waveform 2623 of the current i_{LF} formed through the inductor L_{F} of the capacitor refresh circuit 2201, a voltage waveform 2624 of the source voltage V_{S} formed at one or more source capacitors C_{S}, fluxing switch M_{FLUX} gate control signals GATE_{FLUX} 2625 of the capacitor refresh circuit 2201, respective bypass switch M_{BP}*gate control signals GATE_{BP}*2626a-b, and laser diode switch M_{DL} gate control signals GATE_{DL} 2627. In the example shown, the current pulse 2621a may be associated with a first channel of the pulsed laser diode driver 2302 shown in FIG. 23A, in which case a pulsed current i_{DL} 2621a is representative of the pulsed current i_{DL}¹, and a fluxing current i_{LS}*2622a is representative of the fluxing current i_{LS}¹. Similarly, the current pulses 2621b and 2622b may be associated with a second channel of the pulsed laser diode driver 2302 shown in FIG. 23A.

The simplified waveforms shown in FIG. 26D illustrate operation of a multi-channel pulsed laser diode driver that is the same or is similar to the laser diode driver 2303 shown in FIG. 23B or the laser diode driver 2305 shown in FIG. 23D, in accordance with some examples. FIG. 26D shows a zoomed-in portion for two pulse emissions (i.e., two channels) of a switching cycle. The waveforms include a current waveform 2723 of the current i_{LF} formed through the inductor L_{F} of the capacitor refresh circuit 2201, fluxing switch M_{FLUX} gate control signals GATE_{FL}UX 2725 of the capacitor refresh circuit 2201, and respective bypass switch M_{BP}*gate control signals GATE_{BP}*2726a-b. In the example shown, the current pulse 2721a may be associated with a first channel of the pulsed laser diode driver 2303 shown in FIG. 23B, in which case a pulsed current i_{DL}*2721a is representative of the pulsed current i_{DL}, and a fluxing current i_{L}S 2722a is representative of the fluxing current i_{LS}¹. Similarly, the current pulses 2721b and 2722b may be associated with a second channel of the pulsed laser diode driver 2303 shown in FIG. 23B.

The simplified waveforms shown in FIG. 26E illustrate operation of a multi-channel pulsed laser diode driver that is the same or is similar to the laser diode driver 2302 shown in FIG. 23A or the laser diode driver 2304 shown in FIG. 23C, in accordance with some examples. FIG. 26E shows a zoomed-in portion for two pulse emissions (i.e., two channels) of a switching cycle in which charge is allowed flow into the source capacitor C_{S} via the Schottky diode D_{S} of the capacitor refresh circuit 2201 when it is forward-biased before the fluxing switch M_{FLUX} gate control signal M_{FLUX} is pulsed to charge the source capacitor C_{S} the remainder of the way to a full charge.

The waveforms shown include a current waveform 2823 of the current i_{LF} formed through the inductor L_{F} of the capacitor refresh circuit 2201, a voltage waveform 2824 of the source voltage V_{S} formed at one or more source capacitors and having points of interest 2825 and 2826, fluxing switch M_{FLUX} gate control signals GATE_{FLUX} 2827 of the capacitor refresh circuit 2201, respective bypass switch M_{BP}*gate control signals GATE_{BP}*2828a-b, and laser diode switch M_{DL} gate control signals GATE_{DL} 2829. In the example shown, the current pulse 2821a may be associated with a first channel of the pulsed laser diode driver 2302 shown in FIG. 23A, in which case the pulsed current i_{DL}2821a is representative of the pulsed current i_{DL}¹, and the fluxing current i_{LS} 2822a is representative of the fluxing current i_{LS}¹. Similarly, the current pulses 2821b and 2822b may be associated with a second channel of the pulsed laser diode driver 2302 shown in FIG. 23A.

In the example shown, the source capacitor C_{S} is initially allowed to recharge without help from the fluxing switch M_{FLUX} of the capacitor refresh circuit 2201, and then the fluxing switch M_{FLUX} is used to “top off” or complete the charge. At 2825, the source voltage V_{S} 2824 has naturally reached about 8.5V. Then, after the fluxing switch M_{FLUX} is briefly pulsed (via gate signal 2827) the source voltage rises to about 11.2 V at 2826.

In many LiDAR systems, a very short (e.g., sub-nanosecond) emitted optical pulse width is desired to meet performance targets. However, the rate of change of current through the laser diode is governed by a total loop inductance of the current path—i.e., the combined self- and mutual inductance of the forward current path and return current path. Parasitic contributions to this loop inductance arise from bond-wire geometry inside the laser-diode package and from the trace layout of the supporting circuit board. A resulting inductive voltage drop due to the total loop inductance limits the achievable rate of change of current through the laser diode (di/dt), and therefore limits a minimum achieved optical pulse width.

Conventional laser diode drivers typically achieve pulse emission by directly discharging energy stored at a capacitor through one or more laser diodes. In such architectures, parasitic loop inductances of the driver circuit are overcome by increasing the capacitor voltage, which in turn increases the achieved pulse width. The capacitance may be reduced, but such steps also have practical limitations.

Laser diode driver circuits and control methods are disclosed below for mitigating the impact of parasitic loop inductances on light pulse emission width. As compared to the gain-switching spike pulsed laser diode drivers disclosed above which advantageously control when the bypass switch M_{BP} is enabled during a given switching cycle to generate ultra-narrow pulse emissions before a peak of the high-current pulse would be reached, the laser diode driver circuits and control methods described below enable the bypass switch at that same time, or very shortly after (i.e., concurrently with) the time that the high-current pulse is reached to generate a current pulse having similar rise and fall times even when significant loop inductance is present.

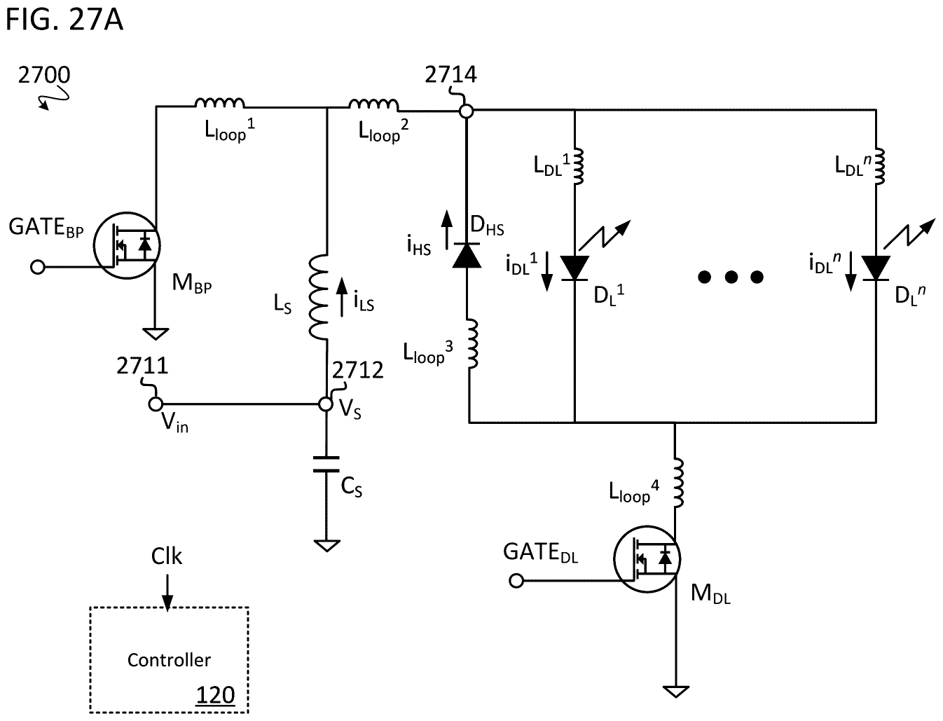

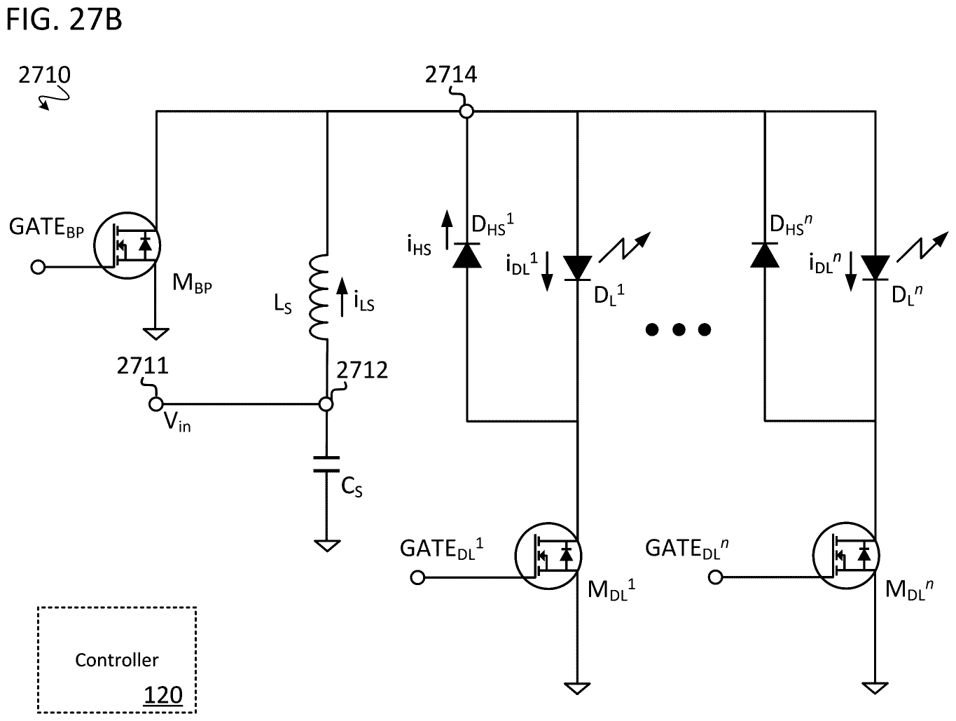

FIG. 27A shows a simplified schematic of a first pulsed laser diode driver 2700 that mitigates the effects of parasitic inductances to achieve ultra-narrow (e.g., sub-nanosecond) laser pulse emission, in accordance with some examples. The simplified circuit schematic 2700 includes a bypass switch M_{BP}, an inductor L_{S} (i.e., a physical component that is not representative of a parasitic inductance of another component), a source capacitor C_{S} (i.e., a physical component that is not representative of a parasitic capacitance of another component), a diode D_{H}S, one or more laser diodes D_{L}ⁱ⁻ⁿ, and a pulse emission switch M_{DL} (also referred to herein as a laser diode switch), connected as shown. In some examples, the diode DHS is a high-surge diode or other rectifier device configured to conduct large, short-duration, forward-current pulses without exceeding its maximum junction temperature or sustaining bond-wire or package failure.

Also shown is the optional controller 120 as described above, a master clock signal Clk received by the controller 120, nodes 2711, 2712, 2714, a DC input voltage Vᵢₙ, a source voltage V_{S} developed at the source capacitor, a current i_{LS} through the inductor L_{S}, a pulse emission switch gate driver signal GATE_{DL}, a bypass switch gate driver signal GATE_{BP}, and currents i_{DL}¹⁻ⁿ.

Example parasitic inductances of the pulsed laser diode driver 2700 are illustrated as inductances Lₗₒₒₚ¹⁻⁴ and L_{DL}¹⁻ⁿ. Even though example parasitic inductances are shown, a first terminal of the inductor L_{S} is considered to be directly electrically connected to a first terminal of the source capacitor C_{S}, and a drain node of the pulse emission switch M_{DL} is directly electrically connected to an anode of the diode DHS, as well as to respective cathodes of the laser diodes D_{L}¹⁻ⁿ. Similarly, a drain node of the bypass switch M_{BP} is considered to be directly electrically connected to a second terminal of the inductor L_{S}, a cathode of the diode DHS, and respective anodes of the laser diodes D_{L}¹⁻ⁿ.

The first terminal of the inductor L_{S} is configured to receive the input voltage Vᵢₙ, a second terminal of the source capacitor C_{S} is directly connected to ground or another bias voltage, and respective source nodes of the bypass switch M_{BP} and the pulse emission switch M_{DL} are directly electrically connected to ground or another bias voltage.

The optional controller 120 is operable to receive the master clock signal Clk to generate the bypass switch gate driver signal GATE_{BP} and the pulse emission switch gate driver signal GATE_{DL}. The bypass switch M_{BP} is configured to receive the bypass switch gate driver signal GATE_{BP} at a gate node, the bypass switch gate driver signal GATE_{BP} being operable to turn the bypass switch M_{BP} ON or OFF based on a voltage level of the bypass switch gate driver signal GATE_{BP}. In some examples, the bypass switch M_{BP} is implemented as a Gallium Nitride (GaN) Field Effect Transistor (FET). In other examples, the bypass switch M_{BP} is implemented as a Silicon-based or Silicon-Carbide-based field-effect transistor (FET).

Similarly, the pulse emission switch M_{DL} is configured to receive the pulse emission switch gate driver signal GATE_{DL} at a gate node, the pulse emission switch gate driver signal GATE_{DL} being operable to turn the pulse emission switch M_{DL} ON or OFF based on a voltage level of the pulse emission switch gate driver signal GATE_{DL}. In some examples, the pulse emission switch M_{DL} is implemented as a Gallium Nitride (GaN) Field Effect Transistor (FET). In other examples, the pulse emission switch M_{DL} is implemented as a Silicon-based or Silicon-Carbide-based field-effect transistor (FET).

In some non-limiting examples, the regulated input voltage Vᵢₙ ranges from 3V to 80V, the inductance of the inductor L_{S} ranges from 10 nH to 1 uH, and the capacitance of the source capacitor C_{S} ranges from 20 pF to 20 nF. However, it is understood that the voltage ranges and component values may be extended beyond the ranges provided based on design and application requirements. For example, a high capacitance value for the source capacitor C_{S} could be used such that the source voltage V_{S} is not significantly reduced during pulse emission as long as the source voltage V_{S} is kept below the forward threshold voltage of the laser diodes D_{L}¹⁻ⁿ shown in FIG. 27A through FIG. 27B. A small amount of current in a laser diode is permissible as long as it does not exceed the current level at which the laser diode begins to emit light.

Additionally, the optional controller 120 is operable to sense a voltage and/or current at any of the nodes 2711, 2712, 2714, and at nodes that are similar to, or the same as those nodes, or at still other nodes described herein. The optional controller 120 may include one or more timing circuits, look-up tables, timing circuits, state machines, processors, memory, or other modules.

FIG. 27B shows a simplified schematic of a second pulsed laser diode driver 2710 that mitigates the effects of parasitic inductances to achieve ultra-narrow (e.g., sub-nanosecond) laser pulse emission, in accordance with some examples. The pulsed laser diode driver 2710 is similar to the pulsed laser diode driver 2700, but is configured for individual channel control of the laser diodes D_{L}¹⁻ⁿ through the use of respective pulsed emission switches M_{DL}¹⁻ⁿ controlled by respective pulsed emission switch gate driver signals GATE_{DL}¹⁻ⁿ. The parasitic inductances Lₗₒₒₚ¹⁻ⁿ shown in FIG. 27A are omitted from FIG. 27B for simplicity, but are understood to be present.

Similar to the example laser diode drivers disclosed above, the laser diode driver circuits 2700 and 2710 generate respective high-current pulses through the laser diodes D_{L}¹⁻ⁿ using a current-resonant mode of operation that involves first developing a current i_{LS} through the inductor L_{S} by enabling the bypass switch M_{BP} while the pulse emission switch M_{DL} (or all of M_{DL}¹⁻ⁿ) remains disabled, and then briefly enabling the pulse emission switch M_{DL} (or one of M_{DL}¹⁻ⁿ) while the bypass switch M_{BP} is disabled to generate a resonant peak voltage at the respective anodes of the laser diodes D_{L}¹⁻ⁿ thereby developing a large current flow through the laser diodes D_{L}¹⁻ⁿ.

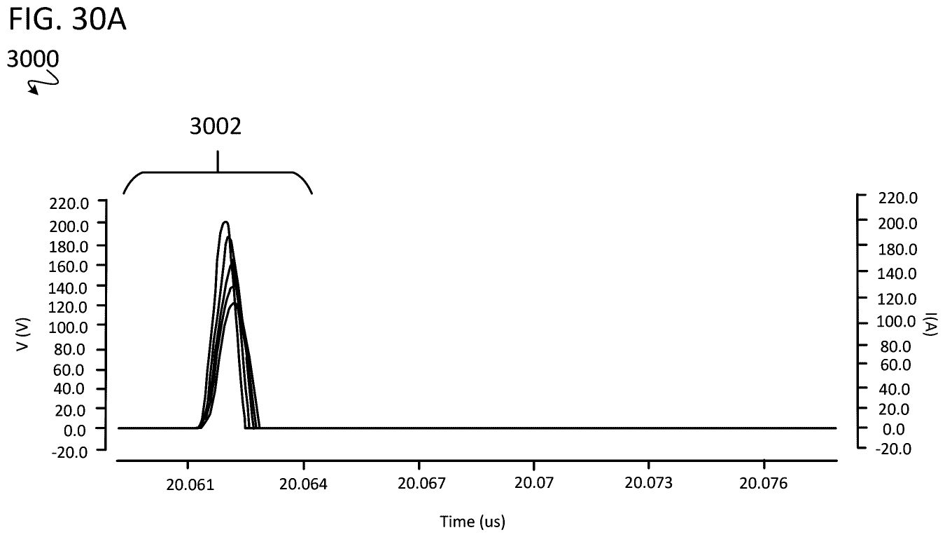

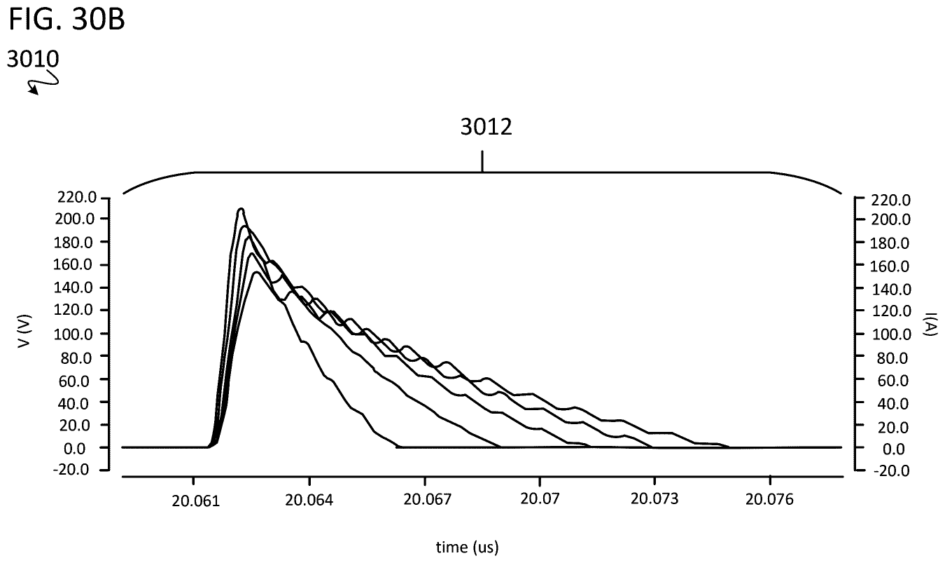

However, during operation, additional voltages are developed across the parasitic inductances in the path of current flow—for example, across the parasitic inductances Lₗₒₒₚ³⁻⁴. Such parasitic inductances do not impact the rise time of a high-current pulse developed through the laser diodes D_{L}¹⁻ⁿ since an initial current was already flowing from the inductor L_{S} to the laser diodes D_{L}¹⁻ⁿ after the bypass switch M_{BP} is disabled and before the pulse emission switch M_{DL} is enabled. However, if the respective cathodes of the laser diodes D_{L}¹⁻ⁿ are grounded, or connected to ground through the pulse emission switch M_{DL} for longer than the desired pulse width, the fall-time (di/dt) of the high-current pulse increases beyond a desired fall time and results in a ramp which significantly increases the pulse width of the high-current pulse through the laser diodes D_{L}¹⁻ⁿ(illustrated in FIG. 30B, described below).

As disclosed herein, if the path to ground for the current through the laser diodes D_{L}¹⁻ⁿ is opened near, or slightly after, the point in time at which a peak current is developed through the laser diodes D_{L}¹⁻ⁿ, the diode current must “pivot” to take a different path to ground, thereby resulting in a fast fall time. The resulting current and laser diode light profile advantageously remains symmetric with a low FWHM (full-width at half-maximum) pulse width. However, a reverse polarity high surge diode (i.e., DHS) is necessary in some examples to limit the amplitude of a reverse bias voltage developed across the laser diodes D_{L}¹⁻ⁿ. Since the pulse emission switch M_{DL} is disabled when the current i_{DL}¹⁻ⁿ developed through each laser diode D_{L}¹⁻ⁿ is near its respective peak, the cathode voltage at each laser diode will rise and forward bias the high surge diode, thereby keeping the anode and cathode of the laser within a few volts of reverse bias.

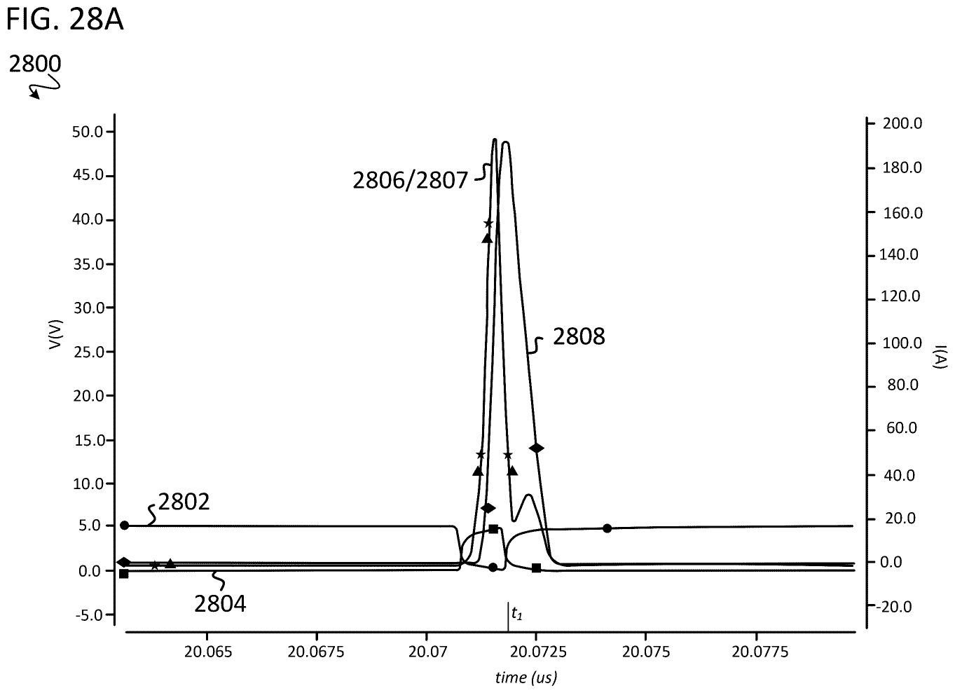

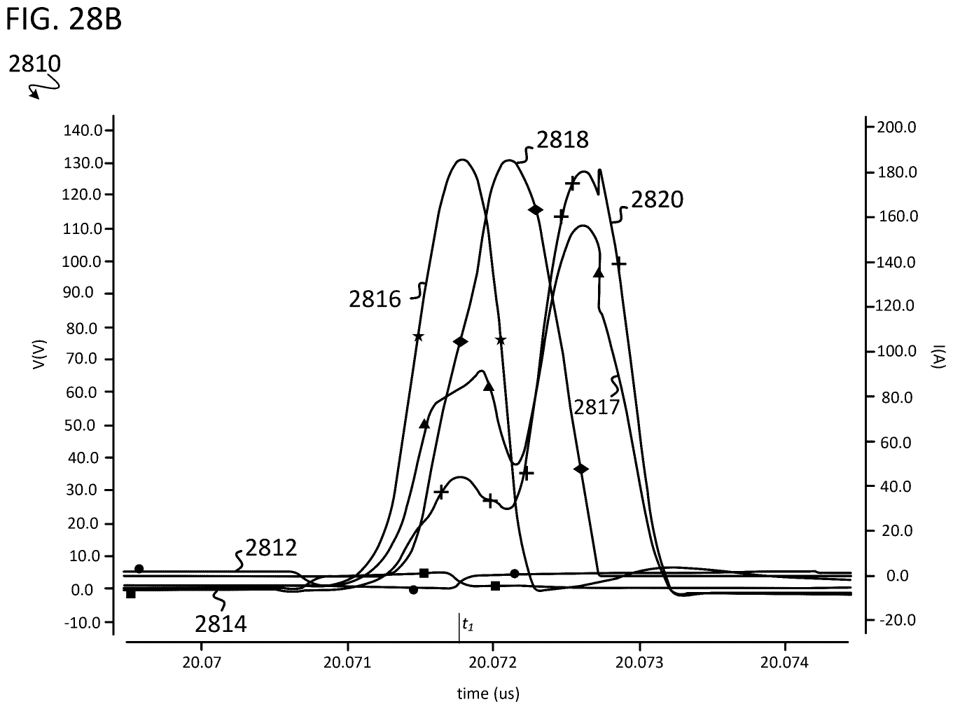

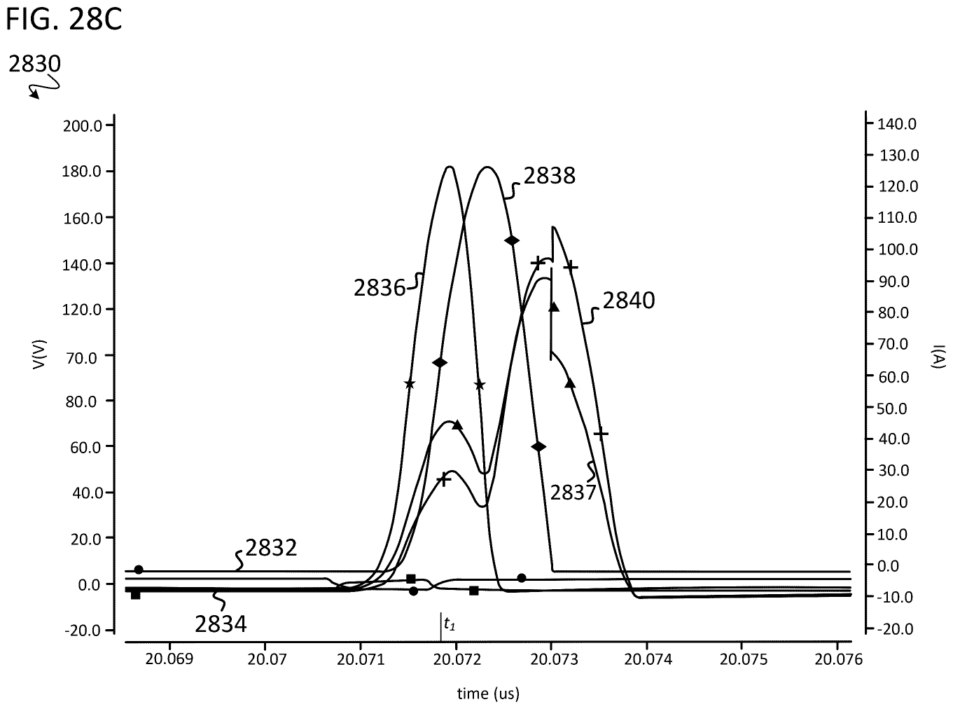

FIG. 28A shows example waveforms 2800 of the laser diode driver 2700 when simulated as an ideal circuit having no parasitic loop inductances, i.e., each of the parasitic inductances Lₗₒₒₚ¹⁻⁴ is equal to 0. As disclosed herein, the bypass switch M_{BP} is advantageously enabled by the controller 120 at or near a point in time t₁ at which the peak of the high-current pulse through the laser diodes D_{L}¹⁻ⁿ occurs. This simulation represents the ideal performance for a PCB layout. In the example shown, a waveform 2802 corresponds to the bypass switch gate driver signal GATE_{BP}, a waveform 2804 corresponds to the pulse emission switch gate driver signal GATE_{DL}, a waveform 2806 corresponds to the voltage developed at the drain node of the pulse emission switch M_{DL}, a waveform 2807 corresponds to a voltage developed at the shared anode terminal of the laser diodes D_{L}¹⁻ⁿ, and a waveform 2808 corresponds to the resultant high-current pulse through the laser diodes D_{L}¹⁻ⁿ, measured at their shared cathode terminal of the laser diodes D_{L}¹⁻ⁿ.

In the example shown, since there is no parasitic loop inductance, the voltage at the drain node of the pulse emission switch M_{DL} (waveform 2806) and the voltage at the shared anode terminal of the laser diodes D_{L}¹⁻ⁿ(waveform 2807) are substantially equivalent and reach close to 50V. Accordingly, the FWHM of the high-current pulse shown in waveform 2808 is very short (750 ns), which is advantageous for human eye safety, and the maximum current achieved is near 200 A.

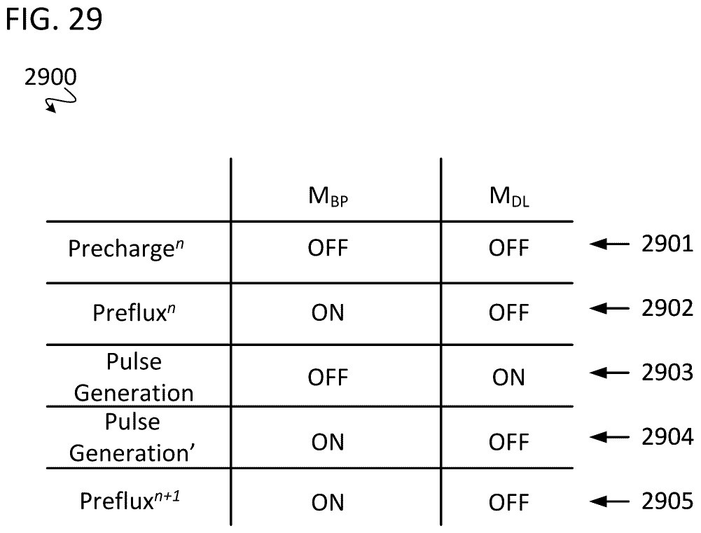

With reference to an example switching sequence 2900 shown in FIG. 29 (e.g., as implemented by the controller 120), the pulsed laser diode driver 2700 advantageously generates a symmetric high-current pulse even as the loop inductance of the pulsed laser diode driver 2700 increases. The example is generally applicable to the pulsed laser diode driver 2710 as well, when individual channels thereof are pulsed. At step 2901, the pulsed laser diode driver 2700 is in a steady state (Prechargeⁿ), not shown in FIG. 28A, in which both of the switches M_{BP} and M_{DL} are in an OFF-state. At step 2902 (Prefluxⁿ), the bypass switch M_{BP} is enabled, and the pulse emission switch M_{DL} remains in the OFF-state. As described above, by providing a path to ground or other bias voltage through the bypass switch M_{BP}, the current i_{LS} develops through the inductor L_{S} to store energy therein in the form of magnetic flux. At step 2903 (Pulse Generation), the bypass switch M_{BP} is transitioned to an OFF-state and the pulse emission switch M_{DL} is enabled to redirect the flow of current i_{LS} through the one or more laser diodes D_{L}¹⁻ⁿ as respective high-current pulses i_{DL}¹⁻ⁿ to cause light pulse emission. However, in contrast to the switching sequence 300 described above with reference to FIG. 3, at step 2904 (Pulse Generation'), the bypass switch M_{BP} is re-enabled at, or slightly after when the peak of the high-current pulse is reached, and the pulse emission switch M_{DL} is transitioned to an OFF-state. By providing a path to ground for the current i_{dl}¹⁻ⁿ via the bypass switch M_{BP}, the current once again pivots to advantageously generate a falling edge of the high-current pulse that is substantially similar (i.e., a similar di/dt) to that of the rising edge of the high-current pulse. At step 2905 (Prefluxⁿ⁺¹), the switching sequence returns to the same state as described with reference to step 2902, or optionally returns to the state shown at step 2901.

FIG. 28B shows example waveforms 2810 of the laser diode driver 2700 when simulated using a parasitic inductance of 100 pH for each of the parasitic inductances Lₗₒₒₚ¹⁻⁴. Similar to the example shown in FIG. 28A, the bypass switch M_{BP} is advantageously enabled by the controller 120 at or near a point in time t₁ at which the peak of the high-current pulse through the laser diodes D_{L}¹⁻ⁿ would normally have occurred. In the example shown, a waveform 2812 corresponds to the bypass switch gate driver signal GATE_{BP}, a waveform 2814 corresponds to the pulse emission switch gate driver signal GATE_{DL}, a waveform 2816 corresponds to the voltage developed at the drain node of the pulse emission switch M_{DL}, a waveform 2817 corresponds to a voltage developed at the shared anode terminal of the laser diodes D_{L}¹⁻ⁿ, a waveform 2818 corresponds to the resultant high-current pulse through the laser diodes D_{L}¹⁻ⁿ, measured at their shared cathode terminal, and a waveform 2820 corresponds to a voltage developed at the shared cathode terminal of the laser diodes D_{L}¹⁻ⁿ.

Since there are four placements of parasitic inductances Lₗₒₒₚ¹⁻⁴ and each has a value of 100 pH, a total loop inductance of the pulsed laser diode driver circuit 2700 is 400 pH, which is a significant inductance to overcome. However, because the current must “pivot” (i.e., take a different path to ground) during both the rise time and fall time of the high-current pulse, even though the voltage waveforms 2816 and 2817 have been highly impacted by the total loop inductance, the symmetry of the current waveform 2818 is not dramatically affected as compared to that of the ideal current waveform 2808 shown in FIG. 28A.

Because of the additional inductance, the voltage at the drain node of the pulse emission switch M_{DL} (waveform 2816) reaches a peak of about 130V while the voltage at the shared anode terminal of the laser diodes D_{L}¹⁻ⁿ only reaches a peak of about 50V-60V. If a high-voltage rated switch (e.g., GaN) is used, such additional voltage is not an issue. Thus, using the pulsed laser diode driver 2700 and the control method disclosed herein, a 500 W peak for quad-pack laser diodes and a 1000 W peak for octal-pack laser diodes with a FWHM pulse width of 750 psec is attainable. Such architectures therefore advantageously aid in human eye safety in LiDAR systems.

FIG. 28C shows example waveforms 2830 of the laser diode driver 2700 when simulated using a parasitic inductance of 250 pH for each of the parasitic inductances Lₗₒₒₚ¹⁻⁴. Similar to the example shown in FIG. 28A, the bypass switch M_{BP} is advantageously enabled by the controller 120 at or near a point in time t₁ at which the peak of the high-current pulse through the laser diodes D_{L}¹⁻ⁿ occurs. In the example shown, a waveform 2832 corresponds to the bypass switch gate driver signal GATE_{Bp}, a waveform 2834 corresponds to the pulse emission switch gate driver signal GATE_{DL}, a waveform 2836 corresponds to the voltage developed at the drain node of the pulse emission switch M_{DL}, a waveform 2837 corresponds to a voltage developed at the shared anode terminal of the laser diodes D_{L}¹⁻ⁿ, a waveform 2838 corresponds to the resultant high-current pulse through the laser diodes D_{L}¹⁻ⁿ, measured at their shared cathode terminal, and a waveform 2840 corresponds to a voltage developed at the shared cathode terminal of the laser diodes D_{L}¹⁻ⁿ.

Since there are four placements of parasitic inductances Lₗₒₒₚ¹⁻⁴ and each has a value of 250 pH, a total loop inductance of the pulsed laser diode driver circuit is 1 nH, which is an even higher inductance to overcome as compared to the example shown in FIG. 28B. However, even with a 1 nH loop inductance, the pulsed laser diode driver 2700 and control method disclosed herein generate a high-current pulse (waveform 2838) that is substantially symmetric and has a peak current of about 130 A.

In the example shown, the voltage at the shared anode terminals of the laser diodes D_{L}¹⁻ⁿ(waveform 2837) exceeds the voltage at the shared cathode terminal (waveform 2840) during pulse emission. However, when the pulse emission switch M_{DL} is disabled, the voltage at the shared cathode node exceeds the voltage at the shared anode node of the laser diodes D_{L}¹⁻ⁿ until the diode DHS becomes forward biased and is enabled, thereby preventing a large reverse bias voltage from being developed across the laser diodes D_{L}¹⁻ⁿ which could potentially damage them.

In some examples, the pulsed laser diode driver 2700/2710 enables the bypass switch M_{BP} at, or slightly after (e.g., within less than 1 usec, within less than 500 nsec, within less than 5 nsec, etc.) the point in time that the peak of the high-current pulse occurs based on a timing configuration at the controller 120. In other examples, the controller 120 is operable to sense a current amplitude of the high-current pulse through one or more of the laser diodes D_{L}¹⁻ⁿ and determine a time within a switching sequence at which the peak will occur and enable the bypass switch M_{BP} according to the determined time.

FIG. 30A and FIG. 30B show example simulation results 3000 and 3010, respectively, of a pulsed laser diode driver circuit that is similar to that shown and described with reference to FIG. 27A. The plots 3002 demonstrate the loop inductance tolerance of the pulsed laser diode driver 2700 across a range of loop inductances, and the plots 3012 illustrate a baseline example where the effects of loop inductance are not mitigated. All of the plots shown in FIG. 30A and FIG. 30B were generated using an input voltage Vin of 10V.

The plots 3002 and 3012 each illustrate combined laser diode currents when driving four laser diodes simultaneously. The plot 3002 illustrates the high-current pulse through the laser diodes as a total loop inductance varied from 200 pH to 1000 pH in steps of 200 pH. As shown, although the amplitude of the high-current pulse was reduced, the FWHM pulse width remained below 1 nsec (ranging from 600 psec to 800 psec). By comparison, the plots 3012 illustrate the performance of the pulsed laser diode driver 2700 when operated without the methods disclosed above for mitigating the effects of loop inductances. In the example shown, the loop inductance was swept over the identical range as compared to that of FIG. 30A, but the FWHM pulse width ranged from 3 ns to 5 ns.

Reference has been made in detail to examples of the disclosed invention, one or more examples of which have been illustrated in the accompanying figures. Each example has been provided by way of explanation of the present technology, not as a limitation of the present technology. In fact, while the specification has been described in detail with respect to specific embodiments of the invention, it will be appreciated that those skilled in the art, upon attaining an understanding of the foregoing, may readily conceive of alterations to, variations of, and equivalents to these examples. For instance, features illustrated or described as part of one embodiment may be used with another example to yield a still further embodiment. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only, and is not intended to limit the invention.

What is claimed is:

1. A pulsed laser diode driver comprising:
an inductor having a first terminal and a second terminal, the first terminal of the inductor being configured to receive a first source voltage, the first source voltage being based on a DC input voltage;
a source capacitor having a first terminal directly electrically connected to the first terminal of the inductor to provide the first source voltage and a second terminal electrically coupled to ground;
a bypass switch having a drain node that is directly electrically connected to the second terminal of the inductor and a source node that is directly electrically connected to ground;
a first laser diode having an anode and a cathode, the anode of the first laser diode being directly electrically connected to the second terminal of the inductor and to the drain node of the bypass switch; and
a first pulse emission switch having a drain node that is directly electrically connected to the cathode of the first laser diode and a source node that is directly electrically connected to ground;
wherein:
the first pulse emission switch and the bypass switch are configured to control a current flow through the inductor to emit a high-current pulse through the first laser diode to thereby emit a light pulse, the high-current pulse corresponding to a peak current of a resonant waveform developed at the anode of the first laser diode; and
the bypass switch is enabled during emission of the high-current pulse to modify a falling edge of the high-current pulse.

2. The pulsed laser diode driver of claim 1, wherein:
the bypass switch is enabled during emission of the high-current pulse to truncate emission of the light pulse after a gain-switching spike portion of the light pulse occurs and before a resonant portion of the light pulse concludes.

3. The pulsed laser diode driver of claim 2, wherein:
the first pulse emission switch is enabled to initiate the emission of the high-current pulse and remains enabled when the bypass switch is enabled during the emission of the high-current pulse to truncate emission of the light pulse.

4. The pulsed laser diode driver of claim 1, wherein:
the bypass switch is enabled during emission of the high-current pulse substantially concurrently with a peak amplitude of the high-current pulse.

5. The pulsed laser diode driver of claim 4, wherein:
the first pulse emission switch is enabled to initiate the emission of the high-current pulse and is disabled substantially concurrently with the peak amplitude of the high-current pulse.

6. The pulsed laser diode driver of claim 4, further comprising:
a diode having an anode terminal directly electrically connected with the drain node of the first pulse emission switch and a cathode directly electrically connected with the drain node of the bypass switch.

7. The pulsed laser diode driver of claim 1, further comprising:
a second laser diode having an anode and a cathode, the anode of the second laser diode being directly electrically connected to the second terminal of the inductor and to the drain node of the bypass switch;
wherein:
at least the first pulse emission switch and the bypass switch are configured to control a current flow through the inductor to emit a high-current pulse through the second laser diode to thereby emit a light pulse, the high-current pulse corresponding to a peak current of a resonant waveform developed at the anode of the second laser diode.

8. The pulsed laser diode driver of claim 7, wherein:
the cathode of the second laser diode is directly electrically connected to the drain node of the first pulse emission switch.

9. The pulsed laser diode driver of claim 7, further comprising:
a second pulse emission switch having a drain node that is directly electrically connected to the cathode of the second laser diode and a source node that is directly electrically connected to ground.

10. A pulsed laser diode driver comprising:
an inductor having a first terminal and a second terminal, the first terminal of the inductor being configured to receive a first source voltage, the first source voltage being based on a DC input voltage;
a source capacitor having a first terminal directly electrically connected to the first terminal of the inductor to provide the first source voltage and a second terminal electrically coupled to ground;
a bypass switch having a drain node that is directly electrically connected to the second terminal of the inductor and a source node that is directly electrically connected to ground;
a first laser diode having an anode and a cathode, the anode of the first laser diode being directly electrically connected to the second terminal of the inductor and to the drain node of the bypass switch;
wherein:
the bypass switch is configured to control a current flow through the inductor to emit a high-current pulse through the first laser diode to thereby emit a light pulse, the high-current pulse corresponding to a peak current of a resonant waveform developed at the anode of the first laser diode; and
the bypass switch is enabled during emission of the high-current pulse to truncate emission of the light pulse after a gain-switching spike portion of the light pulse occurs and before a resonant portion of the light pulse concludes.

11. A pulsed laser diode driver comprising:
an inductor having a first terminal and a second terminal, the first terminal of the inductor being configured to receive a first source voltage, the first source voltage being based on a DC input voltage;
a source capacitor having a first terminal directly electrically connected to the first terminal of the inductor to provide the first source voltage and a second terminal electrically coupled to ground;
a bypass switch having a drain node that is directly electrically connected to the second terminal of the inductor and a source node that is directly electrically connected to ground;
a first laser diode having an anode and a cathode, the anode of the first laser diode being directly electrically connected to the second terminal of the inductor and to the drain node of the bypass switch; and
a first pulse emission switch having a drain node that is directly electrically connected to the cathode of the first laser diode and a source node that is directly electrically connected to ground;
wherein:
the first pulse emission switch and the bypass switch are configured to control a current flow through the inductor to emit a high-current pulse through the first laser diode to thereby emit a light pulse, the high-current pulse corresponding to a peak current of a resonant waveform developed at the anode of the first laser diode; and
the bypass switch is enabled during emission of the high-current pulse substantially concurrently with a peak amplitude of the high-current pulse.

12. The pulsed laser diode driver of claim 11, wherein:
the first pulse emission switch is enabled to initiate the emission of the high-current pulse and is disabled substantially concurrently with the peak amplitude of the high-current pulse.

13. The pulsed laser diode driver of claim 11, further comprising:
a diode having an anode terminal directly electrically connected with the drain node of the first pulse emission switch and a cathode directly electrically connected with the drain node of the bypass switch.
